(19) United States
(12) Patent Application Publication
(10) Pub. No.: US 2026/0182091 A1
(43) Pub. Date: Jun. 25, 2026

(54) DISPLAY INCLUDING LATERAL-STRUCTURE MULTICOLOR LIGHT EMITTING DEVICE PIXELS AND METHOD OF FABRICATION THEREOF

(71) Applicant: SAMSUNG ELECTRONICS CO., LTD., Suwon-si (KR)

(72) Inventors: Saket CHADDA, Milpitas, CA (US); Wei DING, Milpitas, CA (US); Zulal Tezcan OZEL, Milpitas, CA (US)

(73) Assignee: SAMSUNG ELECTRONICS CO., LTD., Suwon-si (KR)

(21) Appl. No.: 19/127,477

(22) PCT Filed: Dec. 1, 2023
(86) PCT No.: PCT/US2023/082045

§ 371 Date: May 6, 2025

Related U.S. Application Data
(60) Provisional application No. 63/385,671, filed on Dec. 1, 2022.

(51) Int. Cl. H10H 20/819; H10H 20/01

(52) U.S. Cl. CPC H10H 20/819; H10H 20/01

(57) ABSTRACT

A multicolor (e.g., red, green and blue) direct view display device and methods of fabrication thereof are disclosed. Multicolor light emitting device pixels having a plurality of subpixels configured to emit different color light may be fabricated on the same initial growth substrate and transferred to a second substrate to provide a direct view display device. The multicolor light emitting device pixels may have p-side and n-side contact electrodes of each pixel located on the same side of the structure, which enables functional multicolor light emitting device pixels to be transferred without requiring subsequent backend processing steps to form contact electrodes for the pixels.

### FIELD

The present invention relates to light emitting devices, and particularly to displays including multicolor light emitting device subpixels sourced from a common growth substrate, and methods of fabricating the same.

### BACKGROUND

Light emitting devices such as light emitting diodes (LEDs) are used in electronic displays, such as backlights in liquid crystal displays located in laptops or televisions. Light emitting devices include light emitting diodes (LEDs) and various other types of electronic devices configured to emit light.

### SUMMARY

According to an aspect of the present disclosure, a display includes a backplane having a mounting surface, and a multicolor pixel bonded to the mounting surface of the backplane, the multicolor pixel including a plurality of subpixels, where each subpixel is configured to emit light having a different peak wavelength, and where each subpixel of the multicolor pixel comprises a front side surface configured to emit light there through and a rear side surface facing the backplane. Each subpixel of the multicolor pixel includes a front side portion adjacent to the front side surface of the subpixel and including a first conductivity-type semiconductor material layer extending continuously between each subpixel of the multicolor pixel, and a rear side portion adjacent to the rear side surface of the subpixel and including an active region and a second conductivity-type semiconductor material layer. A first contact electrode electrically contacts the first conductivity-type semiconductor material layer, second contact electrodes electrically contact the second conductivity-type semiconductor material layer in each subpixel of the multicolor pixel, and bonding material portions mechanically and electrically couple the first contact electrode and the plurality of second contact electrodes to corresponding bonding pads on the mounting surface of the backplane.

According to another aspect of the present disclosure, a method of fabricating a a display device includes forming a multicolor light emitting device pixel over an initial growth substrate, the multicolor light emitting device pixel including a first conductivity-type semiconductor material layer and a plurality of light emitting device structures over the first conductivity-type semiconductor material layer that are configured to emit light having different peak wavelengths, forming a contact electrode over the first conductivity-type semiconductor material layer, and transferring the multicolor light emitting device pixel from the initial growth substrate to a second substrate such that a bonding material portion electrically couples the contact electrode to a bonding pad on the second substrate and the contact electrode provides a common contact electrode for the plurality of light emitting device structures of the multicolor light emitting device pixel.

### BRIEF DESCRIPTION OF THE DRAWINGS

FIG. 1A is a plan view of a substrate with light emitting diodes of multiple colors according to an embodiment of the present disclosure.

FIG. 1B is an enlarged view of a portion of a substrate that includes four multicolor light emitting device pixels according to an embodiment of the present disclosure.

FIG. 1C is a vertical cross-section view of a multicolor light emitting device pixel taken along line A-A′ in FIG. 1B.

FIG. 1D is a vertical cross-section view of a portion of the substrate including a pair of adjacent pixels taken along line B-B′ in FIG. 1B.

FIG. 2 is a vertical cross-section view of a first exemplary structure including a pixel region of an initial growth substrate on which a multicolor light emitting pixel may be subsequently formed according to various embodiments of the present disclosure.

FIG. 3 is a vertical cross-section view of the first exemplary structure including a continuous doped semiconductor material layer formed over the initial growth substrate according to various embodiments of the present disclosure.

FIG. 4 is a vertical cross-section view of the first exemplary structure including a continuous superlattice structure formed over the continuous doped semiconductor material layer according to various embodiments of the present disclosure.

FIG. 5 is a vertical cross-section view of the first exemplary structure including a continuous lower spacer layer formed over the continuous superlattice structure according to various embodiments of the present disclosure.

FIG. 6 is a vertical cross-section view of the first exemplary structure including a continuous first dielectric material layer formed over the continuous lower spacer layer according to various embodiments of the present disclosure.

FIG. 7 is a vertical cross-section view of the first exemplary structure including a patterned mask formed over the continuous first dielectric material layer according to various embodiments of the present disclosure.

FIG. 8 is a vertical cross-section view of the first exemplary structure including an opening formed through the first dielectric material layer in a first subpixel region according to various embodiments of the present disclosure.

FIG. 9 is a vertical cross-section view of the first exemplary structure including an upper spacer layer formed over the continuous lower spacer layer in the first subpixel region according to various embodiments of the present disclosure.

FIG. 10 is a vertical cross-section view of the first exemplary structure including an active region formed over the upper spacer layer in the first subpixel region according to various embodiments of the present disclosure.

FIG. 11 is a vertical cross-section view of the first exemplary structure including an optional electron blocking layer formed over the active region in the first subpixel region according to various embodiments of the present disclosure.

FIG. 12 is a vertical cross-section view of the first exemplary structure including a doped semiconductor material layer formed over the electron blocking layer in the first subpixel region according to various embodiments of the present disclosure.

FIG. 13 is a vertical cross-section view of the first exemplary structure following an etching process to remove the first dielectric material layer according to various embodiments of the present disclosure.

FIG. 14 is a vertical cross-section view of the first exemplary structure including a continuous second dielectric material layer formed over the lower portion of the spacer layer and over the side surfaces and upper surface of a mesa portion of a first light emitting epitaxial semiconductor structure according to various embodiments of the present disclosure.

FIG. 15 is a vertical cross-section view of the first exemplary structure including a patterned mask formed over the continuous second dielectric material layer according to various embodiments of the present disclosure.

FIG. 16 is a vertical cross-section view of the first exemplary structure including an opening formed through the second dielectric material layer in a second subpixel region according to various embodiments of the present disclosure.

FIG. 17 is a vertical cross-section view of the first exemplary structure including an upper portion of the spacer layer formed in a second subpixel region according to various embodiments of the present disclosure

FIG. 18 is a vertical cross-section view of the first exemplary structure including an active region formed over the upper portion of the spacer layer and the second dielectric material layer in the second subpixel region according to various embodiments of the present disclosure.

FIG. 19 is a vertical cross-section view of the first exemplary structure including a second light emitting epitaxial semiconductor structure in the pixel region according to various embodiments of the present disclosure.

FIG. 20 is a vertical cross-section view of the first exemplary structure following an etching process to remove the second dielectric material layer according to various embodiments of the present disclosure

FIG. 21 is a vertical cross-section view of the first exemplary structure including a continuous third dielectric material layer formed over the lower portion of the spacer layer, over the side surfaces and upper surface of the mesa portion of the first light emitting epitaxial semiconductor structure, and over the side surfaces and upper surface of the mesa portion of the second light emitting epitaxial semiconductor structure according to various embodiments of the present disclosure.

FIG. 22 is a vertical cross-section view of the first exemplary structure including a patterned mask formed over the continuous third dielectric material layer according to various embodiments of the present disclosure.

FIG. 23 is a vertical cross-section view of the first exemplary structure including an opening formed through the third dielectric material layer in a third subpixel region according to various embodiments of the present disclosure.

FIG. 24 is a vertical cross-section view of the first exemplary structure including an upper portion of the spacer layer formed in the third subpixel region according to various embodiments of the present disclosure.

FIG. 25 is a vertical cross-section view of the first exemplary structure including an active region formed over the upper portion of the spacer layer and the third dielectric material layer in the third subpixel region according to various embodiments of the present disclosure.

FIG. 26 is a vertical cross-section view of the first exemplary structure including a third light emitting epitaxial semiconductor structure in the pixel region according to various embodiments of the present disclosure.

FIG. 27 is a vertical cross-section view of the first exemplary structure following an etching process to remove the third dielectric material layer according to various embodiments of the present disclosure.

FIG. 28 is a vertical cross-section view of the first exemplary structure including a continuous fourth dielectric material layer formed over the lower portion of the spacer layer, over the side surfaces and upper surface of the mesa portion of the first light emitting epitaxial semiconductor structure, over the side surfaces and upper surface of the mesa portion of the second light emitting epitaxial semiconductor structure and over the side surfaces and upper surface of the mesa portion of the third light emitting epitaxial semiconductor structure according to various embodiments of the present disclosure.

FIG. 29 is a vertical cross-section view of the first exemplary structure including contact electrodes over the upper surfaces of the mesa portions of each of the subpixels of a multicolor pixel according to various embodiments of the present disclosure.

FIG. 30 is a vertical cross-section view the first exemplary structure including a contact electrode over the first conductivity-type semiconductor layer within a contact region of the multicolor pixel according to various embodiments of the present disclosure.

FIG. 31 is a vertical cross-section view of the first exemplary structure including a reflector layer over the fourth dielectric material layer according to an embodiment of the present disclosure.

FIG. 32 is a vertical cross-section view the first exemplary structure including a reflector layer and a contact electrode over the first conductivity-type semiconductor layer within a contact region of the multicolor pixel according to various embodiments of the present disclosure.

FIG. 33 is a vertical cross-section view of the first exemplary structure illustrating a reflector layer that functions as contact electrodes for each of the subpixels and as a common contact electrode for the multicolor pixel according to an embodiment of the present disclosure.

FIG. 34 is a vertical cross-section view of the first exemplary structure including an isolation trench around a multicolor light emitting device pixel according to various embodiments of the present disclosure.

FIG. 35 is a vertical cross-section view of the first exemplary structure in which the isolation trenches are omitted and the first conductivity-type doped semiconductor material layer extends continuously between adjacent multicolor pixels according to an embodiment of the present disclosure.

FIG. 36 is a vertical cross-section view of the first exemplary structure in which the isolation trenches are omitted and a common contact electrode is utilized by multiple pixels according to another embodiment of the present disclosure.

FIG. 37 is a vertical cross-section view of a second exemplary structure including a continuous doped semiconductor material layer formed over an initial growth substrate according to various embodiments of the present disclosure.

FIG. 38 is a vertical cross-section view of the second exemplary structure including a continuous first dielectric material layer formed over the continuous first conductivity-type doped semiconductor material layer according to various embodiments of the present disclosure

FIG. 39 is a vertical cross-section view of the second exemplary structure including an opening formed through the first dielectric material layer in a subpixel region according to various embodiments of the present disclosure.

FIG. 40 is a vertical cross-section view of the second exemplary structure including a discrete first conductivity-type semiconductor material layer formed within the opening in the first dielectric material layer in the first subpixel region according to various embodiments of the present disclosure.

FIG. 41 is a vertical cross-section view of the second exemplary structure including a superlattice structure and a spacer layer formed over the upper portion of the first conductivity-type semiconductor material layer in the first subpixel region according to various embodiments of the present disclosure.

FIG. 42 is a vertical cross-section view of the second exemplary structure including a first light emitting epitaxial semiconductor structure in a pixel region according to various embodiments of the present disclosure.

FIG. 43 is a vertical cross-section view of the second exemplary structure including a multicolor light emitting pixel including a first light emitting epitaxial semiconductor structure, a second light emitting epitaxial semiconductor structure and a third light emitting epitaxial semiconductor structure according to various embodiments of the present disclosure.

FIG. 44 is a vertical cross-section view of the second intermediate structure illustrating a dielectric material layer over and between the mesa structures, contact electrodes for each subpixel formed over the upper surface of respective mesa structures, and a common contact electrode for the multicolor pixel within the contact region according to various embodiments of the present disclosure.

FIG. 45 a vertical cross-section view showing an initial growth substrate having a multicolor light emitting pixel formed thereon and a backplane.

FIG. 46 is a vertical cross-section view illustrating the initial growth substrate moved vertically relative to the backplane such that each facing pair of a diode-side bonding material portion and a backplane-side bonding material portion contact each other according to an embodiment of the present disclosure.

FIG. 47 is a vertical cross-section view illustrating a laser irradiation process using a detachment laser beam according to various embodiments of the present disclosure.

FIG. 48 is a vertical cross-section view illustrating the initial growth substrate and the backplane following the application of a compressive force that induces deformation of the bonding material portions according to an embodiment of the present disclosure.

FIG. 49 is a vertical cross-section view illustrating a bonding laser irradiation process that induces reflow and subsequent bonding of mating pairs of diode-side bonding material portions and backplane-side bonding material portions according to an embodiment of the present disclosure.

FIG. 50 is a vertical cross-section view illustrating a multicolor light emitting device pixel transferred from the initial growth substrate to the backplane according to an embodiment of the present disclosure.

FIG. 51 is a vertical cross-section view of a portion of a display including a plurality of multicolor light emitting device pixels mounted to a backplane according to an embodiment of the present disclosure.

FIGS. 52A-52E schematically illustrate a method of transferring multicolor light emitting device pixels from an initial growth substrate to a target substrate according to an embodiment of the present disclosure.

### DETAILED DESCRIPTION

As stated above, the present disclosure is directed to light emitting devices, and particularly to displays including multicolor light emitting device subpixels sourced from a common growth substrate, and methods of fabricating the same, the various aspects of which are described below. Throughout the drawings, like elements are described by the same reference numeral. Elements with the same reference numeral are presumed to have a same material composition unless expressly stated otherwise. The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure.

As used herein, a “light emitting device” refers to any device that is configured to emit light and includes, but is not limited to, a light emitting device (LED), a laser, such as a vertical-cavity surface-emitting laser (VCSEL), and any other electronic device that is configured to emit light upon application of a suitable electrical bias. As used herein, a “light emitting device assembly” refers to an assembly in which at least one light emitting device is structurally fixed with respect to a carrier structure, which can include, for example, a substrate, a matrix, or any other structure configured to provide stable mechanical support to the at least one light emitting device.

A display device according to various embodiments of the present disclosure may be formed by transferring an array of light emitting devices from an initial growth substrate to a target substrate. The target substrate can be any substrate on which formation of multiple types of devices in any configuration is desired. In an illustrative example, the target substrate can be a backplane substrate such as an active or passive matrix backplane substrate for driving light emitting devices. As used herein, a “backplane” or a “backplane substrate” refers to any substrate configured to affix multiple devices thereupon. The light emitting devices may include a plurality of light emitting devices, such as a group of two light emitting devices, one configured to emit blue light and one configured to emit green light. The light emitting devices may include a group of three light emitting devices, one configured to emit blue light, one configured to emit green light, and one configured to emit red light. As used herein, “neighboring light emitting devices” refer to a plurality of two or more light emitting devices located in closer proximity than at least another light emitting device.

A plurality of light emitting devices configured to emit different color light may be fabricated on an initial growth substrate. As used herein, an “initial growth substrate” refers to a substrate that is processed to form devices thereupon or therein. The devices can include light emitting devices and/or sensor devices (e.g., photodetectors) and/or any other electronic devices. The light emitting devices can be any type of light emitting devices, e.g., vertical light emitting diodes, or any combination thereof. The light emitting devices can be formed as an array on the initial growth substrate.

A display device, such as a direct view display can be formed from an ordered array of pixels located on a target substrate, such as a backplane. Each pixel can include a set of subpixels that emit light at a respective peak wavelength. For example, a pixel can include a red subpixel, a green subpixel, and a blue subpixel. Each subpixel can include one or more light emitting devices (e.g., LEDs) that emit light of a particular wavelength. Each pixel is driven by a backplane circuit such that any combination of colors within a color gamut may be shown on the display for each pixel. The display panel can be formed by a process in which LED subpixels are soldered to, or otherwise electrically attached to, a bond pad located on the backplane. The bond pad is electrically driven by the backplane circuit and other driving electronics.

In the embodiments of the present disclosure, a method for fabrication of a multicolor (e.g., three or more color) direct view display may be performed by using light emitting devices which emit different color light in each pixel. In one embodiment, bulk (e.g., planar) LEDs may be used. Each LED may have a respective blue, green and red light emitting active region to form blue, green and red subpixels in each pixel.

A display device, such as a direct view display device, may be fabricated by epitaxial growth of various material layers, such as III-V including III-nitride semiconductor material layers, over a suitable initial growth substrate (e.g., a wafer). The material layers may be processed using standard semiconductor fabrication techniques to provide a plurality of light emitting devices (e.g., LEDs) on the initial growth substrate, where each of the light emitting devices may include semiconductor material regions of opposite conductivity types (i.e., n-type and p-type) surrounding an active region, which may include one or more quantum wells. The quantum wells are designed to emit light at a particular peak wavelength, which may range from ultraviolet to visible red light. The light emitting devices are then transferred from the initial growth substrate to a backplane to form a display panel.

In the case of multicolor display panels, typically light emitting devices of the same type are grown on respective initial growth substrates that are each processed under conditions optimized to provide light emission at a particular peak wavelength (e.g., red, green or blue). Then, individual light emitting devices from each of the initial growth substrates are transferred to the backplane using separate transfer steps to provide a display panel having multicolor (e.g., red, green and blue) light emitting device sub-pixels. This process can cause a number of complications, including the need to perform multiple separate transfer steps to form each pixel of the multicolor display panel.

Further, following the transfer of the plurality of light emitting devices, additional back-end processes are required to form functional vertical light emitting devices, such as deposition of a dielectric material layer and the formation of electrodes over the light-emitting surfaces of the device.

Another approach to making multicolor light emitting device (e.g., micro-LED) displays include providing multiple monochrome light emitting panels having different peak wavelengths (e.g., red, green and blue) and using a light engine to combine the light from the individual monochrome light emitting panels to create a multicolor display. However, the incorporation of multiple light emitting panels and an associated light engine may increase the complexity and size of the final product, which may render it unsuitable for some applications.

Various embodiments include a multicolor (e.g., red, green and blue) direct view display device and methods of fabricating a multicolor direct view display device. In various embodiments, multicolor light emitting device pixels having a plurality of subpixels configured to emit light at the respective different wavelengths may be fabricated on the same initial growth substrate, such as via a selective area growth technique. The multicolor light emitting device pixels each comprising multi-color LEDs may then be transferred as a unit from the initial growth substrate to a second substrate (e.g., a backplane) to provide the direct view display device. This may provide functional multicolor light emitting device pixels to be transferred to the second substrate without requiring subsequent backend processing steps to form contact electrodes for the pixels or to transfer each color LEDs separately from different growth substrates to the same backplane.

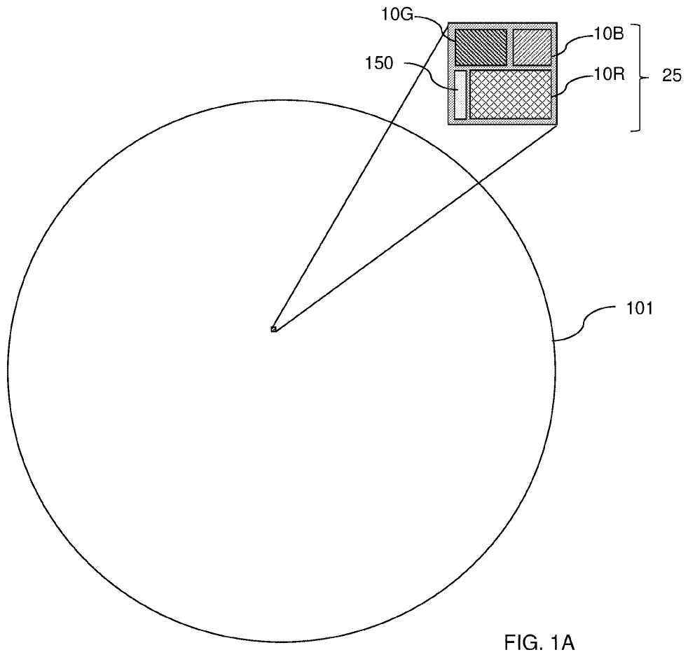

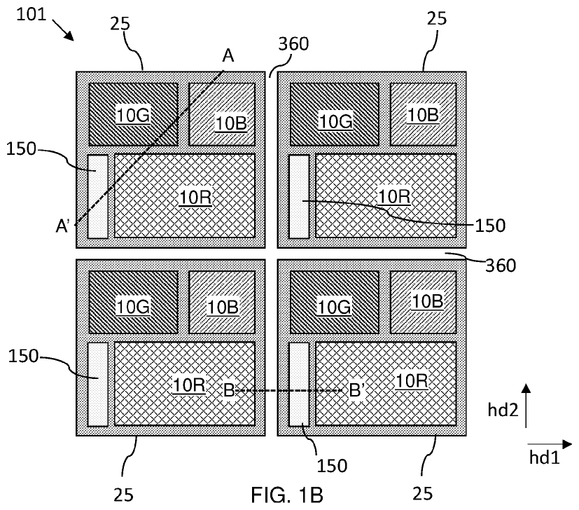

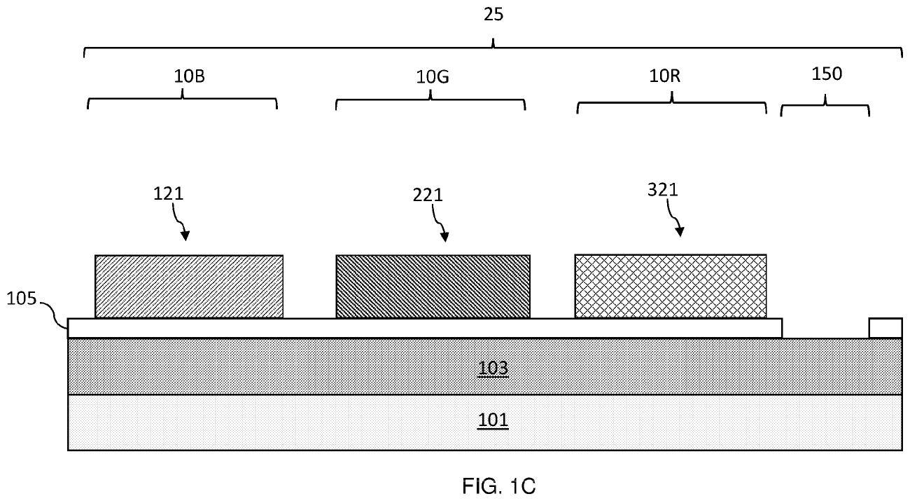

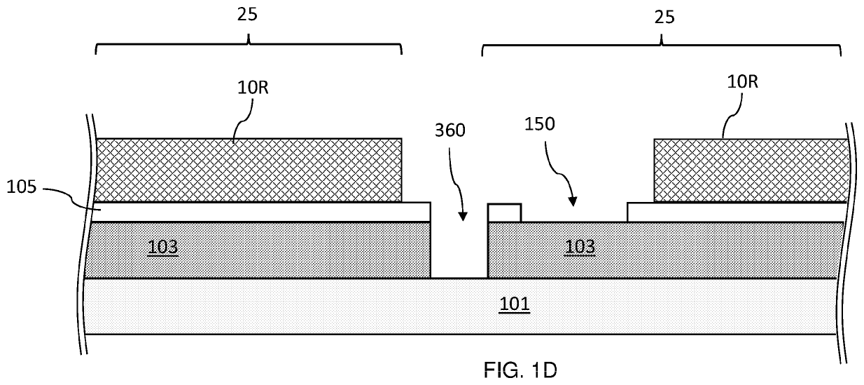

FIG. 1A illustrates a substrate 101 on which an array of pixels 25 is fabricated. FIG. 1B is an enlarged view of a portion of a substrate 101 that includes four pixels 25. Each pixel 25 can include a plurality of subpixels (10B, 10G, 10R), each of which includes light emitting epitaxial semiconductor structures configured to emit light at a respective wavelength. Each pixel 25 can include light emitting diodes that emit light at different wavelengths. For example, each pixel 25 can include at least one first-type light emitting diode 10B (such as at least one blue-light-emitting diode) that emits light at a first peak wavelength (such as a peak wavelength in a range from 400 nm to 495 nm), at least one second-type light emitting diode 10G (such as at least one green-light-emitting diode) that emits light at a second peak wavelength (such as a peak wavelength in a range from 495 nm to 570 nm), and at least one third-type light emitting diode 10R (such as at least one red-light-emitting diode 10R) that emits light at a third peak wavelength (such as a peak wavelength in a range from 600 nm to 700 nm). The number of each type of light emitting diodes within a pixel 25 can be selected to provide a suitable level of illumination per pixel. For example, plural epitaxial semiconductor structure LEDs which emit green, blue and red light are formed in each respective green, blue and red light emitting areas of the pixel 25. Optionally, a portion of the pixel 25 may be left vacant as a repair site for later attaching a repair LED device to compensate for a defective or non-functioning LED device 10G, 10B or 10R in a particular pixel 25. A vacant site may be employed for one or more additional functionalities for a display device such as touch recognition through use of an infrared photodiode sensor.

In some embodiments, an array of closely packed pixels 25, each having an identical structure, may be formed on the substrate 101. Each pixel 25 may include plurality of subpixels (10B, 10G, 10R) configured to emit light at different peak wavelengths. Each pixel 25 may be electrically isolated from the adjacent pixels 25 of the array, as described in more detail below. In some embodiments, the space separating adjacent pixels 25 of the array may be less than about 10 μm, such as less than about 5 μm (e.g., ≤2 μm), including less than about 1 μm, such as 500 nm to 2 μm, although greater and lesser space may separate adjacent pixels 25 of the array.

In some embodiments, the dimensions and/or shapes of the individual subpixels (10B, 10G, 10R) within each pixel 25 may be customized to compensate for differences in light output efficiencies of the different subpixels. For example, in the embodiment shown in FIGS. 1A and 1B, the red-emitting subpixel 10R has a larger horizontal cross-sectional area than the corresponding horizontal cross-section areas of the green-emitting subpixel 10G and the blue-emitting subpixel 10B. The larger area of the red-emitting subpixel 10R relative to each of the blue- and green-emitting subpixels 10B and 10G may help to compensate for a relatively lower light output efficiency of the red-emitting LED. In the embodiment of FIGS. 1A and 1B, the green-emitting subpixel 10G has a larger horizontal cross-section area than the blue-emitting subpixel 10B, although in other embodiments the green-emitting subpixel 10G and the blue-emitting subpixel may have the same area. Other suitable configurations for the subpixels (10B, 10G, 10R) are within the contemplated scope of the disclosure. In some embodiments, the space separating the adjacent subpixels (10B, 10G, 10R) with a pixel 25 may be less than about 10 μm, such as less than about 5 μm (e.g., ≤2 μm), including less than about 1 μm, although greater and lesser space may separate each of the adjacent subpixels (10B, 10G, 10R).

Each pixel 25 may also include a contact region 150. The contact region 150 may be a region within the pixel 25 that does not include a light emitting device and that may be utilized to provide an electrical connection between the multicolor pixel 25 and a backplane to which the multicolor pixel 25 is subsequently transferred. In the embodiment of FIGS. 1A and 1B, within each pixel 25, the blue-emitting subpixel 10B and the green-emitting subpixel 10G are located adjacent to one another along a first horizontal direction hd1, and the red-emitting subpixel 10R and the contact region 150 are located adjacent to each other along the first horizontal direction hd1 and are laterally spaced from the blue-emitting subpixel 10B and the green-emitting subpixel 10G along a second horizontal direction hd2 that is perpendicular to the first horizontal direction hd1. Other configurations of the layout of each multicolor pixel 25 are within the contemplated scope of disclosure. In one embodiment shown in FIG. 1B, the adjacent pixels 25 may be separated from each other by isolation trenches 360. The isolation trenches 360 may extend along the first and the second horizontal directions.

FIG. 1C is a vertical cross-section view of a multicolor pixel 25 taken along line A-A′ in FIG. 1B. Referring to FIC. 1C, each subpixel (10B, 10G, 10R) may include a semiconductor material layer 103 having a doping of a first conductivity type, which may be n-type or p-type, over the substrate 101. The semiconductor material layer 103 may also be referred to as a first conductivity-type doped semiconductor layer 103. In some embodiments, the first conductivity-type doped semiconductor layer 103 may extend continuously over the entire area of the pixel 25. One or more optional layers 105, such as a superlattice structure and/or a spacer layer as described in further detail below, may be located over the first conductivity-type doped semiconductor layer 103. Each of the subpixels (10B, 10G, 10R) may include an epitaxial structure 121, 221, 321 formed over the first conductivity-type doped semiconductor layer 103 and the one or more optional layers 105. As discussed in further detail below, each of the epitaxial structures 121, 221, 321 may include an active region configured to emit light having a different peak wavelength, and a semiconductor material layer having a doping of a second conductivity type which is the opposite of the first conductivity type, located over the active region. For example, if the first conductivity type is n-type, then the second conductivity type is p-type. The semiconductor material layer having a doping of the second conductivity type may also be referred to as a second conductivity-type doped semiconductor layer. Thus, each subpixel (10B, 10G, 10R) may be formed by a portion of the continuous first conductivity-type doped semiconductor layer 103 and one or more optional layers 105 and a discrete epitaxial structure 121, 221, 321 formed over the continuous first conductivity-type doped semiconductor layer 103 and the one ore more optional layers 105.

The pixel 25 may also include the contact region 150 in which the first conductivity-type doped semiconductor layer 103 is exposed (i.e., the one or more optional layers 105 are not present in the contact region 150 such that an upper surface of the first conductivity-type doped semiconductor layer 103 is exposed in the contact region 150). In embodiments in which the first conductivity type is n-type, the contact region 150 may provide a local n-side (i.e., cathode-side) electrical contact region for the multicolor pixel 25. In some embodiments, a contact electrode (not shown in FIG. 1C) comprising an electrically conductive material may be formed over at least a portion of the contact region 150 in each pixel 25.

FIG. 1D is a vertical cross-section view of a portion of the substrate 101 including a pair of adjacent pixels 25 taken along line B-B′ in FIG. 1B. In some embodiments, adjacent pixels 25 of the substrate 101 may be electrically isolated from one another by an isolation trench 360 extending between adjacent pixels 25 and around the outer periphery of each of the pixels 25. The substrate 101 may be exposed at the bottom of the isolation trench 360.

At least a portion of the pixels 25 including the subpixels (10B, 10G, 10R) may be subsequently transferred from the substrate 101 to a backplane to provide a display device, such as a direct view display device, as will be described in more detail below. As used herein, a direct view display device refers to a display device in which each pixel 25 includes at least one light source that generates light from within upon application of a suitable electrical bias which may be viewed by an observer. Thus, a direct view display device does not require a back light unit or a liquid crystal material. As used herein, a “multicolor” pixel refers to a pixel that can emit light of different peak wavelengths depending on application of electrical bias, and thus, inherently capable of displaying multiple colors.

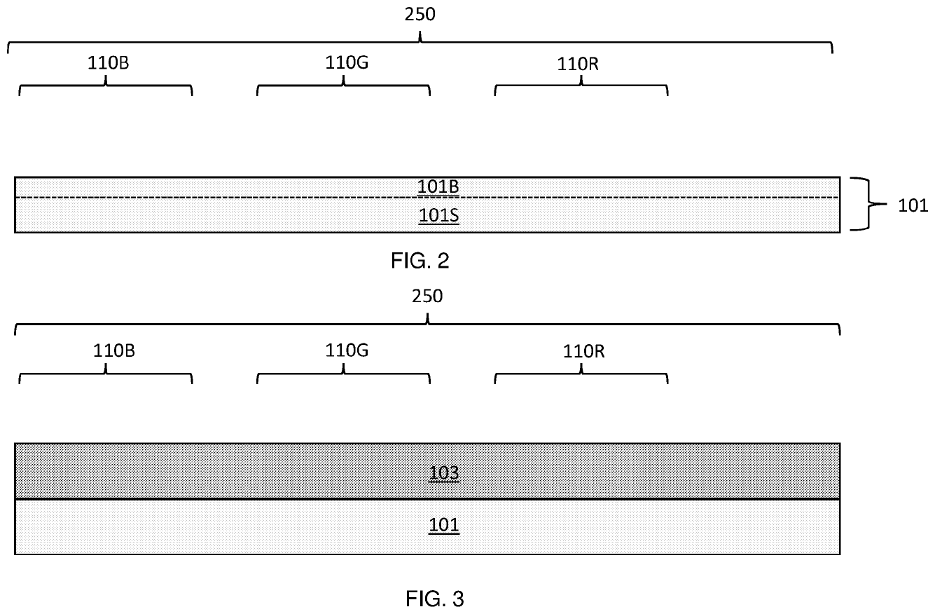

FIGS. 2-28 are sequential vertical cross-section views illustrating a process of fabricating monolithic multicolor light emitting device pixels 25 as shown in FIGS. 1A-ID. The process shown in FIGS. 2-28 includes forming a multicolor light emitting device pixels 25 on a common substrate 101 using a selective growth process in which subpixels (10B, 10G, 10R) that emit light having different peak wavelengths are sequentially formed within each pixel 25. For example, a first plurality of light emitting device structures (i.e., subpixels) that emit a first color light (e.g., blue light) may be formed on the substrate 101, a second plurality of light emitting device structures (i.e., subpixels) that emit a second color light (e.g., green light) may be subsequently formed on the substrate 101, and a third plurality of light emitting device structures (i.e., subpixels) that emit a third color light (e.g., red light) may be subsequently formed on the substrate 101 to provide an array of multicolor pixels 25, where each pixel 25 may include an instance of a blue light-emitting subpixel (10B), an instance of a green light-emitting subpixel (10G) and an instance of a red light-emitting subpixel (10R). Each pixel 25 of the array may also include an above-described contact region 150. It will be understood that other fabrication methods may be used to form an array of multicolor pixels 25 on a common substrate 101. For example, in some embodiments, light emitting device structures having different peak emission wavelengths (i.e., subpixels) may be formed simultaneously (i.e., in the same growth step) on a common substrate utilizing a growth mask containing a pattern of non-uniform growth apertures that are configured to selectively grow light emitting structures having different properties in terms of size, geometry, spacing and/or distribution over the substrate to provide for different color light emission as is described in U.S. Pat. No. 10,304,992 to Ohlsson et al., the entire teachings of which are incorporated herein by reference.

Referring to FIG. 2, a first exemplary structure is illustrated, which is an in-process structure for fabricating monolithic multicolor light emitting device pixels 25 as shown in FIG. 1A-1D. As used herein, an “in-process” structure refers to a structure that is subsequently modified to make a final structure. FIG. 2 is a vertical cross-section view of a pixel region 250 of a substrate 101 on which a multicolor light emitting pixel 25 may be subsequently formed. The pixel region 250 may include subpixel regions 110B, 110G and 110B in which a respective blue-emitting subpixel 10B, a green-emitting subpixel 10G and a red-emitting subpixel 10R may be subsequently formed. Thus, the vertical cross-section view of FIG. 2 illustrates a portion of the substrate 101 taken along line A-A′ in FIG. 1B prior to the formation of an array of multicolor light emitting device pixels 25.

Referring again to FIG. 2, the substrate 101, which may also be referred to as an initial growth substrate 101, may include a single crystalline material layer that functions as a template for subsequent epitaxial growth of semiconductor material layer(s) over the substrate 101. Any single crystalline material layer can be employed for the initial growth substrate 101 provided that epitaxial growth of a compound semiconductor material, such as a III-V compound semiconductor material, from the planar surface of the single crystalline material layer is possible. As used herein, a “planar” surface refers a two-dimensional Euclidean surface without a curvature. The initial growth substrate 101 can include a single crystalline material such as Al₂O₃ (sapphire) using either c-plane or r-plane growing surfaces, diamond, Si, Ge, GaN, AlN, SiC, InN, GaP, GaAsP, GaAs, InP, ZnO, ZnS, and ZnSe. For example, the growth substrate 101 may include sapphire (i.e., single crystalline aluminum oxide) with a suitable surface orientation.

In some embodiments, the initial growth substrate 101 may include a single side polished (SSP) sapphire substrate or a patterned sapphire substrate (PSS) having a patterned (e.g., rough) growth surface. Alternatively, a patterned silicon or silicon carbide substrate may be used. Bumps, dimples, and/or angled cuts may, or may not, be provided on the planar surface of the growth substrate 101 to facilitate epitaxial growth of semiconductor material layer(s) over the growth substrate 101 and/or to facilitate separation of semiconductor device structures (e.g., LEDs) from the growth substrate 101 in a subsequent separation process.

In an optional embodiment, the growth substrate 101 may comprise an undoped semiconductor buffer layer 101B located on a top surface of the sapphire substrate portion 101S. The undoped semiconductor buffer layer 101B may comprise undoped (e.g., intrinsic) III-V compound semiconductor material, which may include a III-nitride semiconductor material, that is epitaxially grown on the sapphire substrate portion 101S. In one non-limiting example, the buffer layer 101B may be composed of GaN. Other suitable III-V compound semiconductor material buffer layers 101B that can be epitaxially grown on the sapphire substrate portion 101S are within the contemplated scope of disclosure.

FIG. 3 is a vertical cross-section view of the first exemplary structure including a continuous doped semiconductor material layer 103 formed over the initial growth substrate 101 according to various embodiments of the present disclosure. As used herein, a “continuous” layer refers to an unpatterned material layer that is not divided into multiple portions. As such, each point in a continuous layer can be connected entirety with points located within the continuous layer. The continuous doped semiconductor material layer 103 may include a III-V compound semiconductor material, which may include a III-nitride semiconductor material, that is epitaxially grown on the initial growth substrate 101 (e.g., on the undoped semiconductor buffer layer 101B if present, or on the sapphire substrate portion 101S if the buffer layer 101B is omitted). In one non-limiting example, the continuous doped semiconductor material layer 103 may be composed of GaN. Other suitable III-V compound semiconductor materials that can be epitaxially grown on the initial growth substrate 101 are within the contemplated scope of disclosure. The continuous doped semiconductor material layer 103 may have a doping of a first conductivity type, which may be n-type or p-type. The continuous doped semiconductor material layer 103 may also be referred to as a first conductivity-type doped semiconductor layer 103. The continuous doped semiconductor material layer 103 may be formed over the initial growth substrate 101 using a suitable deposition process, such as metalorganic vapor phase epitaxy (MOVPE), molecular beam epitaxy (MBE), hydride vapor phase epitaxy (HVPE), liquid phase epitaxy (LPE), metal-organic molecular beam epitaxy (MOMBE), and/or atomic layer deposition (ALD). Other suitable deposition processes are within the contemplated scope of disclosure.

In some embodiments, the continuous doped semiconductor material layer 103 may be formed via an initial nucleation growth of an III-V compound semiconductor material (e.g., GaN) over the surface of the initial growth substrate 101 that may be undoped or lightly doped with dopant(s) of the first conductivity type. Then, the III-V compound semiconductor material having a relatively higher concentration of dopant(s) of the first conductivity type may be epitaxially grown over the initial nucleation growth. The continuous doped semiconductor material layer 103 may be formed of a single crystalline III-V compound semiconductor material (e.g., single crystal GaN). In some embodiments, a thickness of the continuous doped semiconductor material layer 103 may be between about 2 μm and about 5 μm, although greater and lesser thicknesses for the continuous doped semiconductor material layer 103 may be utilized.

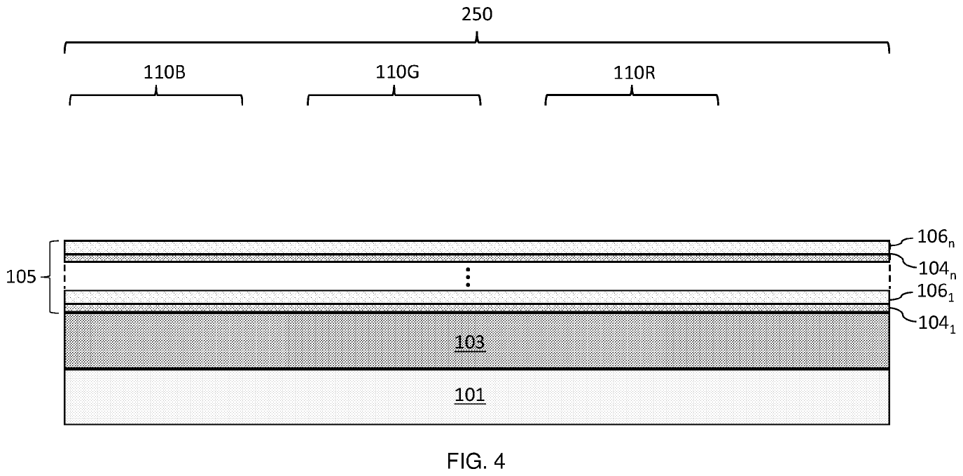

FIG. 4 is a vertical cross-section view of the first exemplary structure including a continuous superlattice structure 105 formed over the continuous doped semiconductor material layer 103 according to various embodiments of the present disclosure. The continuous superlattice structure 105 may be formed of alternating layers a first III-V compound semiconductor material and a second III-V compound semiconductor material having a different composition than the first III-V compound semiconductor material. In one non-limiting embodiment, the first III-V compound semiconductor material may be InₓGa₁₋ₓN, where 0.01≤x≤0.1 (e.g., x≈0.03), and the second III-V compound semiconductor material may be GaN. Thus, in the embodiment shown in FIG. 4, a first instance of the continuous superlattice structure 105 may include a continuous InGaN layer 104₁ formed over the continuous doped semiconductor material layer 103, and a continuous GaN layer 106₁ formed over the continuous InGaN layer 104₁. Additional instances of the continuous superlattice structure 105 may be subsequently formed such that the continuous superlattice structure 105 may include a layer stack including n instances of a continuous InGaN layer 104 and a continuous GaN layer over the continuous InGaN layer, where n may be an integer in a range between 20 and 50.

Each of the alternating layers 104, 106 of the first III-V compound semiconductor material and the second III-V compound semiconductor material forming the continuous superlattice structure 105 may be formed using a suitable deposition process as described above. In some embodiments, each layer 104 of the first III-V compound semiconductor material (e.g., InGaN) may have a thickness in a range of 1-2 nm, and each layer 106 of the second III-V compound semiconductor material (e.g., GaN) may have a thickness in a range of 4-6 nm, although it will be understood that greater or lesser thicknesses may be utilized. In various embodiments, the continuous superlattice structure 105 may function to suppress dislocation density in epitaxial semiconductor material layers that are subsequently formed over the continuous superlattice structure 105.

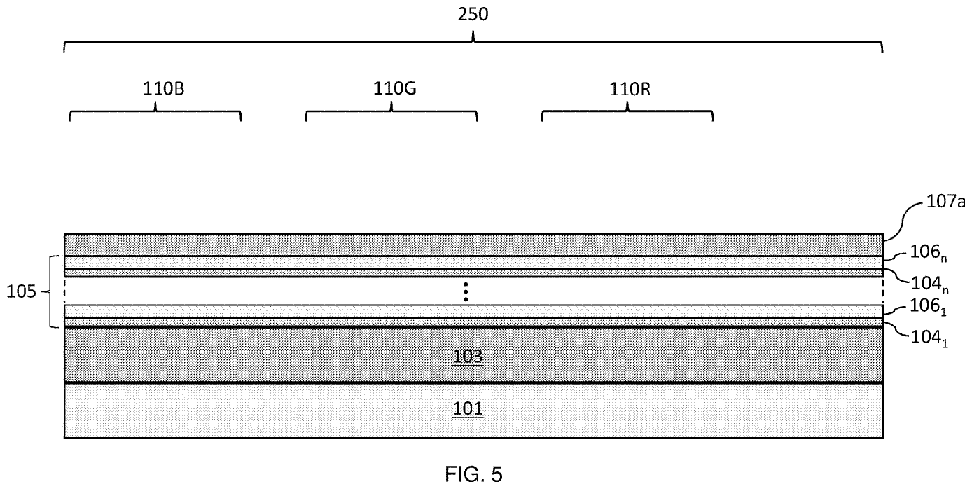

FIG. 5 is a vertical cross-section view of the first exemplary structure including an optional continuous lower spacer layer 107a formed over the continuous superlattice structure 105 according to various embodiments of the present disclosure. The continuous lower spacer layer 107a may include a III-V compound semiconductor material, such as GaN, that is epitaxially grown over the continuous superlattice structure 105. The continuous lower spacer layer 107a may be formed using a suitable deposition process as described above. In some embodiments, the continuous lower spacer layer 107a may be formed of the same III-V compound semiconductor material as the continuous doped semiconductor material layer 103 (e.g., GaN). The continuous lower spacer layer 107a may be lightly doped with dopant(s) of the first conductivity type. In some embodiments, an average concentration of dopants of the first conductivity type present in the continuous lower spacer layer 107a may be less than an average concentration of dopants of the first conductivity type present in the continuous doped semiconductor material layer 103. The continuous lower spacer layer 107a may have a thickness in a range of about 5-25 nm, although greater and lesser thicknesses may be utilized. Alternatively, the continuous lower spacer layer 107a may be omitted.

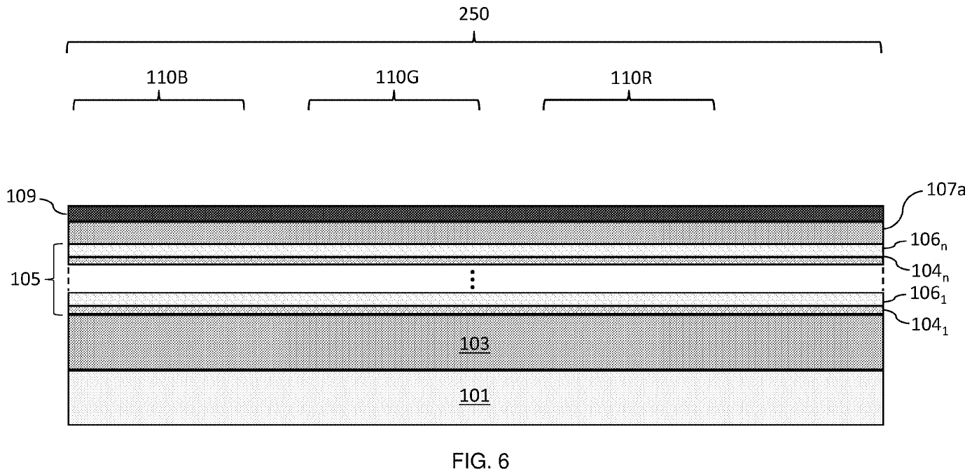

FIG. 6 is a vertical cross-section view of the first exemplary structure including a continuous first dielectric material layer 109 formed over the continuous lower spacer layer 107a (if present, or directly on the superlattice 105 of the lower spacer layer 107a is omitted) according to various embodiments of the present disclosure. The continuous first dielectric material layer 109 may be composed of a suitable dielectric material, such as aluminum oxide, silicon oxide, silicon nitride, etc., including combinations thereof. The continuous first dielectric material layer 109 may be deposited using a suitable deposition process, such as plasma-enhanced chemical vapor deposition (PECVD), high-density plasma chemical vapor deposition (HDPCVD), atomic layer deposition (ALD), and combinations thereof. Other suitable deposition processes are within the contemplated scope of disclosure. The continuous first dielectric material layer 109 may have a thickness in a range of about 10-100 nm, although greater and lesser thicknesses may also be utilized. In various embodiments, the upper surface of the continuous first dielectric material layer 109 may be composed of a dielectric material that minimizes or prevents epitaxial growth of a III-V compound semiconductor material over the continuous first dielectric material layer 109 in a subsequent deposition process.

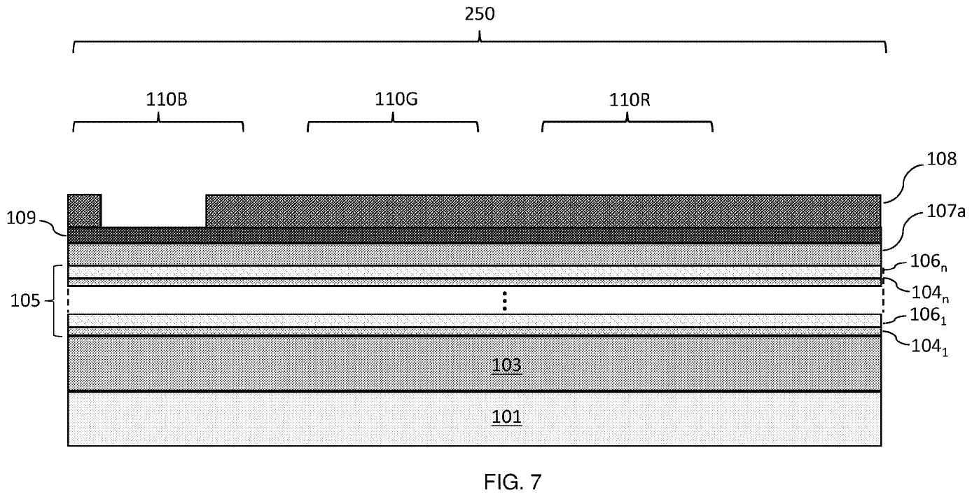

FIG. 7 is a vertical cross-section view of the first exemplary structure including a patterned mask 108 formed over the continuous first dielectric material layer 109 according to various embodiments of the present disclosure. The patterned mask 108 may be formed by applying a layer of photoresist over the continuous first dielectric material layer 109 and lithographically patterning the layer of photoresist to form one or more openings therethrough by lithographic exposure and development. Each opening through the patterned mask 108 may be located in a subpixel region 110B of the first exemplary structure corresponding to a location in which subpixels 10B of the same type (i.e., subpixels which emit light of the same color) may be subsequently formed. In the embodiment of FIG. 7, the one or more openings be located in subpixel regions 110B in which blue-emitting subpixels 10B may be subsequently formed, although it will be understood that the one or more openings may alternatively be located in subpixel regions 110G or 110R. Thus, although a single opening through the patterned mask 108 is illustrated in FIG. 7, it will be understood that each pixel region 250 of the first exemplary structure may include an opening through the patterned mask 108, where the opening may be located in a subpixel region 110B within which subpixels 10B of the same type are subsequently formed.

The size and shape of each opening through the patterned mask 108 may be selected to optimize the shape and size of epitaxial semiconductor structures to be subsequently formed in subpixel regions 110B. For example, the openings through the patterned mask 108 can have polygonal shapes (such as triangles, rectangles (including squares), pentangles, hexagons, heptagons, etc.), circular shapes, elliptical shapes, and/or any other generally curvilinear closed two-dimensional shapes. In an illustrative example, the openings in the patterned mask 108 can have rectangular shapes, triangular shapes, hexagonal shapes, or circular shapes that are arranged as a two-dimensional periodic array.

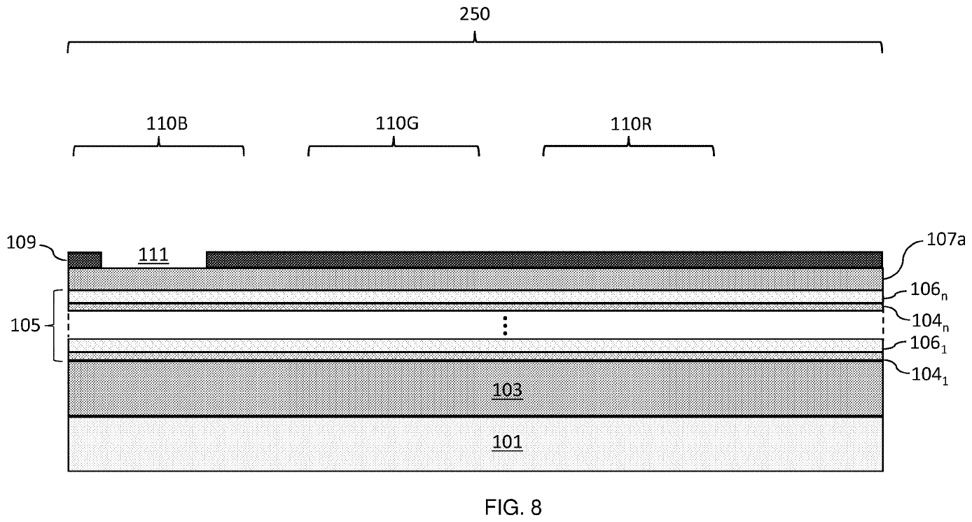

FIG. 8 is a vertical cross-section view of the first exemplary structure including an opening 111 formed through the first dielectric material layer 109 according to various embodiments of the present disclosure. Referring to FIGS. 7 and 8, an etching process, such as a wet etching process and/or a dry etching process, may be performed to remove portions of the continuous first dielectric material layer 109 exposed through the openings in the patterned mask 108 and thereby transfer the pattern of the openings in the patterned mask 108 to the first dielectric material layer 109. The upper surface of the lower spacer layer 107a may be exposed in the bottom of each of the openings 111 in the first dielectric material layer 109. Thus, the first dielectric material layer 109 may function as a patterned growth mask that may enable selective epitaxial growth of semiconductor structures over the exposed upper surface of the lower spacer layer 107a within each of the subpixel regions 110B of the same type (e.g., the subpixel regions 110B corresponding to the locations of blue-emitting subpixels 10B in the embodiment of FIG. 8). Following the etching process, the patterned mask 108 may be removed using a suitable process, such as by ashing and/or dissolution with a solvent.

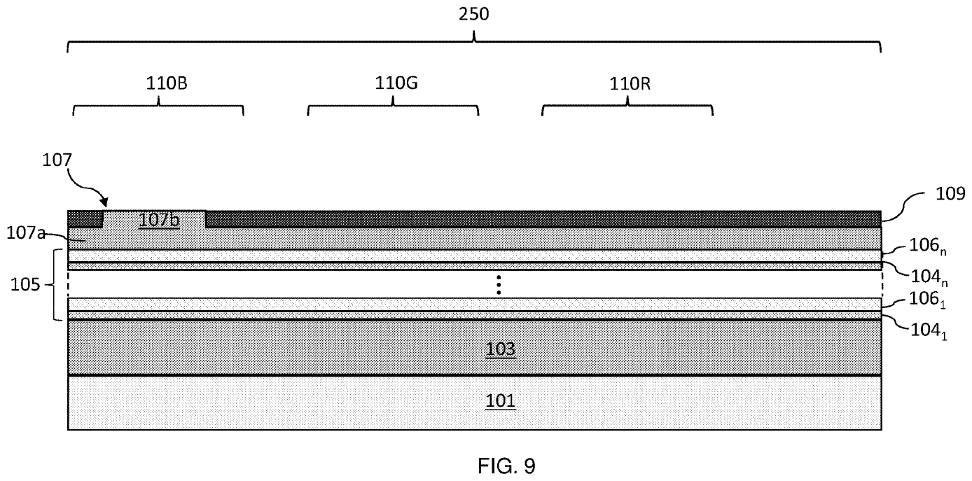

FIG. 9 is a vertical cross-section view of the first exemplary structure including an optional upper spacer layer 107b formed over the continuous lower spacer layer 107a according to various embodiments of the present disclosure. The upper spacer layer 107b may include a III-V compound semiconductor material. In various embodiments, the upper spacer layer 107b may be composed of the same material as the material of the continuous lower spacer layer 107a, such as GaN that is lightly doped with dopant(s) of the first conductivity type. The upper spacer layer 107b may be formed using a selective semiconductor deposition process that grows semiconductor material from semiconductor surfaces and does not grow the semiconductor material from dielectric surfaces. Thus, the semiconductor material of the upper spacer layer 107b may be selectively grown over the exposed surface of the continuous lower spacer layer 107a within the opening 111 in the first dielectric material layer 109, but there may be minimal or no growth of the semiconductor material of the upper spacer layer 107b over the upper surface of the first dielectric material layer 109. The upper spacer layer 107b may fill at least a portion of the opening 111 in the first dielectric material layer 109. In some embodiments, the upper spacer layer 107b may completely fill the opening 111 in the first dielectric material layer 109 such that the upper surface of the upper spacer layer 107b may be substantially coplanar with the upper surface of the first dielectric material layer 109. The upper spacer layer 107b may be a discrete layer of semiconductor material that contacts the continuous lower spacer layer 107a and is laterally surrounded by the first dielectric material layer 109. Although a single discrete upper spacer layer 107b is shown in FIG. 9, it will be understood that each pixel region 250 of the first exemplary structure may include a discrete upper spacer layer 107b located in a subpixel region 110B in which subpixels 10B of the same type are subsequently formed. The lower spacer layer 107b and each of the upper spacer layers 107a may be considered as forming a single spacer layer 107 including a continuous lower spacer layer portion 107a and one or more discrete upper spacer layer portions 107b having a pedestal-like structure located in each of the subpixel regions 110B of the first exemplary structure.

The upper spacer layer 107b may have a thickness in a range of about 5-25 nm, although greater and lesser thicknesses may be utilized. In some embodiments, a total thickness of the continuous lower spacer layer 107a and the upper spacer layer 107b may be between about 10 nm and about 50 nm, although greater and lesser thicknesses may be employed. Alternatively, the upper spacer layer 107b may be omitted.

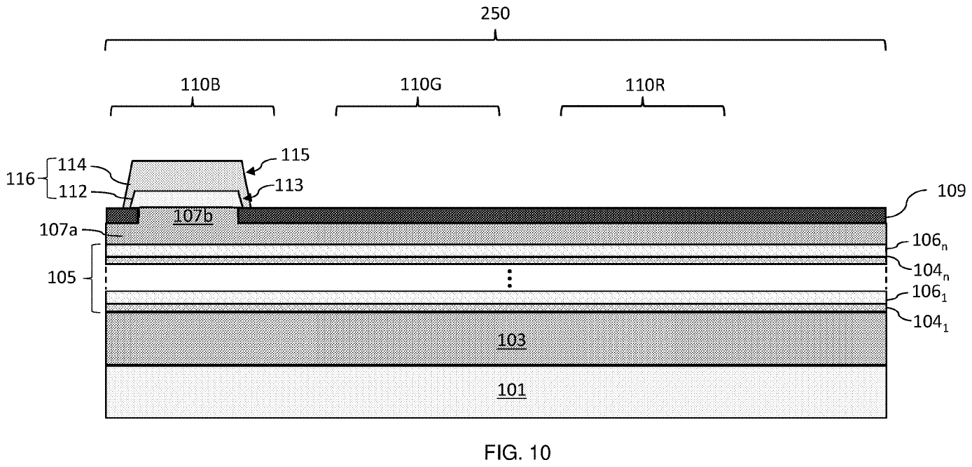

FIG. 10 is a vertical cross-section view of the first exemplary structure including an active region 116 formed over the upper spacer layer 107b (if present) according to various embodiments of the present disclosure. The active region 116 may be formed using a selective semiconductor deposition process that grows semiconductor material from semiconductor surfaces and does not grow the semiconductor material from dielectric surfaces. Thus, the active region 116 may be selectively grown over the upper surface of the upper spacer layer 107b within subpixel region 110B.

The active region 116 may include at least one semiconductor material that emits radiation (e.g., visible light or ultraviolet radiation) upon application of a suitable electrical bias. In one embodiment, the active region 116 includes an optically active compound semiconductor layer stack configured to emit light. For example, the active region 116 can include at least one quantum well (QW) structure (112, 114) that emits light upon application of an electrical bias thereacross. Each quantum well structure (112, 114) of the active region 116 can include at least one instance of a first band gap semiconductor layer 112 having a first band gap and a second band gap semiconductor layer 114 having a second band gap greater than the first band gap located over the first band gap semiconductor layer 112. In some embodiments, the active region 116 can include a layer stack including multiple instances of a quantum well structure including a first band gap semiconductor layer 112 and a second band gap semiconductor layer 114 over the first band gap semiconductor layer 112, such as between 2 and 10 repeating instances of the first band gap semiconductor layer 112 and the second band gap semiconductor layer 114. Alternatively, the active region 116 may include any other suitable semiconductor layers or stack of layers for light emitting diode applications provided that it can be selectively grown over the upper spacer layer 107b. The set of all layers within an active region 116 is herein referred to as an active layer.

In various embodiments, each of the respective layers 112, 114 that form the active region 116 may include a mesa structure including a horizontal planar upper surface and tapered sidewalls 113, 115 extending from the horizontal planar upper surface towards the upper surface of the first dielectric material layer 109. As used herein, a “tapered” element refers to an element that is not horizontal and is not vertical. A width dimension of the mesa structures (i.e., a dimension of the mesa structure within a horizontal plane) may increase between the horizontal planar upper surface of the mesa structures and the upper surface of the first dielectric material layer 109. Each of the respective layers 112, 114 that form the active region 116 may further include a bottom surface. The bottom surfaces of the layers 112, 114 of the active region may be coplanar with one another and may each contact the upper surface of the first dielectric material layer 109. The bottom surface of the lowermost layer of the active region 116 (i.e., layer 112 in FIG. 10) may additionally contact the upper surface of the upper spacer layer 107b.

In the embodiment shown in FIG. 10, the active region 116 formed over the upper spacer layer 107b in subpixel region 110B may be configured to emit blue light having a peak wavelength in range from 400 nm to 495 nm upon application of a suitable electrical bias thereacross. In a non-limiting illustrative example of a blue light emitting active region 116 composed of a quantum well structure, the first band gap semiconductor layer(s) 112 may be composed of In_{z}Ga_{1-z}N, where 0.18≤z≤0.22 (e.g., z≈0.2), and the second band gap semiconductor layer(s) 114 may be composed of GaN. The first band gap semiconductor layer(s) 112 may have a thickness in a range of about 2.5-5 nm (i.e., between the horizontal planar upper surface of the layer 112 and the upper surface of the immediately underlying material layer), and the second band gap semiconductor layer(s) 114 may have a thickness in a range of about 15-20 nm (i.e., between the horizontal planar upper surface of the layer 114 and the upper surface of the immediately underlying material layer), although greater and lesser thicknesses may be employed.

Although a single blue light emitting active region 116 is shown in FIG. 10, it will be understood that each pixel region 250 of the first exemplary structure may include a blue light emitting active region 116 located in a subpixel region 110B of the pixel region 250.

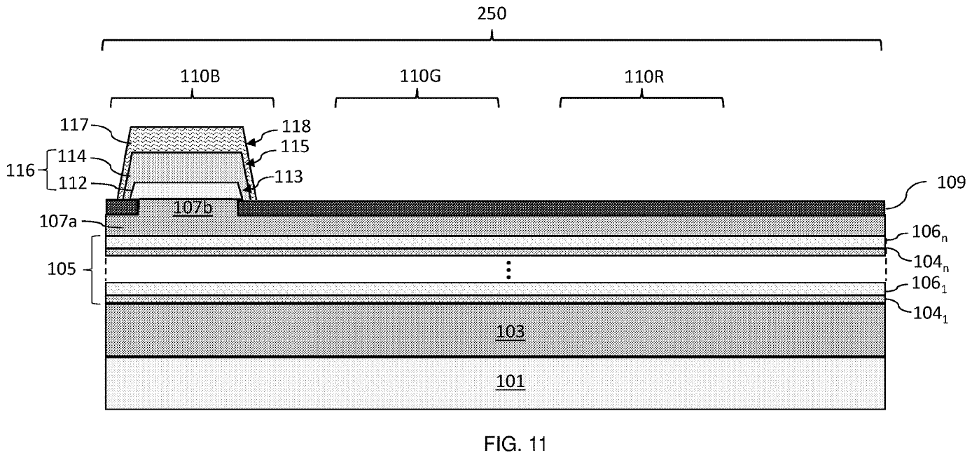

FIG. 11 is a vertical cross-section view of the first exemplary structure including an optional electron blocking layer 117 formed over the active region 116 according to various embodiments of the present disclosure. The electron blocking layer 117 may be composed of a doped semiconductor material having a doping of a second conductivity type, which is the opposite of the first conductivity type. For example, if the first conductivity type is n-type, then the second conductivity type is p-type. If the first conductivity type is p-type, then the second conductivity type is n-type. In some embodiments, the electron blocking layer 117 may include a doped AlGaN material having a doping of the second conductivity type. The electron blocking layer 117 may be formed using a selective semiconductor deposition process that grows semiconductor material from semiconductor surfaces and does not grow the semiconductor material from dielectric surfaces. Thus, the electron blocking layer 117 may be selectively grown over the upper surface and exposed sidewalls 115 of the active region 116 within subpixel region 110B.

The electron blocking layer 117 may include a mesa structure including a horizontal planar upper surface and tapered sidewalls 118 extending from the horizontal planar upper surface towards the upper surface of the first dielectric material layer 109. The tapered sidewalls 118 of the electron blocking layer 117 may laterally surround the active region 116. The width dimension of the mesa structure may increase between the horizontal planar upper surface of the mesa structure and the upper surface of the first dielectric material layer 109. The electron blocking layer 117 may further include a bottom surface that contacts the upper surface of the first dielectric material layer 109 and may be coplanar with the bottom surfaces of each of the layers 112, 114 of the active region 116. The electron blocking layer 117 may have a thickness in a range of about 15-30 nm (i.e., between the horizontal planar upper surface of electron blocking layer 117 and the horizontal planar upper surface of the active region 116), although greater and lesser thicknesses may be employed.

The electron blocking layer 117 may function as a current blocking layer for the angled facets (i.e., sidewalls 113, 115) of the active region 116 and thereby reduce leakage current through the angled facets of the active region 116. This may enable a uniform emission of light with narrow full width at half maximum (FWHM) from the planar c-plane region within the active region 116 and may also promote parallel emission of light along the vertical direction from multiple light emitting subpixels 10B, 10G, 10R of a display device.

Although a single electron blocking layer 117 is shown in FIG. 11, it will be understood that each pixel region 250 of the first exemplary structure may include an electron blocking layer 117 over a blue light emitting active region 116 within a subpixel region 110B of the pixel region 250.

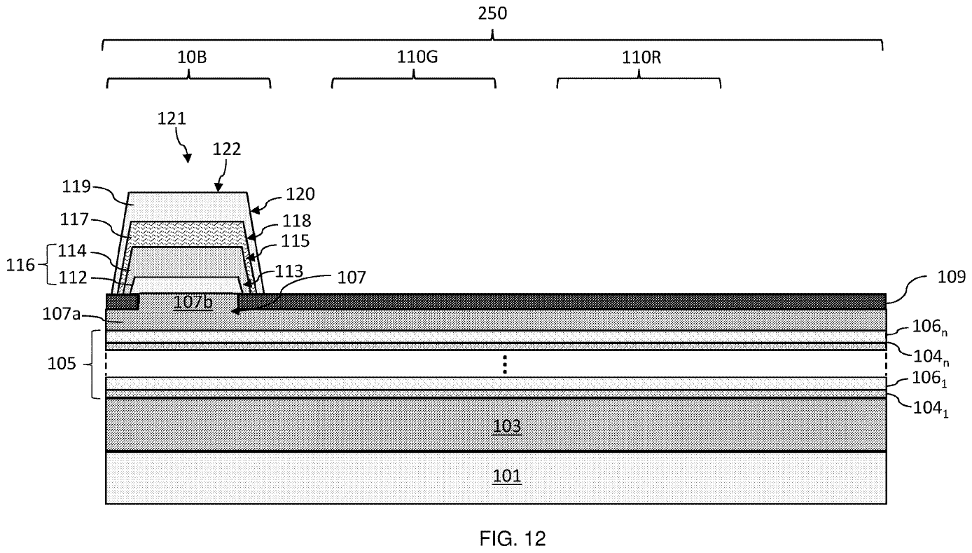

FIG. 12 is a vertical cross-section view of the first exemplary structure including a doped semiconductor material layer 119 formed over the electron blocking layer 117 according to various embodiments of the present disclosure. The doped semiconductor material layer 119 may be composed of a doped semiconductor material having a doping of the second conductivity type. In some embodiments, the doped semiconductor material layer 119 may include a doped III-V compound semiconductor material, such as GaN, having a doping of the second conductivity type. The doped semiconductor material layer 119 may also be referred to as a second conductivity-type doped semiconductor material layer 119. The doped semiconductor material layer 119 may be formed using a selective semiconductor deposition process that grows semiconductor material from semiconductor surfaces and does not grow the semiconductor material from dielectric surfaces. Thus, the doped semiconductor material layer 119 may be selectively epitaxially grown over the upper surface and exposed sidewalls 118 of the electron blocking layer 117 within subpixel region 110B. In embodiments in which the electron blocking layer 117 is omitted, the doped semiconductor material layer 119 may be selectively epitaxially grown over the upper surface and exposed sidewalls 115 of the active region 116 within subpixel region 110B.

The doped semiconductor material layer 119 may include a mesa structure including a horizontal planar upper surface 122 and tapered sidewalls 120 extending from the horizontal planar upper surface towards the upper surface of the first dielectric material layer 109. The tapered sidewalls 120 of the doped semiconductor material layer 119 may laterally surround the electron blocking layer 117 and the active region 116. The width dimension of the mesa structure may increase between the horizontal planar upper surface of the mesa structure and the upper surface of the first dielectric material layer 109. The doped semiconductor material layer 119 may further include a bottom surface that contacts the upper surface of the first dielectric material layer 109 and may be coplanar with the bottom surfaces of each of the layers 112, 114 of the active region 116 and the bottom surface of the electron blocking layer 117. The doped semiconductor material layer 119 may have a thickness in a range of about 50-200 nm (i.e., between the horizontal planar upper surface 122 of the doped semiconductor material layer 119 and the horizontal planar upper surface of the electron blocking layer 117 or of the active region 116 in embodiments that do not include an electron blocking layer 117). Greater and lesser thicknesses for the doped semiconductor material layer 119 are within the contemplated scope of disclosure.

Although a doped semiconductor material layer 119 over an electron blocking layer 117 is shown in FIG. 12, it will be understood that each pixel region 250 of the first exemplary structure may include a doped semiconductor material layer 119 located directly on the active region 116 in embodiments that do not include an electron blocking layer 117 within a subpixel region 110B of the pixel region 250.

Referring again to FIG. 12, a first light emitting epitaxial semiconductor structure 10B (i.e., a subpixel structure) is illustrated in a pixel region 250 of the first exemplary structure. The first light emitting epitaxial semiconductor structure 10B may be capable of emitting light of a first color (e.g., blue) upon application of a suitable electrical bias. The first light emitting epitaxial structure 10B includes an optional first conductivity-type doped semiconductor layer 103 over an initial growth substrate 101, an optional superlattice structure 105 over the first conductivity-type doped semiconductor layer 103, a spacer layer 107 over the superlattice structure 105 that includes a lower portion 107a and an upper portion 107b that forms a pedestal-like structure over the lower portion 107a of the spacer layer 107. A first dielectric material layer 109 is located over the upper surface of the lower portion 107a of the spacer layer 107 and laterally surrounds the upper portion 107b of the spacer layer 107.

The first light emitting epitaxial semiconductor structure 10B further includes a mesa portion 121 over the upper portion 107b of the spacer layer 107 and a portion of the dielectric material layer 109. The mesa portion 121 includes a planar horizontal lower surface contacting the upper portion 107b of the spacer layer 107 and the upper surface of the first dielectric material layer 109, a planar horizontal upper surface 122, and a tapered outer sidewall 120 extending between the planar horizonal upper surface 122 and the planar horizontal lower surface of the mesa portion 121. The mesa portion 121 in the embodiment of FIG. 12 includes an active region 116, an optional electron blocking layer 117 over the upper surface of and laterally surrounding the active region 116, and a second conductivity-type doped semiconductor material layer 119 over the upper surface of and laterally surrounding the electron blocking layer 117. A plurality of mesa portions 121 as shown in in FIG. 12 may be located over the upper portion 107a of the spacer layer 107, where each mesa portion 121 may form a portion of a first light emitting epitaxial semiconductor structure 10B located within a pixel region 250 of the first exemplary structure.

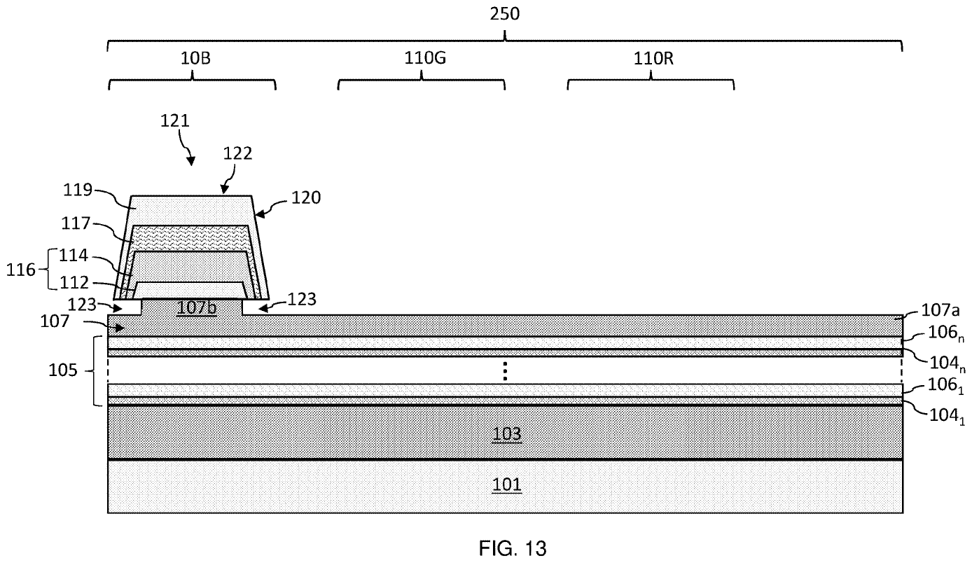

FIG. 13 is a vertical cross-section view of the first exemplary structure following an etching process to remove the first dielectric material layer 109 according to various embodiments of the present disclosure. Referring to FIG. 13, a selective etching process may be used to selectively remove the first dielectric material layer 109 and expose the upper surface of the lower portion 107a of the spacer layer 107. The etching process may also provide a recess 123 between the mesa portion 123 of the first light emitting epitaxial semiconductor structure 10B and the upper surface of the lower portion 107a of the spacer layer 107. The recess 123 may surround the upper portion 107b of the spacer layer 107. The recess 123 may be vertically bounded by the upper surface of the lower portion 107a of the spacer layer 107 and the lower surface of the mesa portion 121 (e.g., the bottom surfaces of the active region 116, the electron blocking layer 117, and the second conductivity-type doped semiconductor material layer 119). The upper portion 107b of the spacer layer 107 may form the sidewall of the recess 123.

In various embodiments, the first dielectric material layer 109 may be removed using a suitable etching process, such as a wet chemical etching process. In some embodiments, the etching process may include multiple etching steps utilizing different etch chemistries that are optimized to selectively remove material(s) from the first exemplary structure. For example, an initial etch may be performed to remove residual semiconductor material from over the upper surface of the first dielectric material layer 109. The initial etch may be a wet chemical etch, such as a potassium hydroxide (KOH)-based etch. The mesa portion 121 of the first light emitting epitaxial semiconductor structure 10B may optionally be covered by a mask during the etching process to protect the mesa portion 121 from being etched. A subsequent anisotropic etching step may then be used to remove the first dielectric material layer 109. The subsequent etching step may utilize a different etch chemistry, such as a hydrofluoric acid (HF)-based etch and/or a hot phosphoric acid-based etch, that is optimized to selectively remove the dielectric material (e.g., silicon oxide and/or silicon nitride, respectively) of the first dielectric material layer 109.

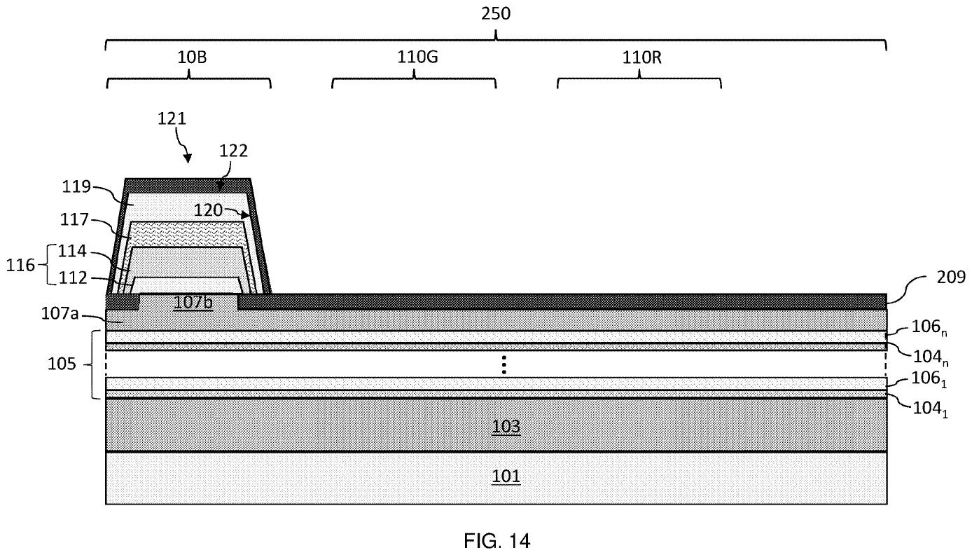

FIG. 14 is a vertical cross-section view of the first exemplary structure including a continuous second dielectric material layer 209 formed over the lower portion 107a of the spacer layer 107 and over the side surfaces 120 and upper surface 122 of the mesa portion 121 of the first light emitting epitaxial semiconductor structure 10B according to various embodiments of the present disclosure. The continuous second dielectric material layer 209 may be composed of a suitable dielectric material, such as aluminum oxide, silicon oxide, silicon nitride, etc., including combinations thereof. The material of the continuous second dielectric material layer 209 may be the same or a different material than the material of the first dielectric material layer 109. The continuous second dielectric material layer 209 may be deposited using a suitable deposition process, such as plasma-enhanced chemical vapor deposition (PECVD), high-density plasma chemical vapor deposition (HDPCVD), atomic layer deposition (ALD), and combinations thereof. Other suitable deposition processes are within the contemplated scope of disclosure. In various embodiments, the continuous second dielectric material layer 209 may be deposited using a conformal deposition process, such as ALD. Thus, the continuous second dielectric material layer 209 may have a relatively uniform thickness over the upper surface of the lower portion 107a of the spacer layer 107, over the side surface of the upper portion 107a of the spacer layer 107 and the bottom surface of the mesa portion 121 exposed in the recess 121, and over the tapered outer sidewalls 120 and the horizontal planar upper surface 122 of the mesa portion 121. In some embodiments, the continuous second dielectric material layer 209 may completely fill the recess 123 between the spacer layer 107 and the bottom surface of the mesa portion 123. The continuous second dielectric material layer 209 may have a thickness in a range of about 10-100 nm, although greater and lesser thicknesses may also be utilized. In various embodiments, the upper surface of the continuous second dielectric material layer 209 may be composed of a dielectric material that minimizes or prevents epitaxial growth of a III-V compound semiconductor material over the continuous second dielectric material layer 209 in a subsequent deposition process.

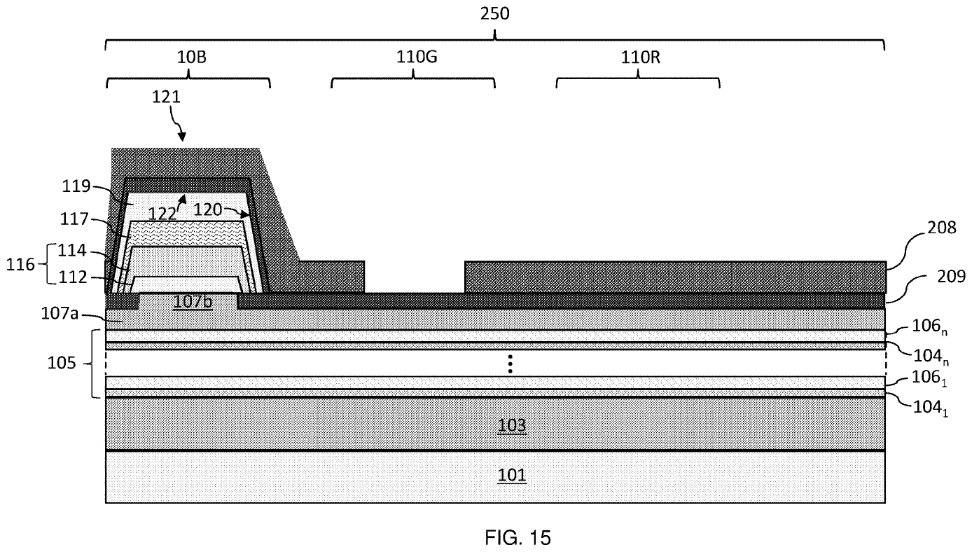

FIG. 15 is a vertical cross-section view of the first exemplary structure including a patterned mask 208 formed over the continuous second dielectric material layer 209 according to various embodiments of the present disclosure. The patterned mask 208 may be formed as described above with reference to FIG. 7. The patterned mask 208 may include an opening through the patterned mask 208 in each subpixel region 110G of the first exemplary structure corresponding to a location in which subpixels 10G of the same type may be subsequently formed. In the embodiment of FIG. 15, the one or more openings are located in subpixel regions 110G in which green-emitting subpixels 10G may be subsequently formed, although it will be understood that the one or more openings may alternatively be located in subpixel regions 110R in which red-emitting subpixels 10R may be subsequently formed, or in subpixel regions 110B in which blue-emitting subpixels 10E may be subsequently formed. Although a single opening through the patterned mask 208 is illustrated in FIG. 15, it will be understood that each pixel region 250 of the first exemplary structure may include an opening through the patterned mask 208, where the opening may be located in a subpixel region 110G within which subpixels 10G of the same type are subsequently formed. As previously described with reference to FIG. 7, the size and shape of each opening through the patterned mask 208 may be selected to optimize the shape and size of epitaxial semiconductor structures to be subsequently formed in subpixel regions 110G.

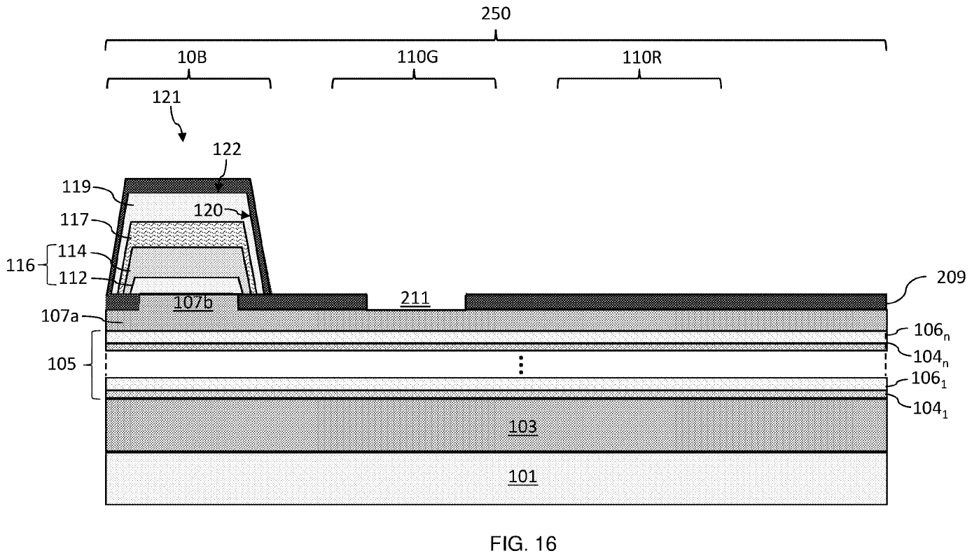

FIG. 16 is a vertical cross-section view of the first exemplary structure including an opening 211 formed through the second dielectric material layer 209 according to various embodiments of the present disclosure. Referring to FIGS. 15 and 16, an etching process as described above with reference to FIGS. 7 and 8 may be remove portions of the continuous second dielectric material layer 209 exposed through the opening(s) in the patterned mask 208 and form one or more openings 211 through the second dielectric material layer 209. The lower portion 107a of the spacer layer 107 may be exposed in the bottom of each of the openings 211. The remaining portion of the second dielectric material layer 209 may function as a patterned growth mask that may enable selective epitaxial growth of semiconductor structures over the exposed upper surface of the lower spacer layer 107a within each of the subpixel regions 110G (e.g., the subpixel regions 110G corresponding to the locations of green-emitting subpixels 10G). Following the etching process, the patterned mask 208 may be removed using a suitable process, such as by ashing and/or dissolution with a solvent.

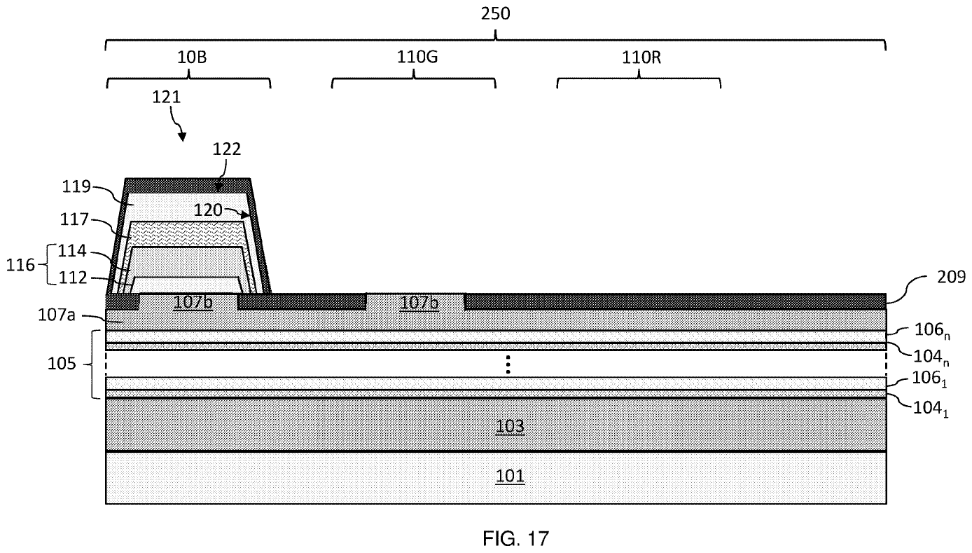

FIG. 17 is a vertical cross-section view of the first exemplary structure including an upper portion 107b of the spacer layer 107 formed within subpixel region 110G according to various embodiments of the present disclosure. In various embodiments, the upper portion 107b of the spacer layer 107 that is formed in subpixel region 110G may be composed of the same material(s) as the material(s) of the lower portion 107a of the spacer layer 107 and/or the upper portion 107a of the spacer layer 107 that is located in subpixel 10B. In some embodiments, the upper portion 107b of the spacer layer 107 that is formed in subpixel region 110G may include GaN that is lightly doped with dopant(s) of the first conductivity type. As described above with reference to FIG. 9, the upper portion 107b of the spacer layer 107 within subpixel region 110G may be selectively grown over the exposed surface of the continuous lower spacer layer 107a within the opening 211 in the second dielectric material layer 209, but there may be minimal or no growth of the semiconductor material over the upper surface of the second dielectric material layer 209. The upper portion 107b of the spacer layer 107 within subpixel region 110G may fill at least a portion of the opening 211 in the second dielectric material layer 209, and may completely fill the opening 211 such that the upper surface of the upper spacer layer 107b may be substantially coplanar with the upper surface of the second dielectric material layer 209. Although a single discrete upper portion 107b of the spacer layer 107 is shown in subpixel region 110G in FIG. 17, it will be understood that each pixel region 250 of the first exemplary structure may include a discrete upper portion 107b of the spacer layer 107 located in a subpixel region 110G in which green light emitting subpixels 10G are subsequently formed. Alternatively, the lower and/or upper portions of the spacer layer 107 may be omitted.

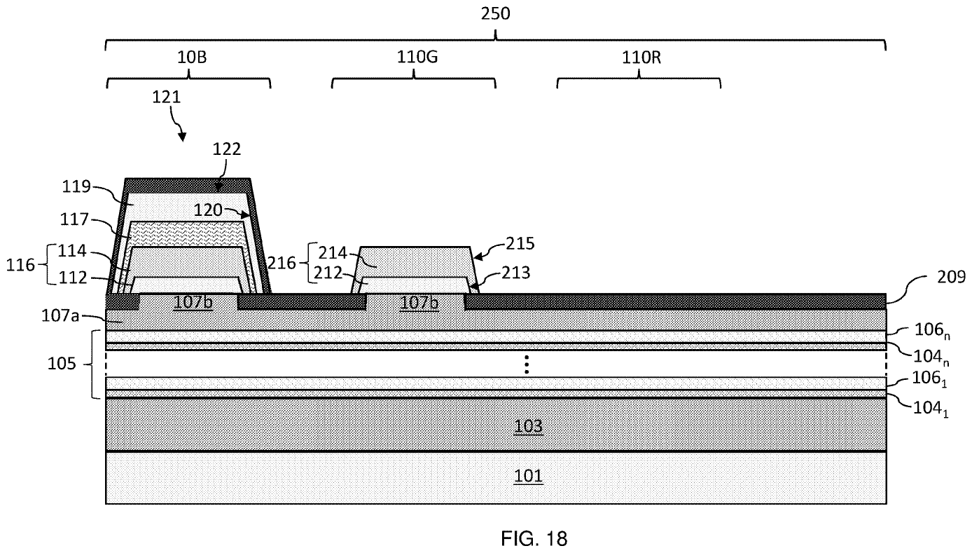

FIG. 18 is a vertical cross-section view of the first exemplary structure including an active region 216 formed over the upper portion 107b of the spacer layer 107 and the second dielectric material layer 209 within subpixel region 110G according to various embodiments of the present disclosure. As with the active region 116 of the blue light emitting subpixel 10B described above, active region 216 may be formed using a selective semiconductor deposition process that enables selective growth of the active region 216 over the upper portion 107b of the spacer layer 107 within subpixel region 110G. The active region 216 in subpixel region 110G may have a similar or identical structure as the active region 116 of subpixel 10B. For example, active region 216 may include an optically active compound semiconductor layer stack configured to emit light, such as at least one above-described quantum well (QW) structure (212, 214) that emits light upon application of an electrical bias thereacross. In some embodiments, the active region 216 can include a layer stack including multiple instances of a quantum well structure including a first band gap semiconductor layer 212 and a second band gap semiconductor layer 214 over the first band gap semiconductor layer 212, such as between 2 and 10 repeating instances of the first band gap semiconductor layer 212 and the second band gap semiconductor layer 214. Alternatively, the active region 216 may include any other suitable semiconductor layers or stack of layers for light emitting diode applications provided that it can be selectively grown over the upper portion 107b of the spacer layer 107. The set of all layers within active region 216 may also be referred to as an active layer.

In various embodiments, each of the respective layers 212, 214 that form the active region 216 may include a mesa structure including a horizontal planar upper surface and tapered sidewalls 213, 215 extending from the horizontal planar upper surface towards the upper surface of the second dielectric material layer 209. A width dimension of the mesa structures (i.e., a dimension of the mesa structure within a horizontal plane) may increase between the horizontal planar upper surface of the mesa structures and the upper surface of the second dielectric material layer 209. Each of the respective layers 212, 214 that form the active region 216 may further include a bottom surface, where the bottom surfaces of the layers 212, 214 may be coplanar with one another and may each contact the upper surface of the second dielectric material layer 209. The bottom surface of the lowermost layer of the active region 216 (i.e., layer 212 in FIG. 18) may additionally contact the upper portion 107b of the spacer layer 107.

In the embodiment shown in FIG. 18, the active region 216 formed in subpixel region 110G may be configured to emit green light having a peak wavelength in range from 495 nm to 570 nm upon application of a suitable electrical bias thereacross. In a non-limiting illustrative example of a green light emitting active region 216 composed of a quantum well structure, the first band gap semiconductor layer(s) 212 may be composed of In_{z}Ga_{1-z}N, where 0.22≤z≤0.24 (e.g., x≈0.23), and the second band gap semiconductor layer(s) 214 may be composed of GaN. In various embodiments, the first band gap semiconductor layer(s) 212 within the active region 216 formed in subpixel region 110G may have a higher concentration of indium than the first band gap semiconductor layer(s) 112 within the blue light emitting subpixels 10B. The first band gap semiconductor layer(s) 212 may have a thickness in a range of about 2.5-5 nm (i.e., between the horizontal planar upper surface of the layer 212 and the upper surface of the immediately underlying material layer), and the second band gap semiconductor layer(s) 214 may have a thickness in a range of about 15-20 nm (i.e., between the horizontal planar upper surface of the layer 214 and the upper surface of the immediately underlying material layer), although greater and lesser thicknesses may be employed.

Although a single green light emitting active region 216 is shown in FIG. 18, it will be understood that each pixel region 250 of the first exemplary structure may include a green light emitting active region 216 located in a subpixel region 110G of the pixel region 250.

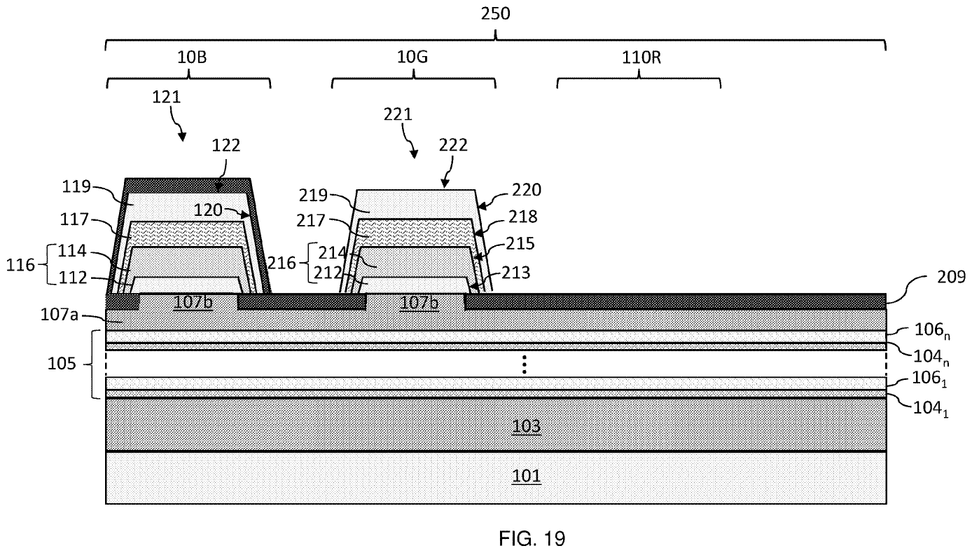

FIG. 19 is a vertical cross-section view of the first exemplary structure including a second light emitting epitaxial semiconductor structure 10G in a pixel region 250 according to various embodiments of the present disclosure. The second light emitting epitaxial semiconductor structure 10G may form a green light emitting subpixel 10G within the pixel region 250. The green light emitting subpixel 10G may be formed by depositing an optional electron blocking layer 217 over the upper surface and sidewalls 215 of the active region 216 and depositing a second conductivity-type doped semiconductor material layer 219 over the upper surface and sidewalls 218 of the electron blocking layer 217. The electron blocking layer 217 may include a doped semiconductor material, such as AlGaN, having a doping of the second conductivity type. The second conductivity-type doped semiconductor material layer 219 may include a doped III-V compound semiconductor material, such as GaN, having a doping of the second conductivity type.

The electron blocking layer 217 and the second conductivity-type doped semiconductor material layer 219 may have similar or identical structures and/or dimensions as the electron blocking layer 117 and the second conductivity-type doped semiconductor material layer 119 of the first light emitting epitaxial semiconductor structure 10B (i.e., the blue light emitting subpixel 10B). In particular, the electron blocking layer 217 may form a mesa structure including a horizontal planar upper surface over the active region 216 and tapered sidewalls 218 extending from the horizontal planar upper surface of the electron blocking layer 217 towards the upper surface of the second dielectric material layer 209 and laterally surrounding the active region 216. The second conductivity-type doped semiconductor material layer 219 may form a mesa structure including a horizontal planar upper surface 222 over the electron blocking layer 217 and tapered sidewalls 220 extending from the horizontal planar upper surface 222 of the second conductivity-type doped semiconductor material layer 219 towards the upper surface of the second dielectric material layer 209 and laterally surrounding the electron blocking layer 217.

Accordingly, the second light emitting epitaxial semiconductor structure 10G (i.e., a green light emitting subpixel 10G) includes an optional first conductivity-type doped semiconductor layer 103 over an initial growth substrate 101, an optional superlattice structure 105 over the first conductivity-type doped semiconductor layer 103, a spacer layer 107 over the superlattice structure 105 that includes a lower portion 107a and a discrete upper portion 107b that forms a pedestal-like structure over the lower portion 107a of the spacer layer 107. A second dielectric material layer 209 is located over the upper surface of the lower portion 107a of the spacer layer 107 and laterally surrounds the upper portion 107b of the spacer layer 107.

The second light emitting epitaxial semiconductor structure 10G further includes a mesa portion 221 over the upper portion 107b of the spacer layer 107 and a portion of the second dielectric material layer 209. The mesa portion 221 includes a planar horizontal lower surface contacting the upper portion 107b of the spacer layer 107 and the upper surface of the second dielectric material layer 209, a planar horizontal upper surface 222, and a tapered outer sidewall 220 extending between the planar horizonal upper surface 222 and the planar horizontal lower surface of the mesa portion 221. The mesa portion 221 in the embodiment of FIG. 19 includes an active region 216 configured to emit green light upon application of a suitable electrical bias, an optional electron blocking layer 217 over the upper surface of and laterally surrounding the active region 216, and a second conductivity-type doped semiconductor material layer 219 over the upper surface of and laterally surrounding the electron blocking layer 217. The mesa portion 221 of second light emitting epitaxial semiconductor structure 10G may be laterally spaced from the mesa portion 121 of the first light emitting semiconductor structure 10B. A plurality of mesa portions 221 as shown in FIG. 19 may be formed over respective upper portions 107b of the spacer layer 107, where each mesa portion 221 may form a portion of a second light emitting epitaxial semiconductor structure 10G located within a pixel region 250 of the first exemplary structure.

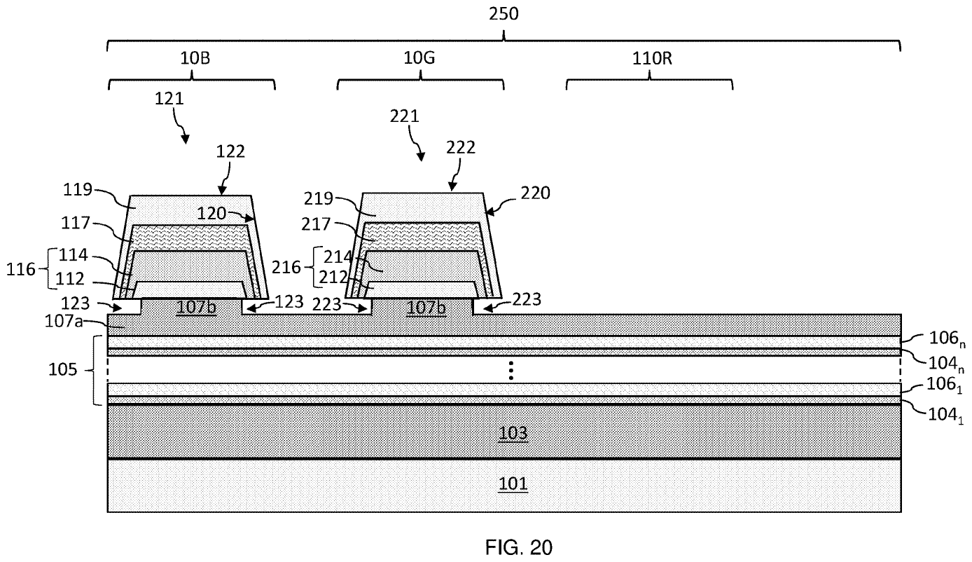

FIG. 20 is a vertical cross-section view of the first exemplary structure following an etching process to remove the second dielectric material layer 209 according to various embodiments of the present disclosure. Referring to FIG. 20, an etching process may be used to selectively remove the second dielectric material layer 209 from over the upper surface of the lower portion 107a of the spacer layer 107 and the mesa portion 121 of the first light emitting epitaxial semiconductor structure 10B. The etching process may also expose recesses 123 and 223 between the lower potion 107a of the spacer layer 107 and the respective mesa portions 121 and 221 of the first light emitting epitaxial semiconductor structure 10B and the second light emitting epitaxial semiconductor structure 10G as shown in FIG. 20. The second dielectric material layer 209 may be removed using a suitable etching process, such as a wet chemical etching process, as described above with reference to FIG. 13. For example, an initial etch, such as a potassium hydroxide (KOH)-based etch, may be performed to remove residual semiconductor material from over the upper surface of the second dielectric material layer 209. The mesa portion 221 of the second light emitting epitaxial semiconductor structure 10G may optionally be covered by a mask to protect the mesa portion 221 from being etched. A subsequent anisotropic etching step, such as a hydrofluoric acid (HF)-based etch and/or a hot phosphoric acid-based etch, may then be used to remove the second dielectric material layer 209.

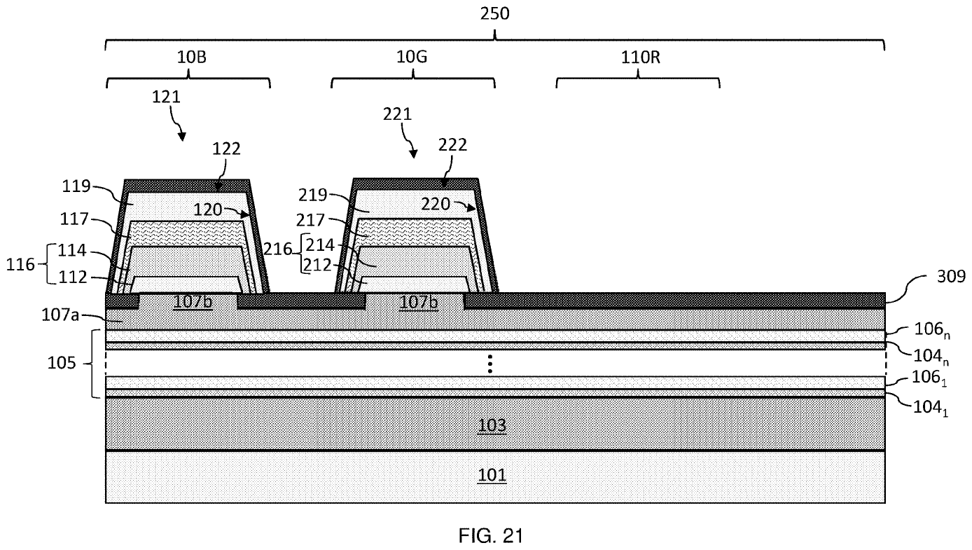

FIG. 21 is a vertical cross-section view of the first exemplary structure including a continuous third dielectric material layer 309 formed over the lower portion 107a of the spacer layer 107, over the side surfaces 120 and upper surface 122 of the mesa portion 121 of the first light emitting epitaxial semiconductor structure 10B, and over the side surfaces 220 and upper surface 222 of the mesa portion 221 of the second light emitting epitaxial semiconductor structure 10G according to various embodiments of the present disclosure. The continuous third dielectric material layer 309 may be composed of a suitable dielectric material, such as aluminum oxide, silicon oxide, silicon nitride, etc., including combinations thereof. The material of the continuous third dielectric material layer 309 may be the same or a different material than the material of the first dielectric material layer 109 and/or the second dielectric material layer 209. The continuous third dielectric material layer 309 may be deposited using a suitable deposition process as described above. In various embodiments, the continuous third dielectric material layer 309 may be deposited using a conformal deposition process, such as ALD. Thus, the continuous third dielectric material layer 309 may have a relatively uniform thickness over the upper surface of the lower portion 107a of the spacer layer 107 and over the surfaces of the mesa portions 121 and 221. In some embodiments, the continuous third dielectric material layer 309 may completely fill the recesses 123 and 223 between the spacer layer 107 and the bottom surface of the mesa portions 121 and 221. The continuous third dielectric material layer 309 may have a thickness in a range of about 10-100 nm, although greater and lesser thicknesses may also be utilized. In various embodiments, the upper surface of the continuous third dielectric material layer 309 may be composed of a dielectric material that minimizes or prevents epitaxial growth of a III-V compound semiconductor material over the continuous third dielectric material layer 309 in a subsequent deposition process.

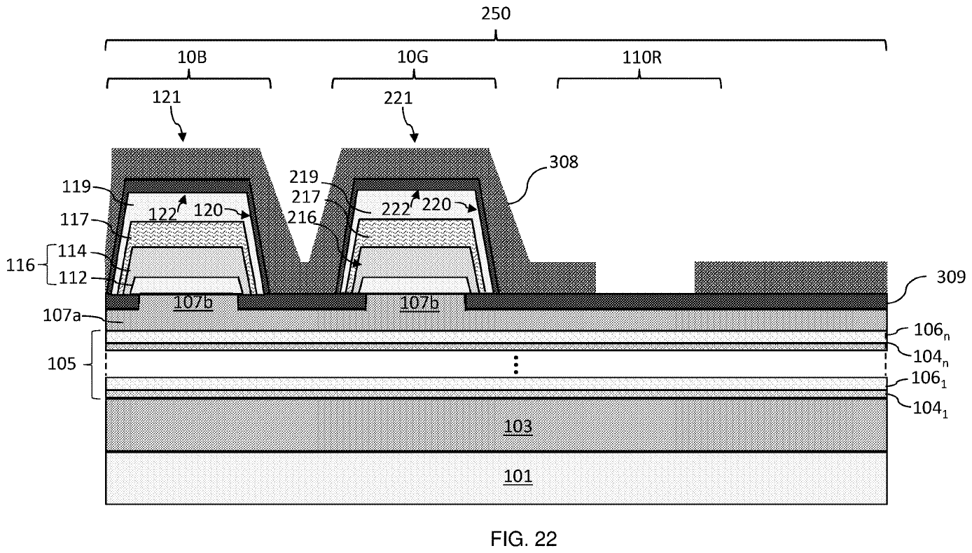

FIG. 22 is a vertical cross-section view of the first exemplary structure including a patterned mask 308 formed over the continuous third dielectric material layer 309 according to various embodiments of the present disclosure. The patterned mask 308 may be formed as described above with reference to FIG. 7. The patterned mask 308 may include an opening through the patterned mask 308 in each subpixel region 110R of the first exemplary structure corresponding to a location in which subpixels 10R of the same type may be subsequently formed. In the embodiment of FIG. 22, the one or more openings are in subpixel regions 110RG in which red-emitting subpixels 10G may be subsequently formed. Although a single opening through the patterned mask 308 is illustrated in FIG. 22, it will be understood that each pixel region 250 of the first exemplary structure may include an opening through the patterned mask 208, where the opening may be located in a subpixel region 110R within which subpixels 10R of the same type are subsequently formed. As previously described with reference to FIG. 7, the size and shape of each opening through the patterned mask 308 may be selected to optimize the shape and size of epitaxial semiconductor structures to be subsequently formed in subpixel regions 110R.

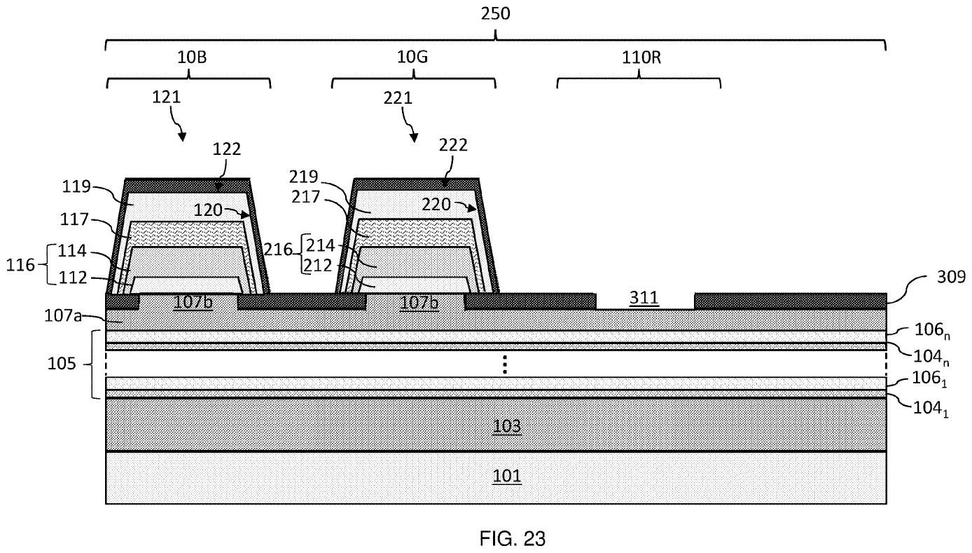

FIG. 23 is a vertical cross-section view of the first exemplary structure including an opening 311 formed through the third dielectric material layer 309 according to various embodiments of the present disclosure. Referring to FIGS. 22 and 23, an etching process as described above with reference to FIGS. 7 and 8 may be remove portions of the continuous third dielectric material layer 309 exposed through the opening(s) in the patterned mask 308 and form one or more openings 311 through the second dielectric material layer 309. The lower portion 107a of the spacer layer 107 may be exposed in the bottom of each of the openings 311. The remaining portion of the second dielectric material layer 309 may function as a patterned growth mask that may enable selective epitaxial growth of semiconductor structures over the exposed upper surface of the lower spacer layer 107a within each of the subpixel regions 110R (e.g., the subpixel regions 110R corresponding to the locations of red-emitting subpixels 10R). Following the etching process, the patterned mask 308 may be removed using a suitable process, such as by ashing and/or dissolution with a solvent.

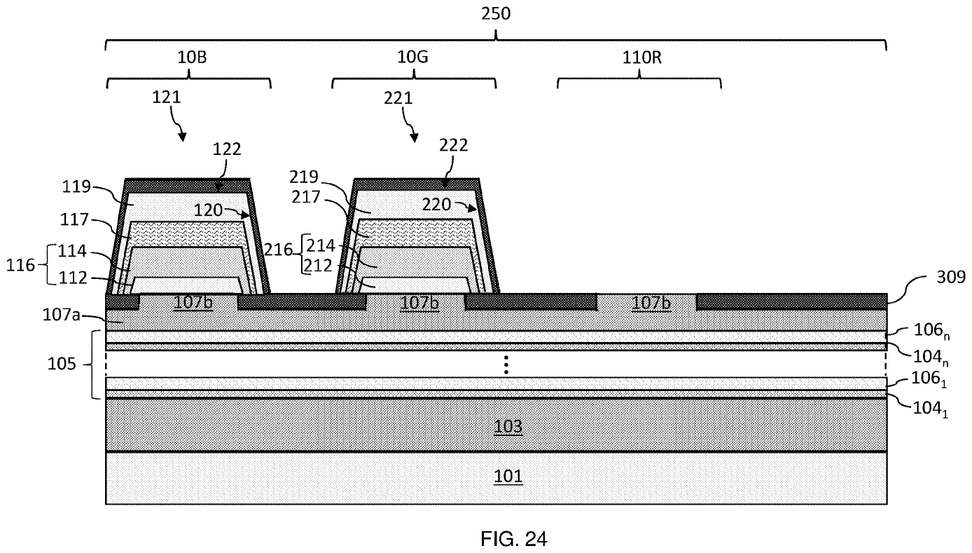

FIG. 24 is a vertical cross-section view of the first exemplary structure including an upper portion 107b of the spacer layer 107 formed within subpixel region 110R according to various embodiments of the present disclosure. In various embodiments, the upper portion 107b of the spacer layer 107 that is formed in subpixel region 110R may be composed of the same material(s) as the material(s) of the lower portion 107a of the spacer layer 107 and/or the upper portions 107a of the spacer layer 107 that are located in subpixel 10B and/or in subpixel 10G. In some embodiments, the upper portion 107b of the spacer layer 107 that is formed in subpixel region 110R may include GaN that is lightly doped with dopant(s) of the first conductivity type. As described above with reference to FIG. 9, the upper portion 107b of the spacer layer 107 within subpixel region 110R may be selectively grown over the exposed surface of the continuous lower spacer layer 107a within the opening 311 in the third dielectric material layer 309, but there may be minimal or no growth of the semiconductor material over the upper surface of the third dielectric material layer 309. The upper portion 107b of the spacer layer 107 within subpixel region 110R may fill at least a portion of the opening 311 in the third dielectric material layer 309 and may completely fill the opening 311 such that the upper surface of the upper spacer layer 107b may be substantially coplanar with the upper surface of the third dielectric material layer 309. Although a single discrete upper portion 107b of the spacer layer 107 is shown in subpixel region 110R in FIG. 24, it will be understood that each pixel region 250 of the first exemplary structure may include a discrete upper portion 107b of the spacer layer 107 located in a subpixel region 110R in which red light emitting subpixels 10R are subsequently formed.

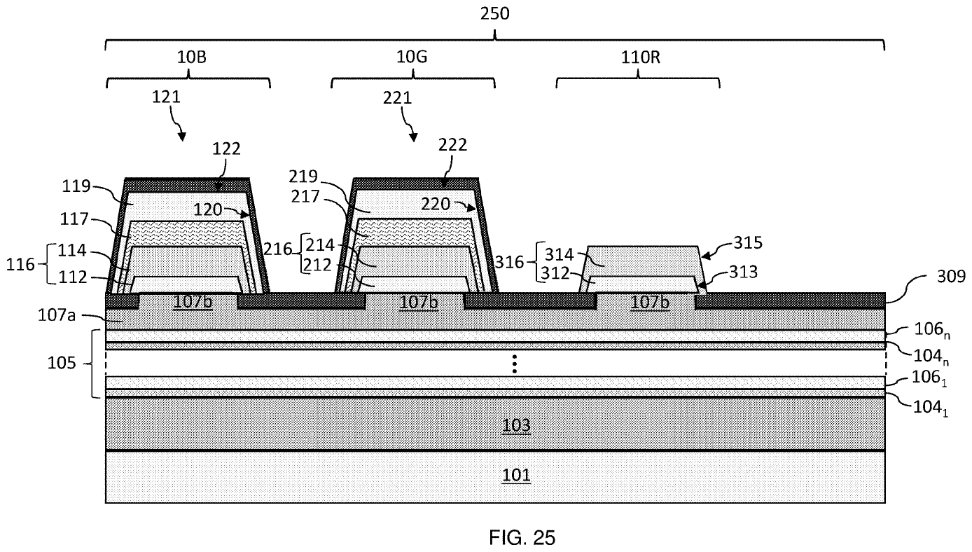

FIG. 25 is a vertical cross-section view of the first exemplary structure including an active region 316 formed over the upper portion 107b of the spacer layer 107 and the third dielectric material layer 309 within subpixel region 110R according to various embodiments of the present disclosure. As in the cases of the active regions 116 and 216 of the blue light emitting subpixel 10B and the green light emitting subpixel 10G respectively, the active region 316 in subpixel region 110R may be formed using a selective semiconductor deposition process that enables selective growth of the active region 316 over the upper portion 107b of the spacer layer 107 within subpixel region 110R. The active region 316 in subpixel region 110R may have a similar or identical structure as the active region 116 of subpixel 10B and/or the active region 216 in subpixel 10G. For example, active region 316 may include an optically active compound semiconductor layer stack configured to emit light, such as at least one above-described quantum well (QW) structure (312, 314) that emits light upon application of an electrical bias thereacross. In some embodiments, the active region 316 can include a layer stack including multiple instances of a quantum well structure including a first band gap semiconductor layer 312 and a second band gap semiconductor layer 314 over the first band gap semiconductor layer 312, such as between 2 and 10 repeating instances of the first band gap semiconductor layer 312 and the second band gap semiconductor layer 314. Alternatively, the active region 316 may include any other suitable semiconductor layers or stack of layers for light emitting diode applications provided that it can be selectively grown over the upper portion 107b of the spacer layer 107. The set of all layers within active region 316 may also be referred to as an active layer.

In various embodiments, each of the respective layers 312, 314 that form the active region 316 may form a mesa structure including a horizontal planar upper surface and tapered sidewalls 313, 315 extending from the horizontal planar upper surface towards the upper surface of the third dielectric material layer 309. A width dimension of the mesa structures (i.e., a dimension of the mesa structure within a horizontal plane) may increase between the horizontal planar upper surface of the mesa structures and the upper surface of the third dielectric material layer 309. Each of the respective layers 312, 314 that form the active region 316 may further include a bottom surface, where the bottom surfaces of the layers 312, 314 may be coplanar with one another and may each contact the upper surface of the third dielectric material layer 309. The bottom surface of the lowermost layer of the active region 316 (i.e., layer 312 in FIG. 25) may additionally contact the upper portion 107b of the spacer layer 107.

In the embodiment shown in FIG. 25, the active region 316 formed in subpixel region 110R may be configured to emit red light having a peak wavelength in range from 600 nm to 700 nm upon application of a suitable electrical bias thereacross. In a non-limiting illustrative example of a red light emitting active region 316 composed of a quantum well structure, the first band gap semiconductor layer(s) 312 may be composed of In_{z}Ga_{1-z}N, where 0.24≤z≤0.27 (e.g., x≈0.25), and the second band gap semiconductor layer(s) 314 may be composed of GaN. In various embodiments, the first band gap semiconductor layer(s) 312 within the active region 316 formed in subpixel region 110R may have a higher concentration of indium than the first band gap semiconductor layer(s) 112 within the blue light emitting subpixels 10B and the first band gap semiconductor layer(s) 212 within the green light emitting subpixels 10G. The first band gap semiconductor layer(s) 312 may have a thickness in a range of about 2.5-5 nm (i.e., between the horizontal planar upper surface of the layer 312 and the upper surface of the immediately underlying material layer), and the second band gap semiconductor layer(s) 314 may have a thickness in a range of about 15-20 nm (i.e., between the horizontal planar upper surface of the layer 314 and the upper surface of the immediately underlying material layer), although greater and lesser thicknesses may be employed.

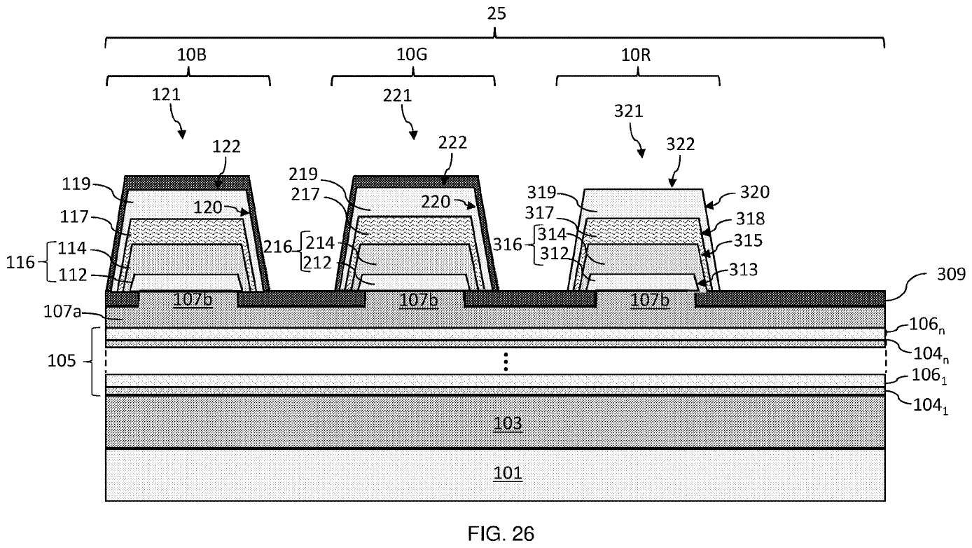

FIG. 26 is a vertical cross-section view of the first exemplary structure including a third light emitting epitaxial semiconductor structure 10R in a pixel region 250 according to various embodiments of the present disclosure. The third light emitting epitaxial semiconductor structure 10R may form a red light emitting subpixel 10R within the pixel region 250. Thus, the first light emitting epitaxial semiconductor structure 10B, the second light emitting epitaxial semiconductor structure 10G and the third light emitting epitaxial semiconductor structure 10R may collectively form a multicolor pixel 25. A plurality of multicolor pixels 25 as shown in FIG. 26 may be located over the initial growth substrate 101. The third light emitting epitaxial semiconductor structure 10R may be formed by forming an optional electron blocking layer 317 over the upper surface and sidewalls 315 of the active region 316 and forming a second conductivity-type doped semiconductor material layer 319 over the upper surface and sidewalls 318 of the electron blocking layer 317. The electron blocking layer 317 may include a doped semiconductor material, such as AlGaN, having a doping of the second conductivity type. The second conductivity-type doped semiconductor material layer 319 may include a doped III-V compound semiconductor material, such as GaN, having a doping of the second conductivity type. The electron blocking layer 317 and the second conductivity-type doped semiconductor material layer 319 may have similar or identical structures and/or dimensions as the electron blocking layer 117 and the second conductivity-type doped semiconductor material layer 119 of the first light emitting epitaxial semiconductor structure 10B (i.e., the blue light emitting subpixel 10B) and/or the electron blocking layer 217 and the second conductivity-type doped semiconductor material layer 219 of the second light emitting epitaxial semiconductor structure 10G (i.e., the green light emitting subpixel 10B). In particular, the electron blocking layer 317 may form a mesa structure including a horizontal planar upper surface over the active region 316 and tapered sidewalls 318 extending from the horizontal planar upper surface of the electron blocking layer 317 towards the upper surface of the third dielectric material layer 309 and laterally surrounding the active region 316. The second conductivity-type doped semiconductor material layer 319 may form a mesa structure including a horizontal planar upper surface 322 over the electron blocking layer 317 and tapered sidewalls 320 extending from the horizontal planar upper surface 322 of the second conductivity-type doped semiconductor material layer 319 towards the upper surface of the third dielectric material layer 309 and laterally surrounding the electron blocking layer 317.

Accordingly, the third light emitting epitaxial semiconductor structure 10R (i.e., a red light emitting subpixel 10R) includes an optional first conductivity-type doped semiconductor layer 103 over an initial growth substrate 101, an optional superlattice structure 105 over the first conductivity-type doped semiconductor layer 103, a spacer layer 107 over the superlattice structure 105 that includes a lower portion 107a and a discrete upper portion 107b that forms a pedestal-like structure over the lower portion 107a of the spacer layer 107. A third dielectric material layer 309 is located over the upper surface of the lower portion 107a of the spacer layer 107 and laterally surrounds the upper portion 107b of the spacer layer 107.

The third light emitting epitaxial semiconductor structure 10R further includes a mesa portion 321 over the upper portion 107b of the spacer layer 107 and a portion of the third dielectric material layer 309. The mesa portion 321 includes a planar horizontal lower surface contacting the upper portion 107b of the spacer layer 107 and the upper surface of the third dielectric material layer 309, a planar horizontal upper surface 322, and a tapered outer sidewall 320 extending between the planar horizonal upper surface 322 and the planar horizontal lower surface of the mesa portion 321. The mesa portion 321 in the embodiment of FIG. 25 includes an active region 316 configured to emit red light upon application of a suitable electrical bias, an optional electron blocking layer 317 over the upper surface of and laterally surrounding the active region 316, and a second conductivity-type doped semiconductor material layer 319 over the upper surface of and laterally surrounding the electron blocking layer 317. The mesa portion 321 of third light emitting epitaxial semiconductor structure 10R may be laterally spaced from the mesa portion 221 of the second light emitting semiconductor structure 10G and the mesa portion 121 of the first light emitting semiconductor structure 10B. A plurality of mesa portions 321 as shown in FIG. 26 may be formed over respective upper portions 107b of the spacer layer 107, where each mesa portion 321 may form a portion of a third light emitting epitaxial semiconductor structure 10G of a multicolor pixel 25 of the first exemplary structure.

In the above-described fabrication method, the first (i.e., blue) light emitting epitaxial semiconductor structures 10B are formed prior to the formation of the second (i.e., green) light emitting epitaxial semiconductor structures 10G, and both the first (i.e., blue) light emitting epitaxial semiconductor structures 10B and the second (i.e., green) light emitting epitaxial semiconductor structures 10G are formed prior to the formation of the third (i.e., red) light emitting epitaxial semiconductor structures 10R. This sequence of fabrication may be advantageous due to differences in the composition of the respective light emitting epitaxial semiconductor structures 10B, 10G and 10R. In particular, the first (i.e., blue) light emitting epitaxial semiconductor structures 10B typically include the lowest concentration of indium within the active regions 116 of the structures 10B. The second (i.e., green) light emitting epitaxial semiconductor structures 10G typically have a relatively higher concentration of indium in the active regions 216, and the third (i.e., red) light emitting epitaxial semiconductor structures 10R generally have the highest concentration of indium in the active regions 316. By forming the semiconductor structures having relatively higher indium concentrations after the formation of semiconductor structures having relatively lower indium concentrations, high temperature processing of the structures having the relatively higher indium concentrations may be minimized. It is believed that high temperature processing of indium-containing semiconductor structures may result in a loss of indium from the structures. Thus, by minimizing the high temperature processing of the red and green light emitting semiconductor structures, the indium loss in these structures may be minimized and the performance of the multicolor light emitting devices may be improved.

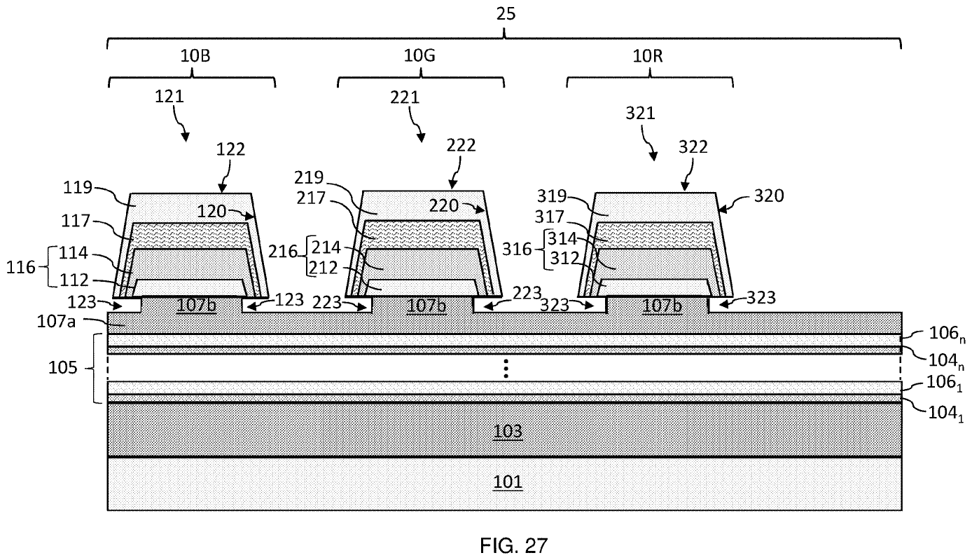

FIG. 27 is a vertical cross-section view of the first exemplary structure following an etching process to remove the third dielectric material layer 309 according to various embodiments of the present disclosure. Referring to FIG. 27, an etching process may be used to selectively remove the third dielectric material layer 209 from over the upper surface of the lower portion 107a of the spacer layer 107, the mesa portion 121 of the first light emitting epitaxial semiconductor structure 10B and the mesa portion 221 of the second light emitting epitaxial semiconductor structure 10G. The etching process may also expose recesses 123, 223 and 323 between the lower potion 107a of the spacer layer 107 and the respective mesa portions 121, 221 and 331 of the first light emitting epitaxial semiconductor structure 10B, the second light emitting epitaxial semiconductor structure 10G and the third light emitting epitaxial semiconductor structure 10R, respectively. The third dielectric material layer 309 may be removed using a suitable etching process, such as a wet chemical etching process, as described above with reference to FIG. 13. For example, an initial etch, such as a potassium hydroxide (KOH)-based etch, may be performed to remove residual semiconductor material from over the upper surface of the second dielectric material layer 309. The mesa portion 321 of the third light emitting epitaxial semiconductor structure 10R may optionally be covered by a mask to protect the mesa portion 321 from being etched. A subsequent anisotropic etching step, such as a hydrofluoric acid (HF)-based etch and/or a hot phosphoric acid-based etch, may then be used to remove the third dielectric material layer 309.

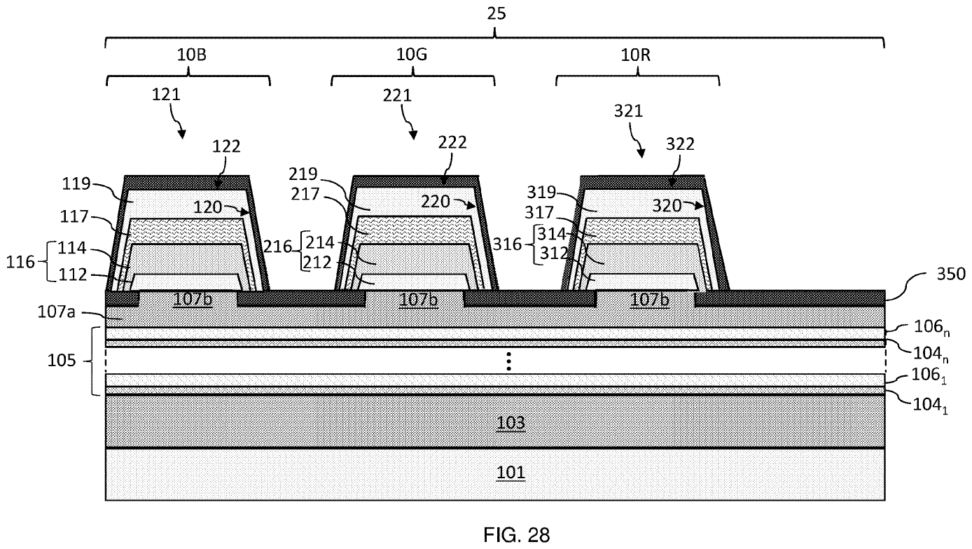

FIG. 28 is a vertical cross-section view of the first exemplary structure including a continuous fourth dielectric material layer 350 formed over the lower portion 107a of the spacer layer 107, over the side surfaces 120 and upper surface 122 of the mesa portion 121 of the first light emitting epitaxial semiconductor structure 10B, over the side surfaces 220 and upper surface 222 of the mesa portion 221 of the second light emitting epitaxial semiconductor structure 10G and over the side surfaces 320 and upper surface 322 of the mesa portion 321 of the third light emitting epitaxial semiconductor structure 10R. The continuous fourth dielectric material layer 350 may be composed of a suitable dielectric material, such as aluminum oxide, silicon oxide, silicon nitride, etc., including combinations thereof. The material of the continuous fourth dielectric material layer 350 may be the same or a different material than the material of the first dielectric material layer 109, the second dielectric material layer 209 and/or the third dielectric material layer 309. The continuous fourth dielectric material layer 350 may be deposited using a suitable deposition process as described above. In various embodiments, the continuous fourth dielectric material layer 350 may be deposited using a conformal deposition process, such as ALD. Thus, the continuous fourth dielectric material layer 350 may have a relatively uniform thickness over the upper surface of the lower portion 107a of the spacer layer 107 and over the surfaces of the mesa portions 121, 221 and 321. In some embodiments, the continuous fourth dielectric material layer 350 may completely fill the recesses 123, 223 and 323 between the spacer layer 107 and the bottom surfaces of the mesa portions 121, 221 and 321. The continuous fourth dielectric material layer 350 may have a thickness in a range of about 10-100 nm, although greater and lesser thicknesses may also be utilized. In one embodiment, the heights (i.e., thicknesses) of the three mesa portions 121, 221 and 321 may be the same. In another embodiment, the heights (i.e., thicknesses) of the three mesa portions 121, 221 and 321 may be different from each other. For example, the mesa portion 321 of the red subpixel 10R may be thicker than the mesa portions 121 and/or 221 of the blue subpixel 10B and/or green subpixel 10G, respectively.

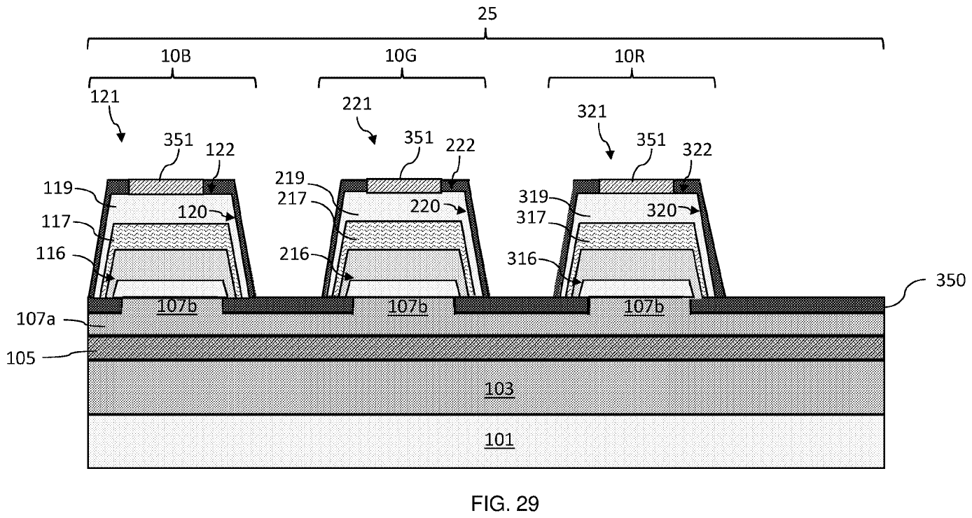

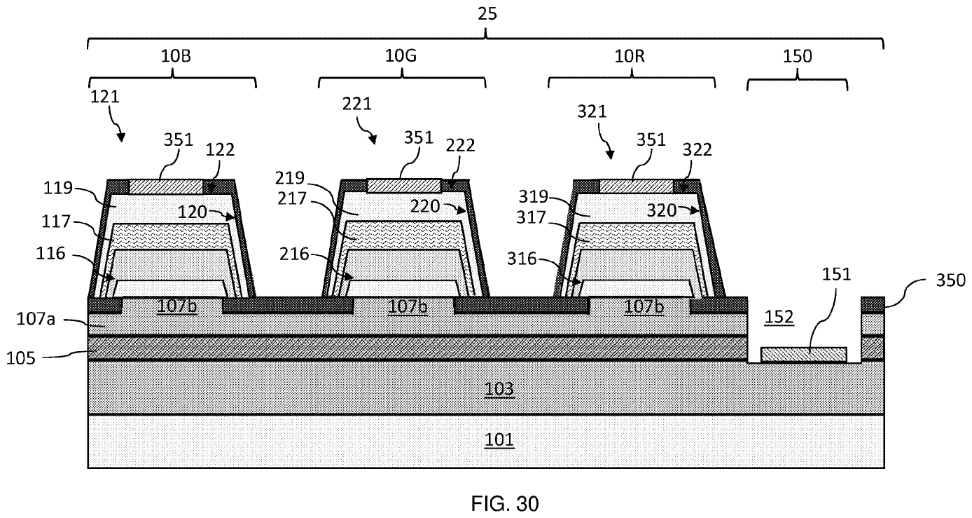

FIGS. 29 and 30 are sequential vertical cross-section views of the first exemplary structure illustrating a process of forming n- and p-side contact electrodes for a multicolor light emitting device pixel 25 according to an embodiment of the present invention. For clarity of illustration, the superlattice structure 105 is shown as a single layer in FIGS. 29 and 30, although it will be understood that the superlattice structure 105 may include a multi-layer structure as described above. FIG. 29 is a vertical cross-section view of the first exemplary structure including contact electrodes 351 over the upper surfaces 122, 222 and 322 of the mesa portions 121, 221 and 321 of each of the subpixels 10B, 10G and 10R of the multicolor pixel 25 according to various embodiments of the present disclosure. Referring to FIG. 29, a photoresist layer (not shown in FIG. 29) may be applied over the fourth dielectric material layer 350 and may be lithographically patterned to provide openings over the upper surfaces 122, 222 and 322 of the mesa portions 121, 221 and 321 of each of the subpixels 10B, 10G and 10R. In some embodiments, the opening through the photoresist layer may overlie center portions of the upper surfaces 122, 222 and 322 of the mesa portions 121, 221 and 321, and may not overlie peripheral portions of the upper surfaces 122, 222 and 322 that are adjacent to the respective sidewalls 120, 220 and 320 of the mesa portions 121, 221 and 321. An etch process can be performed to remove unmasked portions of the fourth dielectric material layer 350 employing the photoresist layer as an etch mask, thereby forming openings through the fourth dielectric material layer 350 exposing portions of the upper surfaces 122, 222 and 322 of the mesa portions 121, 221 and 321 of each of the subpixels 10B, 10G and 10R. The photoresist layer may be subsequently removed, for example, by ashing.

An electrically conductive material may then be deposited over the fourth dielectric material layer 350 and over the exposed upper surfaces 122, 222 and 322 of the of the mesa portions 121, 221 and 321 in each of the subpixels 10B, 10G and 10R. In some embodiments, the conductive material may include a reflective metal such as aluminum, silver, copper, and/or gold. Other suitable conductive materials, such as a conductive transparent oxide (e.g., indium tin oxide or aluminum zinc oxide) are within the contemplated scope of disclosure. The conductive material may be deposited, for example, by sputtering. Other suitable deposition processes are within the contemplated scope of disclosure. The conductive material may fill each of the openings through the fourth dielectric material layer 350 located over the upper surfaces 122, 222 and 322 of the mesa portions 121, 221 and 321 of the subpixels 10B, 10G, 10R. A planarization process, such as a chemical mechanical planarization (CMP) may be used to remove excess conductive material from over the upper surface of the fourth dielectric material layer 350, leaving discrete contact electrodes 351 contacting the upper surfaces 122, 222 and 322 of the of the mesa portions 121, 221 and 321 in each of the subpixels 10B, 10G and 10R. Each contact electrode 351 may be laterally surrounded by the fourth dielectric material layer 350 and may have an upper surface that is substantially coplanar with the upper surface of the fourth dielectric material layer 350, as shown in FIG. 29. In an alternative embodiment, the fourth dielectric material layer 350 may be omitted, and the contact electrodes 351 may be formed on the upper surfaces 122, 222 and 322 of the of the mesa portions 121, 221 and 321 in each of the subpixels 10B, 10G and 10R by conductive layer deposition followed by photolithograph and etching.

Each of the contact electrodes 351 may electrically contact a second conductivity-type semiconductor material layer 119, 219, 319 of a respective sub-pixel 10B, 10G, 10R of the first exemplary structure. In embodiments in which the second conductivity-type semiconductor material layers 119, 219 and 319 include p-type semiconductor materials, the contact electrodes 351 may provide anode contact electrodes 351 for the respective sub-pixels 10B, 10G and 10R of a multicolor pixel 25. As discussed above, in various embodiments the contact electrodes 351 may contact the second conductivity-type semiconductor material layers 119, 219 and 319 in a central region of the horizontal planar upper surface 122, 222 and 322 of the second conductivity-type semiconductor material layers 119, 219 and 319, and may not contact the second conductivity-type semiconductor material layers 119, 219 and 319 in a peripheral region of the horizontal planar upper surface 122, 222, 322 that is adjacent to a sidewall 120, 220, 320 of the second conductivity-type semiconductor material layer 119, 219, 310. This may promote current injection from the top of the mesa portions 121, 221, 321 through the active regions 116, 216, 316 rather than through the faceted sidewalls of the mesa portions 121, 221, 321, which may provide improved light extraction efficiency.

Optionally, at least one metallic (i.e., electrically conductive) barrier layer (not shown) can be formed as a component of the contact electrode 351. In this case, the at least one metallic barrier layer can be located at a planar surface of the contact electrode 351, and may be employed to facilitate subsequent bonding of a solder material over the respective subpixels 10B, 10G and 10R. The at least one metallic barrier layer may include a metal or metal alloy (i.e., metallic) material layers that can be employed for under-bump metallurgy (UBM), i.e., a set of metal layers provided between a conductive bonding structure and a die. In one embodiment, the at least one metallic barrier layer can include a diffusion barrier layer and an adhesion promoter layer. Exemplary materials that can be employed for the diffusion barrier layer include titanium, titanium-tungsten, titanium-platinum or tantalum. Exemplary materials that can be employed for the adhesion promoter layer include tungsten, platinum, or a stack of tungsten and platinum. Any other under-bump metallurgy known in the art can also be employed.

FIG. 30 is a vertical cross-section view the first exemplary structure including a contact electrode 151 over the first conductivity-type semiconductor layer 103 within a contact region 150 of the multicolor pixel 25 according to various embodiments of the present disclosure. Referring to FIG. 30, a photoresist layer (not shown in FIG. 30) may be applied over the first exemplary structure and may be lithographically patterned to provide an opening over the fourth dielectric material layer 350 in a contact region 150 of the pixel 25 that does not include a subpixel 10B, 10G or 10R. In some embodiments, the contact region 150 of the pixel 25 may be located in a peripheral region of the pixel 25 (e.g., as shown in FIG. 1B). An etch process may be performed utilizing the photoresist layer as a mask to remove a portion of the fourth dielectric material layer 350, the lower potion 107a of the spacer layer 107 and the superlattice structure 105 to provide a recessed portion 152 (i.e., an opening through the fourth dielectric material layer 350, the lower portion 107a of the spacer layer 107 and the superlattice structure 107) in the pixel 25. The first conductivity-type semiconductor layer 103 may be exposed on the bottom surface of the recessed portion 152. In one embodiment, the photoresist layer may be subsequently removed, for example, by ashing.

An electrically conductive material may then be deposited via a suitable deposition method over the exposed surface of the first conductivity type semiconductor layer 103 within the contact region 150 of the pixel 25. The electrically conductive material may be lithographically patterned using a suitable process, such as a masked etching process and/or a liftoff process (in which case the patterned photoresist layer is retained and then lifted off with the electrically conductive material), to provide a discrete contact electrode 151 electrically contacting the first conductivity type semiconductor layer 103 within the contact region 150 of the pixel 25. The contact electrode 151 may be composed of a suitable conductive material, such as a reflective metal (e.g., aluminum, silver, copper, and/or gold) and/or a conductive transparent oxide (e.g., indium tin oxide or aluminum zinc oxide). In some embodiments, the conductive material of the contact electrode 151 in the contact region 150 may be composed of the same material(s) as the contact electrodes 351 contacting the upper surfaces 122, 222 and 322 of the mesa portions 121, 221 and 321 in each of the subpixels 10B, 10G and 10R. As in the case of the contact electrodes 351 described above, at least one metallic (i.e., electrically conductive) barrier layer (not shown), such as an above-described diffusion barrier layer and/or an adhesion promoter layer, may be formed as a component of the contact electrode 151. In embodiments in which the first conductivity-type semiconductor material layer 103 includes an n-type semiconductor material, the contact electrode 151 in the contact region 150 of the pixel 25 may provide a common cathode contact electrode 252 for the respective sub-pixels 10B, 10G and 10R of the multicolor pixel 25.

In another alternative embodiment, the recessed portion 152 in the contact region 150 is formed during the same etching step as the openings through the fourth dielectric material layer 350 which expose portions of the upper surfaces 122, 222 and 322 of the mesa portions 121, 221 and 321 of each of the subpixels 10B, 10G and 10R in FIG. 29. The contact electrodes 151 and 351 may then be formed during the same conductive layer deposition and patterning step. For example, one or more electrically conductive layers may be formed over the device and in the recessed portion 152 and in the openings in the fourth dielectric material layer 350. The one or more electrically conductive layers are then lithographically patterned using a suitable process, such as a masked etching process and/or a liftoff process to provide the discrete contact electrode 151 in the recessed portion 152 and the contact electrodes 351 to the upper surfaces 122, 222 and 322 of the mesa portions 121, 221 and 321 of each of the subpixels 10B, 10G and 10R during the same deposition and patterning steps.

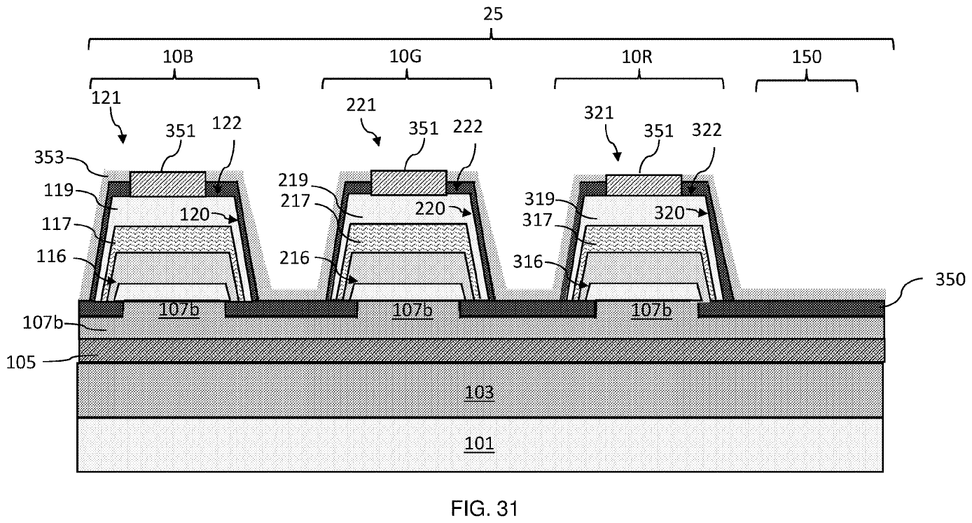

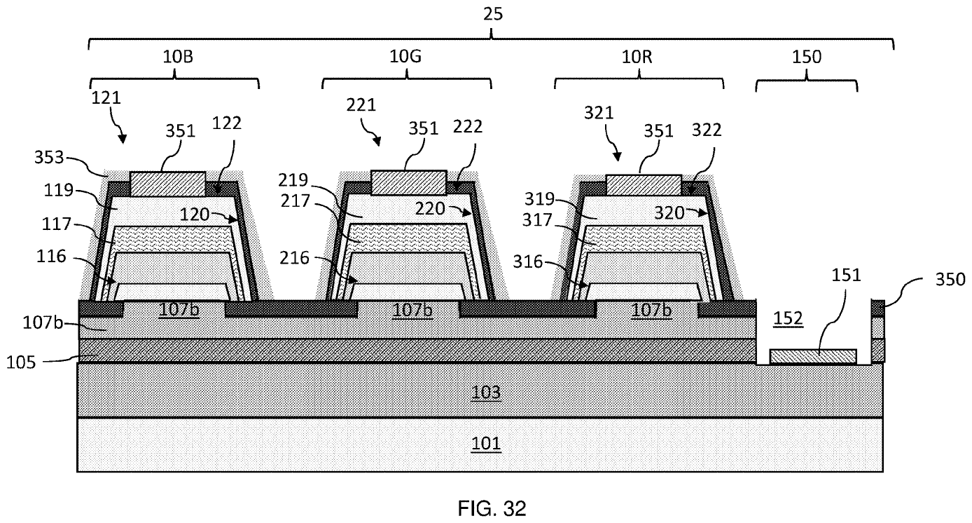

FIGS. 31 and 32 are sequential vertical cross-section views of the first exemplary structure illustrating another alternative process of forming n- and p-side contact electrodes 151 and 351 and a reflector layer 353 for a multicolor light emitting device pixel 25 according to an embodiment of the present invention. Referring to FIG. 31, a reflector layer 353 may be formed over the fourth dielectric material layer 350. The reflector layer 353 may be composed of a suitable optically reflective material, such as one or more reflective conductive materials (e.g., silver, aluminum, copper, gold, etc.). In some embodiments, the reflector layer 353 may include a thin film distributed Bragg reflector (DBR) having small index changes to provide enhanced reflectivity. The reflector layer 353 may be deposited using a suitable deposition method, such as sputtering and/or vacuum evaporation. Other suitable deposition methods are within the contemplated scope of disclosure. The reflector layer 353 may be configured to reflect light emitted from the active regions 116, 216, 316 of the subpixels 10B, 10G, 10R in a downward direction (i.e., toward the growth substrate 101). In some embodiments, the reflector layer 353 may be configured direct the light with a controlled viewing angle (e.g., in a range between 30-150°, such as between 60-120°).

In various embodiments, the reflector layer 353 may be deposited as a continuous layer over the fourth dielectric material layer 350. Then, a photoresist layer may be applied over the reflector layer 353, and the processing steps described above with reference to FIG. 29 may be performed to form openings through the reflector layer 353 and the fourth dielectric layer 350, and to form discrete contact electrodes 351 within the openings and contacting the upper surfaces 122, 222 and 322 of the of the mesa portions 121, 221 and 321 in each of the subpixels 10B, 10G and 10R. Each of the contact electrodes 351 may be laterally surrounded by both the reflector layer 353 and the fourth dielectric material layer 350 as shown in FIG. 31. In embodiments in which the reflector layer 353 is composed of an electrically conductive material, the contact electrodes 351 may be electrically connected to the reflector layer 353.

FIG. 32 is a vertical cross-section view the first exemplary structure including a contact electrode 151 over the first conductivity-type semiconductor layer 103 within a contact region 150 of the multicolor pixel 25 according to various embodiments of the present disclosure. Referring to FIG. 32, a photoresist layer (not shown in FIG. 32) may be applied over reflector layer 353 and may be lithographically patterned such that the photoresist layer covers portions of the reflector layer 353 located over the mesa portions 121, 221 and 321 of each of the subpixels 10B, 10G and 10R, while portions of the reflector layer 353 located between the respective subpixels 10B, 10G and 10R and within the contact region 150 of the pixel 25 may be exposed through the photoresist layer. An etching process may be utilized to remove portions of the reflector layer 353 from between respective subpixels 10B, 10G, 10R to electrically isolate the contact electrodes 351 of the respective subpixels 10B, 10G, 10R. The etching process may also remove the reflector layer 353 from the contact region 150 of the pixel 25. Then, the process steps described above with reference to FIG. 30 may be performed to form a recessed portion 152 (e.g., an opening) in the contact region 150 of the pixel 25 that exposes the first conductivity-type semiconductor layer 103 on the bottom surface of the recessed portion 152, and to form a contact electrode 151 (e.g., a common cathode electrode) over the bottom surface of the recessed portion 152 that electrically contacts the first conductivity type semiconductor layer 103 within the contact region 150 of the pixel 25.

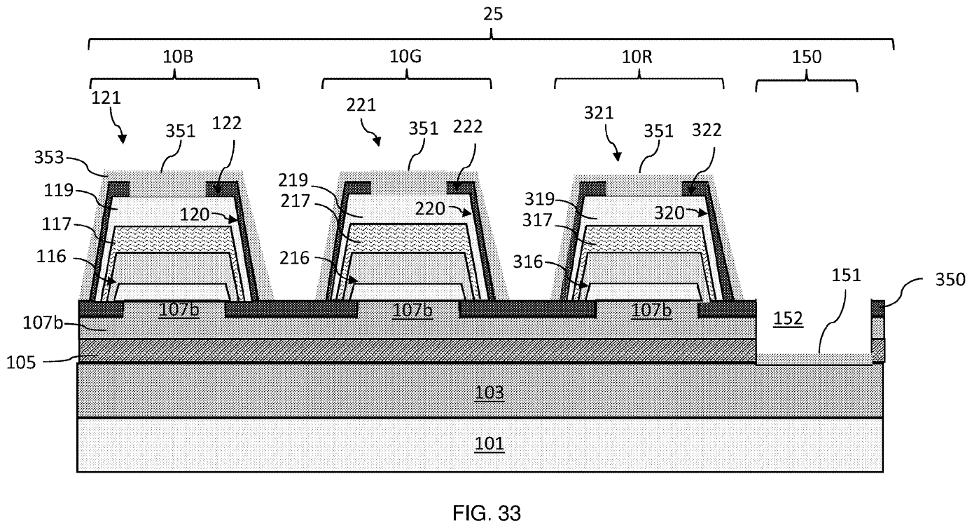

Various alternative configurations of the reflector layer 353 and the contact electrodes 351 and 151 are within the contemplated scope of disclosure. For example, in embodiments in which the reflector layer 353 is composed of an electrically conductive material, a continuous reflector layer 353 may be formed over a structure as shown in FIG. 30 such that a portion of the reflector layer 353 overlies and contacts the upper surfaces of each of the contact electrodes 351 and 151. Portions of the continuous reflector layer 353 may be removed via an etching process as described above to electrically isolate each of the contact electrodes 351 and 151. The remaining discrete portions of the reflector layer 353 overlying the respective contact electrodes 351 and 151 may thus provide a conductive pathway between each of the contact electrodes 351 and 151 and a corresponding bonding structure (e.g., a solder material portion) that may be subsequently provided over the discrete portions of the reflector layer 353. In still further embodiments, openings may be formed through the fourth dielectric material layer 350 to expose the upper surfaces 122, 222 and 322 of the of the mesa portions 121, 221 and 321 in each of the subpixels 10B, 10G and 10R, as described above with reference to FIG. 29. A recessed portion 152 may also be formed in the contact region 150 of the pixel 25 as described above with reference to FIG. 30. Then, a continuous reflector layer 353 may be formed over the fourth dielectric material layer 350, within the openings in the fourth dielectric material layer 350 exposing the upper surfaces 122, 222 and 322 of the of the mesa portions 121, 221 and 321 in each of the subpixels 10B, 10G and 10R, and within the recessed portion 152 in the contact region 150 of the pixel 25. The portions of the continuous reflector layer 353 located within the openings and contacting the upper surfaces 122, 222 and 322 of the of the mesa portions 121, 221 and 321 in each of the subpixels 10B, 10G and 10R may function as contact electrodes 351 (e.g., anode contact electrodes 351) for each of the subpixels 10B, 10G, 10R, and the portion of the continuous reflector layer 353 contacting the first conductivity-type semiconductor layer 103 within the recessed portion 152 in the contact region 150 of the pixel 25 may function as a common contact electrode (e.g., a cathode contact electrode 151) for the multicolor pixel 25. Portions of the continuous reflector layer 353 may be removed via an etching process as described above to electrically isolate the respective portions of the reflector layer 353 that function as contact electrodes 351 and 151 of the multicolor pixel 25. FIG. 33 is a vertical cross-section view illustrating a reflector layer 353 that functions as contact electrodes 351 (e.g., anode contact electrodes) for each of the subpixels 10B, 10G and 10R and as a common contact electrode 151 (i.e., a cathode contact electrode) for the multicolor pixel 25.

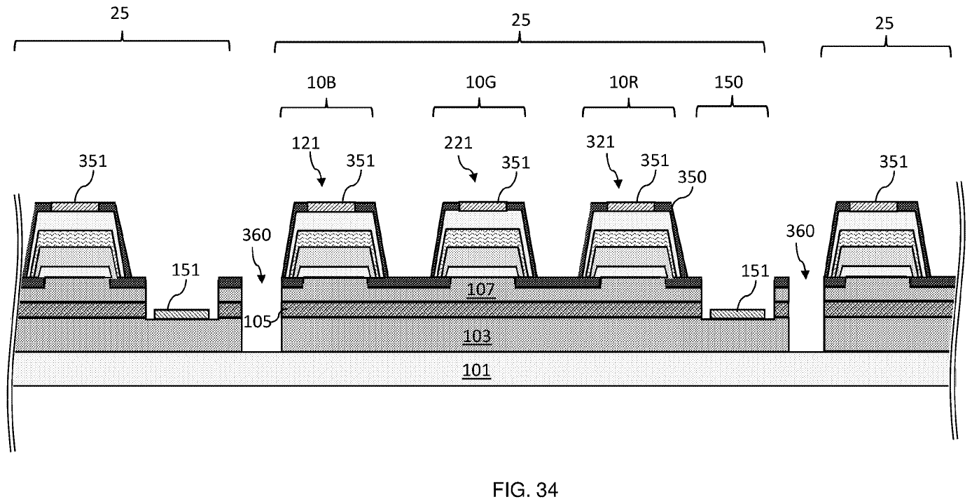

FIG. 34 is a vertical cross-section view of the first exemplary structure including an isolation trench 360 around a multicolor light emitting device pixel 25 according to various embodiments of the present disclosure. Referring to FIG. 34, a photoresist layer (not shown in FIG. 34) may be applied over the exemplary intermediate structure and may be lithographically patterned to provide an opening extending around the periphery of the multicolor light emitting device pixel 25. An etch process can be performed to remove portions of the fourth dielectric material layer 350 (and, if present, the reflector layer 353), the spacer layer 107, the superlattice structure 105 and the first conductivity-type doped semiconductor layer 103 that are exposed through the photoresist layer. The etch process may stop at the initial growth substrate 101. The photoresist layer may be subsequently removed, for example, by ashing.

Accordingly, a trench 360 may be formed around the periphery of the multicolor light emitting device pixel 25. In some embodiments, a network of trenches 360 may be formed around each multicolor light emitting device pixel 25 formed on the initial growth substrate 101. The trenches 360 may electrically isolate the respective pixels 25 and thus may be referred to as isolation trenches 360. In the embodiment shown in FIG. 34, each of the subpixels 10B, 10G, 10R within a given pixel 25 may share a common first conductivity-type doped semiconductor layer 103, a common superlattice structure 107, and a common lower portion 107a of the spacer layer 107. A common contact electrode 150 (i.e., a cathode contact electrode) may electrically contact the common first conductivity-type doped semiconductor layer 103 within the contact region 150 of each multicolor light emitting device pixel 25.

In various embodiments, the mesa portions 121, 221, 321 of each of the subpixels 10B, 10G, 10R in the structures shown in FIG. 34 may include un-etched faceted sidewall surfaces, meaning that the tapered sidewall surfaces (e.g., surfaces 113, 213, 313, 115, 215, 315, 118, 218, 318, 120, 220 and 321) of the respective material layers 116, 216, 316, 118, 217, 317, 119, 219, 319 forming the mesa portions 121, 221, 321 may not be subjected to an etch-back process. This may provide light emitting device subpixels 10B, 10G and 10R having a high quantum efficiency due to the lack of dangling bonds along the faceted sidewall surfaces of the mesa portions 121, 221 and 321.

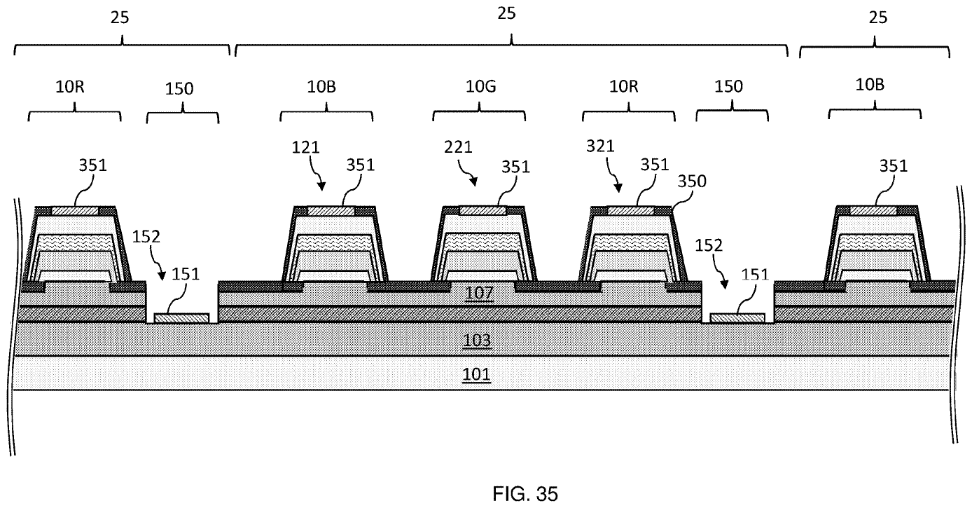

In alternative embodiments, the isolation trenches 360 may be omitted. This may result in a higher PPI display device. FIG. 35 is a vertical cross-section view of an exemplary intermediate structure in which the isolation trenches 360 are omitted according to an embodiment of the present disclosure. In the embodiment shown in FIG. 35, the first conductivity-type doped semiconductor layer 103 may extend continuously between multiple pixels 25 of the array. Each pixel 25 has a contact region 150 including a recessed portion 152 through the spacer layer 107 and the superlattice structure 105 and exposing the surface of the first conductivity-type doped semiconductor layer 103 at the bottom of the recessed portion 152. A contact electrode 151 (e.g., a common cathode electrode) may electrically contact the first conductivity-type doped semiconductor layer 103 in each of the recessed portions 152.

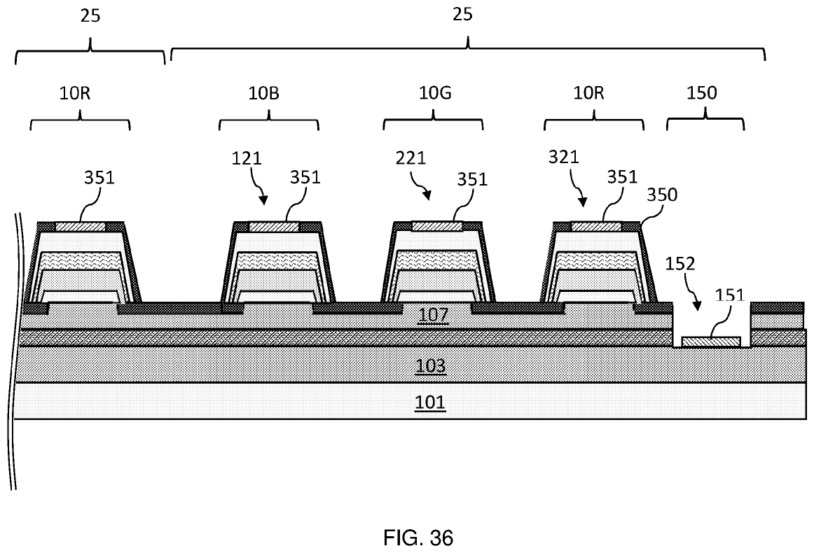

FIG. 36 is a vertical cross-section view of an exemplary intermediate structure in which the isolation trenches are omitted 360 and common contact electrode 150 (e.g., a common cathode electrode) is utilized by multiple pixels 25 according to another embodiment of the present disclosure. In the embodiment shown in FIG. 36, the pixel 25 on the left-hand side does not include a contact region 150 with a contact electrode 150 for the pixel 25. Rather, a single contact region 150 including a contact electrode 150 that electrically contacts the continuous first conductivity-type doped semiconductor layer 103 may function as a common contact electrode 150 (e.g., a common cathode electrode) for multiple pixels 25 of the array, including all of the pixels 25 of the array. In some embodiments, a common contact electrode 150 for multiple pixels 25 of the array may be located on a periphery of the array.

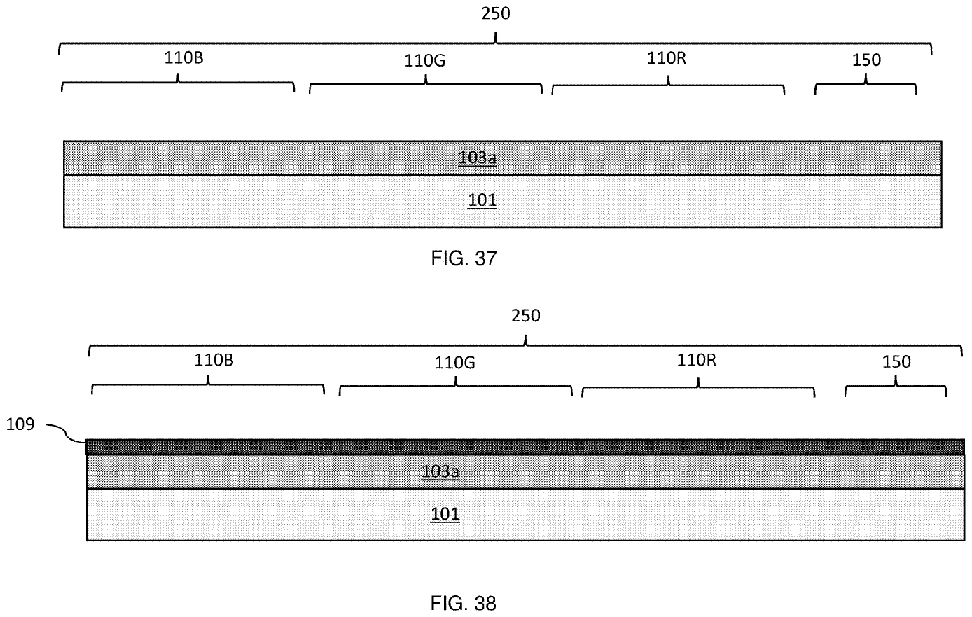

FIGS. 37-44 are sequential vertical cross-section views of a second exemplary structure, which is an in-process structure for fabricating monolithic multicolor light emitting device pixels 25 according to an alternative embodiment of the present disclosure. FIG. 37 is a vertical cross-section view of the second exemplary structure including a continuous doped semiconductor material layer 103a formed over an initial growth substrate 101 according to various embodiments of the present disclosure. The second exemplary structure shown in FIG. 37 may be derived from the first exemplary structure described above with reference to FIG. 3. Thus, repeated discussion of like elements is omitted for brevity. The second exemplary structure of FIG. 37 may differ from the first exemplary structure of FIG. 3 in that a thickness of the continuous doped semiconductor material layer 103a in the second exemplary structure of FIG. 37 may be less than a thickness of the continuous doped semiconductor material layer 103 in the first exemplary structure of FIG. 3. In various embodiments, a thickness of the continuous doped semiconductor material layer 103a in the second exemplary structure of FIG. 37 may be between about 1 μm and about 4 μm, such as in a range of about 2-3 μm (e.g., ≈2.5 μm). The continuous doped semiconductor material layer 103a in the second exemplary structure of FIG. 37 may include a III-V compound semiconductor material (e.g., GaN) that may be doped with dopants of a first conductivity type. Thus, the continuous doped semiconductor material layer 103a may be referred to as a first conductivity-type doped semiconductor material layer 103a.

FIG. 38 is a vertical cross-section view of the second exemplary structure including a continuous first dielectric material layer 109 formed over the continuous first conductivity-type doped semiconductor material layer 103a according to various embodiments of the present disclosure. The continuous first dielectric material layer 109 may be equivalent to the continuous first dielectric material layer 109 described above with reference to FIG. 6. Thus, repeated discussion of the continuous first dielectric material layer 109 is omitted for brevity.

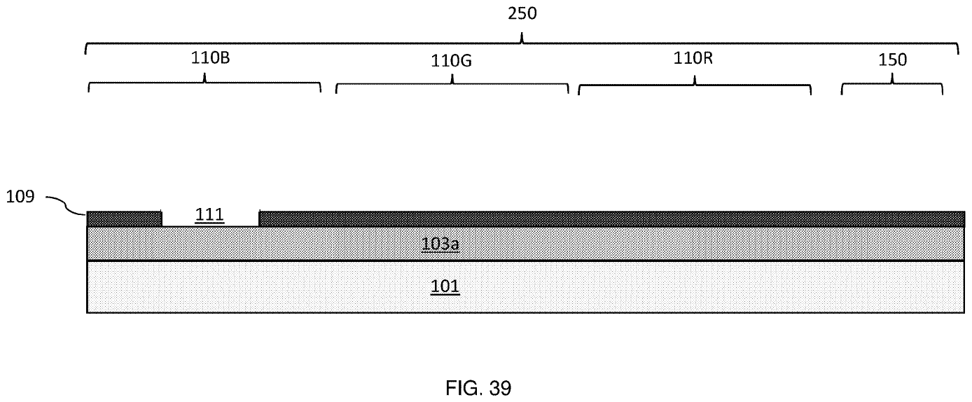

FIG. 39 is a vertical cross-section view of the second exemplary structure including an opening 111 formed through the first dielectric material layer 109 in subpixel region 10B according to various embodiments of the present disclosure. Referring to FIG. 39, a patterned mask may be formed over the first dielectric material layer 109 including an opening within subpixel region 110B, as described above with reference to FIGS. 7 and 8. An etching process as described above with reference to FIG. 9 may be performed to provide an opening 111 through the first dielectric material layer 109 in subpixel region 110B. An upper surface of the continuous first conductivity-type doped semiconductor material layer 103a may be exposed at the bottom of the opening 111. Following the etching process, the patterned mask may be removed using a suitable technique, such as by ashing or dissolution using a solvent.

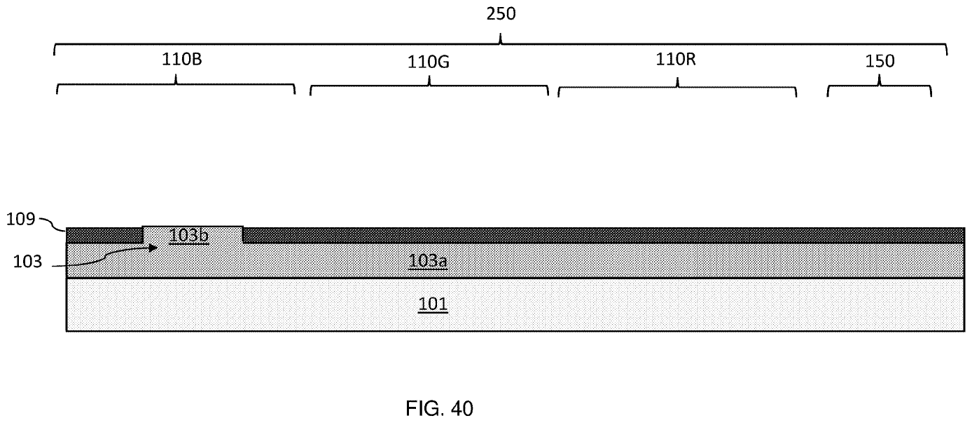

FIG. 40 is a vertical cross-section view of the second exemplary structure including a discrete first conductivity-type semiconductor material layer 103b formed within the opening 111 in the first dielectric material layer 109 in subpixel region 110B according to various embodiments of the present disclosure. The discrete first conductivity-type semiconductor material layer 103b may include a III-V compound semiconductor material that is doped with dopants of the first conductivity type. In various embodiments, the discrete first conductivity-type semiconductor material layer 103b may be composed of the same material as the material of the continuous first conductivity-type semiconductor material layer 103b (e.g., doped GaN). The discrete first conductivity-type semiconductor material layer 103b may be formed using a selective semiconductor deposition process that grows semiconductor material from semiconductor surfaces and does not grow the semiconductor material from dielectric surfaces. Thus, the semiconductor material of the discrete first conductivity-type semiconductor material layer 103b may be selectively grown over the exposed surface of the continuous first conductivity-type semiconductor material layer 103a within the opening 111 in the first dielectric material layer 109. In some embodiments, the discrete first conductivity-type semiconductor material layer 103b may completely fill the opening 111 in the first dielectric material layer 109 such that the upper surface of the discrete first conductivity-type semiconductor material layer 103b may be substantially coplanar with the upper surface of the first dielectric material layer 109. Although a single discrete first conductivity-type semiconductor material layer 103b is shown in FIG. 40, it will be understood that each pixel region 250 of the second exemplary structure may include a discrete first conductivity-type semiconductor material layer 103b located in a subpixel region 110B. The continuous first conductivity-type semiconductor material layer 103a each of the discrete first conductivity-type semiconductor material layers 103b may be considered as forming a single first conductivity-type semiconductor material layer 103 including a continuous lower portion 103a and one or more discrete upper portions 103b laterally surrounded by the first dielectric material layer 109.

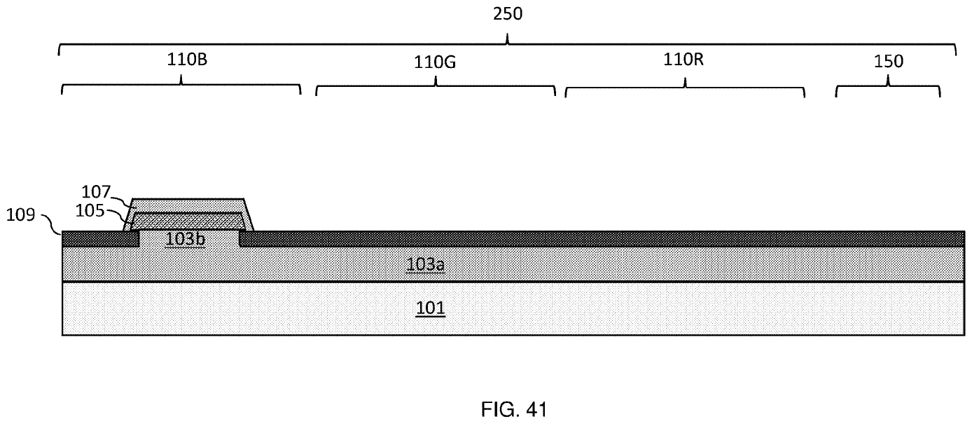

FIG. 41 is a vertical cross-section view of the second exemplary structure including a superlattice structure 105 and a spacer layer 107 formed over the upper portion 103b of the first conductivity-type semiconductor material layer 103 in subpixel region 110B according to various embodiments of the present disclosure. The superlattice structure 105 and the spacer layer 107 may have equivalent compositions and thicknesses as the superlattice structure 105 and the spacer layer 107 of the first exemplary embodiment described above with reference to FIGS. 4, 5 and 9. The superlattice structure 105 and the spacer layer 107 of the second exemplary embodiment may differ from the superlattice structure 105 and the spacer layer 107 of the first exemplary embodiment in that the superlattice structure 105 and the spacer layer 107 of the second exemplary embodiment may include discrete layers formed using a selective semiconductor deposition process that grows semiconductor material from semiconductor surfaces and does not grow the semiconductor material from dielectric surfaces. Thus, the superlattice structure 105 may be selectively grown over the upper portion 103b of the first conductivity-type semiconductor material layer 103 and the spacer layer 107 may be selectively grown over the superlattice structure 105 in subpixel region 110B.

In various embodiments, the superlattice structure 105 may include a mesa structure including a horizontal planar upper surface and tapered sidewalls extending from the horizontal planar upper surface towards the upper surface of the first dielectric material layer 109. A width dimension of the mesa structure may increase between the horizontal planar upper surface of the mesa structure and the upper surface of the first dielectric material layer 109. The spacer layer 107 may include a mesa structure including a horizontal planar upper surface over the horizontal planar upper surface of the superlattice structure 105 and tapered sidewalls extending between the horizontal planar upper surface towards the upper surface of the first dielectric material layer 109 and laterally surrounding the superlattice structure 105. The superlattice structure 105 and the spacer layer 107 may further include bottom surfaces that may be coplanar with one another and may each contact the upper surface of the first dielectric material layer 109. The bottom surface of the superlattice structure 105 may additionally contact the upper portion 103b of the first conductivity-type semiconductor material layer 103.

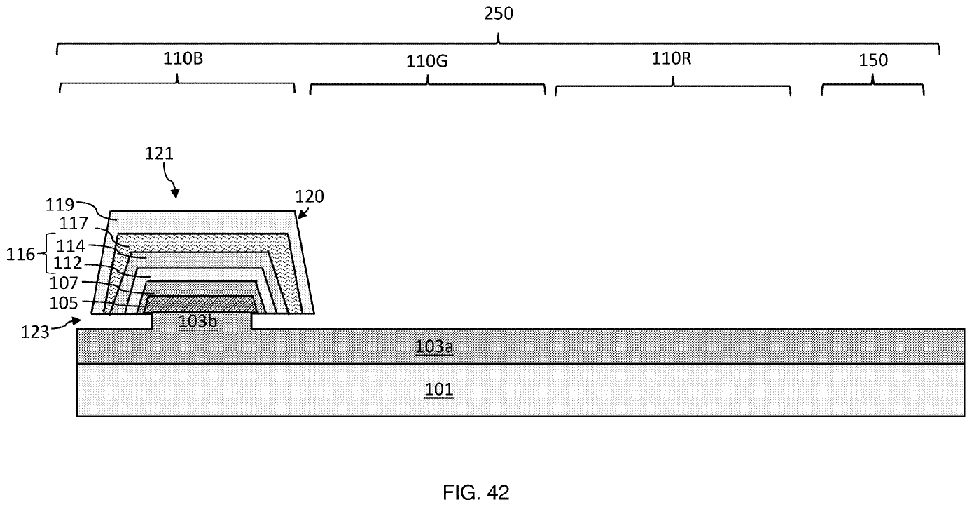

FIG. 42 is a vertical cross-section view of the second exemplary structure including a first light emitting epitaxial semiconductor structure 10B in a pixel region 250 according to various embodiments of the present disclosure. The first light emitting epitaxial semiconductor structure 10B may be formed using the process steps as described above with reference to FIGS. 10-13. In particular, an above-described blue light emitting active region 116 may be selectively grown over the spacer layer 107, an above-described optional electron blocking layer 117 may be selectively grown over the blue light emitting active region 116, and an above-described second conductivity-type doped semiconductor material layer 119 may be selectively grown over the optional electron blocking layer 117 to provide the first light emitting epitaxial semiconductor structure 10B. An above-described etching process may then be performed to remove the first dielectric material layer 109 from the second exemplary structure.

The first light emitting epitaxial structure 10B in the embodiment of FIG. 42 includes a first conductivity-type doped semiconductor material layer 103 over an initial growth substrate 101, where the first conductivity-type doped semiconductor material layer 103 includes a continuous lower portion 103a and an upper portion 103b that forms a pedestal-like structure over the continuous lower portion 103a. The first light emitting epitaxial semiconductor structure 10B further includes a mesa portion 121 over the upper portion 103b of the first conductivity-type doped semiconductor material layer 103. The mesa portion 121 includes a planar horizontal lower surface contacting the upper portion 103a of the first conductivity-type doped semiconductor material layer 103 and the upper surface of the first dielectric material layer 109, a planar horizontal upper surface 122, and a tapered outer sidewall 120 extending between the planar horizonal upper surface 122 and the planar horizontal lower surface of the mesa portion 121. The mesa portion 121 in the embodiment of FIG. 42 includes a superlattice structure 105, a spacer layer 107 over the upper surface of and laterally surrounding the superlattice structure 105, a blue light emitting active region 116 over the upper surface of and laterally surrounding the spacer layer 107, an optional electron blocking layer 117 over the upper surface of and laterally surrounding the active region 116, and a second conductivity-type doped semiconductor material layer 119 over the upper surface of and laterally surrounding the electron blocking layer 117. A recess 123 may be located between the lower surface of the mesa portion 121 and the lower portion 103a of the first conductivity-type doped semiconductor material layer 103 and laterally surrounding the upper portion 103b of the first conductivity-type doped semiconductor material layer 103. A plurality of mesa portions 121 as shown in in FIG. 42 may be located over upper portions 103b of the first conductivity-type doped semiconductor material layer 103, where each mesa portion 121 may form a portion of a first light emitting epitaxial semiconductor structure 10B located within a pixel region 250 of the second exemplary structure.

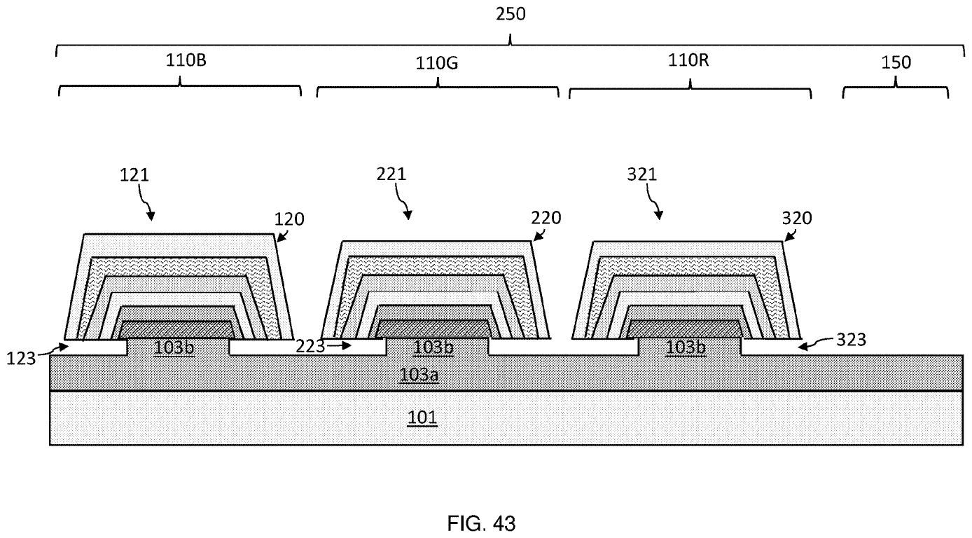

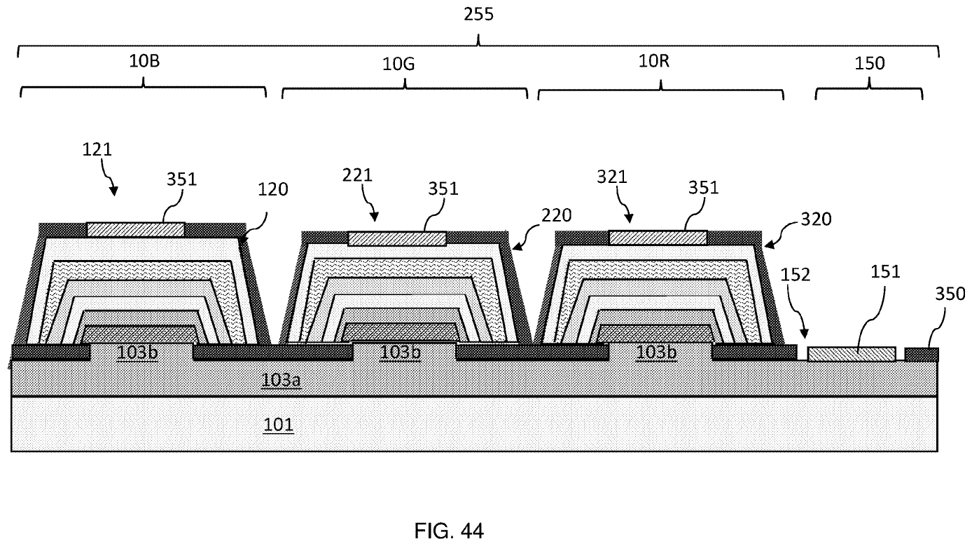

FIG. 43 is a vertical cross-section view of the second exemplary structure including a multicolor light emitting pixel 25 including a first light emitting epitaxial semiconductor structure 10B (i.e., a blue light emitting subpixel 10B), a second light emitting epitaxial semiconductor structure 10G (i.e., a green light emitting subpixel 10G), and a third light emitting epitaxial semiconductor structure 10R (i.e., a red light emitting subpixel 10R) according to various embodiments of the present disclosure. Referring to FIG. 43, the processing steps described above with respect to FIGS. 38-42 may be repeated to form a second light emitting epitaxial semiconductor structure 10G in subpixel region 110G, and may be repeated again to form a third light emitting epitaxial structure 10R in subpixel region 110R. The second light emitting epitaxial semiconductor structure 10G and the third light emitting epitaxial structure 10R may have equivalent structures as the first light emitting epitaxial semiconductor structure 10B described above. In particular, the second light emitting epitaxial semiconductor structure 10G and the third light emitting epitaxial structure 10R may each include a mesa portion 221, 321 over respective upper portions 103b of the first conductivity-type doped semiconductor material layer 103. Each of the mesa portions 221, 321 may include a superlattice structure 205, 305, a spacer layer 207, 307 over the upper surface of and laterally surrounding the superlattice structure 205, 305, an active region 216, 316 over the upper surface of and laterally surrounding the spacer layer 207, 307, an electron blocking layer 217, 317 over the upper surface of and laterally surrounding the active region 216, 316, and a second conductivity-type doped semiconductor material layer 219, 319 over the upper surface of and laterally surrounding the electron blocking layer 117. In the second light emitting epitaxial semiconductor structure 10G, the active region 216 may be a green light emitting active region, and in the third light emitting epitaxial semiconductor structure 10R, the active region 316 may be a red light emitting active region. Recesses 223, 323 may be located between the lower surfaces of the respective mesa portions 221, 321 and the lower portion 103a of the first conductivity-type doped semiconductor material layer 103 and laterally surrounding and upper portion 103b of the first conductivity-type doped semiconductor material layer 103. One or more of the processing steps shown in FIGS. 28-36 may then be performed on the second exemplary structure to form a dielectric material layer 350 over and between the mesa structures 121, 221, 321, contact electrodes 351 contacting each of the mesa structures 121, 221, 321, an additional contact electrode 151 contacting the first conductivity-type doped semiconductor layer 103 in a contact region 150 of the pixel 25, an optional reflector layer 353 over the mesa structures 121, 221, 321, and optional isolation trenches 360 around each pixel 25. FIG. 44 is a vertical cross-section view of the second intermediate structure according to one embodiment illustrating a dielectric material layer 350 over and between the mesa structures 121, 221, 321, contact electrodes 351 (e.g., anode contact electrodes) for each subpixel 10B, 10G and 10R formed over the upper surface of respective mesa structures 121, 221 and 321, and a common contact electrode 151 (e.g., a common cathode electrode) for the multicolor pixel 25 within the contact region 150. In the embodiment of FIG. 44, the recessed portion 152 in the contact region 150 of the pixel 25 may include an opening through the fourth dielectric material layer 350 to expose the lower portion 103a of the first conductivity-type doped semiconductor layer 103.

In the above-described embodiments, the first, second and third connecting portions (i.e., 107b or 103b) of different subpixels 10B, 10G and 10R in the same pixel 25 contact the first conductivity-type common semiconductor material layer (i.e., 107a or 103a) in the same horizontal plane. Thus, the connecting portions of different subpixels 10B, 10G and 10R in the same pixel 25 are laterally co-planar. Likewise, the active regions 116, 216 and 316 different subpixels 10B, 10G and 10R in the same pixel 25 are laterally co-planar and have a bottom surface which is equidistant from the horizontal plane containing the top surface of the first conductivity-type common semiconductor material layer (i.e., 107a or 103a).

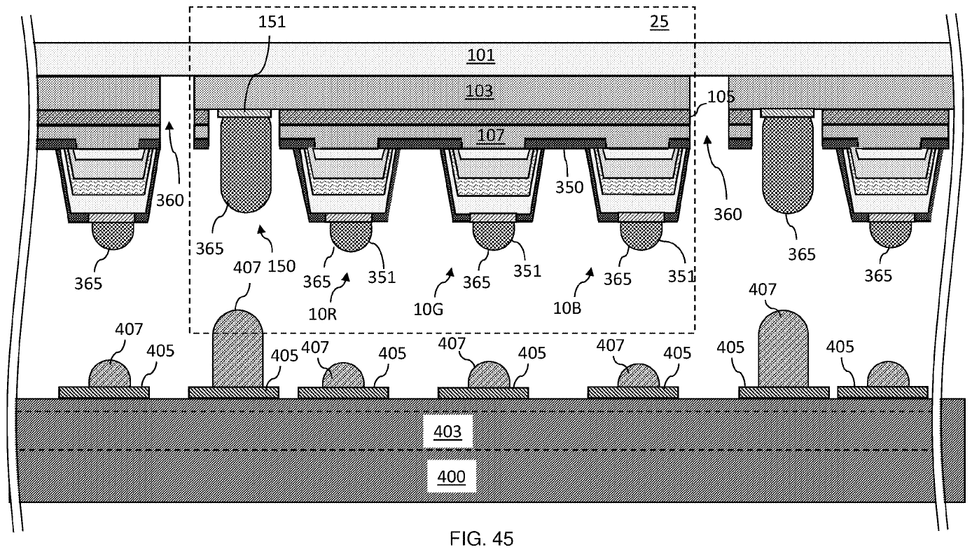

In various embodiments, one or more of the above-described multicolor light emitting pixels 25 may be transferred from an initial growth substrate 101 to a target substrate, such as a backplane, to provide a multicolor display. FIGS. 45-50 are sequential vertical cross-section views of an exemplary process of transferring a multicolor light emitting pixel 25 from an initial growth substrate 101 to a backplane 400 according to an embodiment of the present disclosure. Although FIGS. 45-50 illustrate a transfer process in which a single multicolor light emitting pixel 25 is transferred from the initial growth substrate 101 to the backplane 400, in other embodiments, a plurality of multicolor light emitting pixels 25, such as a contiguous array of multicolor light emitting pixels 25, including all of the multicolor light emitting pixels 25 formed on the initial growth substrate 101, may be transferred from the initial growth substrate 101 to the backplane 400 during a single transfer process. In addition, while FIGS. 45-50 illustrate one example of a suitable transfer process, it will be understood that other suitable processes for transferring one or more multicolor light emitting pixels 25 from an initial growth substrate to a target substrate may also be utilized.

FIG. 45 is a vertical cross-section view showing an initial growth substrate 101 having one or more multicolor light emitting pixels 25 formed thereon and a backplane 400. The exemplary multicolor light emitting pixel 25 shown in FIG. 45 corresponds to the first exemplary structure shown in FIG. 34, although it will be understood that other structures, such as the multicolor light emitting pixel 25 structures described above with reference to FIGS. 32, 33, 35, 36 and/or 44 may also be utilized. In the embodiment shown in FIG. 45, the orientation of the structure is inverted (i.e., flipped-over) relative to the orientation shown in FIG. 34, such that the initial growth substrate 101 is located on a top-side of the structure and the mesa structures 121, 221, 321 of the subpixels 10B, 10G and 10R are located on a bottom-side of the structure. The first contact electrode 151 contacts a rear surface of the first conductivity-type semiconductor material layer 103 that faces the backplane 400. A diode-side bonding material portion 365 may be attached to the contact electrodes 351 of each of the subpixels 10B, 10G and 10R and to the contact electrode 151 in the contact region 150 of each pixel 25. In one embodiment, the diode-side bonding material portions 365 may be solder material portions such as pure tin or an alloy of tin and indium.

The backplane 400 (which may also be referred to as a “backplane substrate” 400) may include any suitable substrate configured to affix multiple devices, such as light emitting devices, thereon. In one embodiment, the backplane 400 may include a substrate of silicon, glass, plastic, and/or at least other material that can provide structural support to the devices to be subsequently transferred thereupon. In one embodiment, the backplane 400 may be a passive backplane, in which metal interconnect structures 403 comprising metallization lines are present, for example, in a criss-cross grid. In some embodiments, active device circuits (such as field effect transistors) may not be present in the backplane 400. In another embodiment, the backplane 400 may be an active backplane, which includes metal interconnect structures 403 as a criss-cross grid of conductive lines and further includes a device circuitry at one or more intersections of the criss-cross grid of conductive lines. The device circuitry may include one or more transistors. The backplane 400 may also include bonding pads 405 located on a first (i.e., upper) surface of the backplane 400. The bonding pads 405 may be electrically coupled to the metal interconnect structures 403. The bonding pads 405 may be composed of a suitable conductive material, such as gold, copper, nickel, titanium, titanium nitride, tungsten, or tungsten nitride, including combinations (e.g., stacks) and/or alloys thereof. The arrangement of the bonding pads 405 on the backplane 400 may correspond to the arrangement of the light emitting device subpixels 10B, 10G and 10R and the contact region 150 of the pixel(s) 25 formed on the initial growth substrate 101. A backplane-side bonding material portion 407 may be attached to the bonding pads 405. In one embodiment, the backplane-side bonding material portions 407 may be solder material portions such as pure tin or an alloy of tin and indium.

The initial growth substrate 101 and the backplane 400 may be disposed such that the lower surfaces of the subpixels 10B, 10G, 10R of the multicolor light emitting device pixel(s) 25 face the upper surface of the backplane 400, and each of the diode-side bonding material portions 365 attached to a contact electrode 351 of a subpixel 10B, 10G and 10R is aligned over a backplane-side bonding material portion 407 located over a bonding pad 405 of the backplane 400. In addition, the diode-side bonding material portion 365 attached to the contact electrode 151 in the contact region 150 of the pixel(s) 25 may be aligned over a backplane-side bonding material portion 407 located over a bonding pad 405 of the backplane 400.

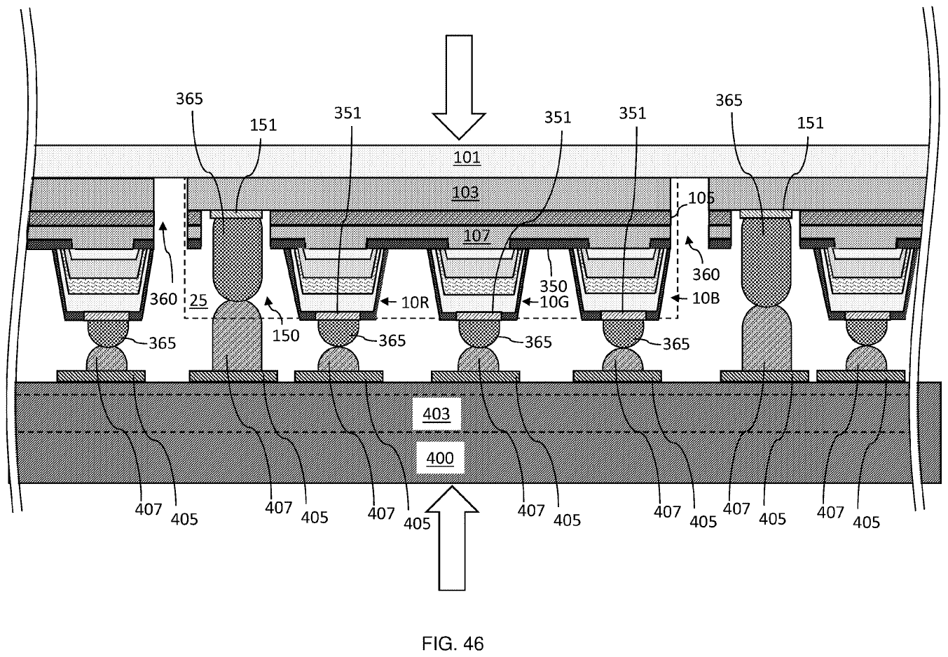

FIG. 46 is a vertical cross-section view illustrating the initial growth substrate 101 moved vertically relative to the backplane 400 such that each facing pair of a diode-side bonding structure 365 and a backplane-side bonding material portion 407 contact each other according to an embodiment of the present disclosure. In general, at least one bonding material portion 365, 407 may be disposed between each vertically neighboring pair of a respective one of the bonding pads 405 and a respective one of the contact electrodes 351 of a subpixel 10B, 10G, 10R, and at least one bonding material portion 365, 407 may be disposed between a vertically neighboring pair of a bonding pad 405 and a contact electrode 151 in the contact region 150 of the pixel 25. In some embodiments, a pair of a diode-side bonding material portion 365 and a backplane-side bonding material portion 407 may be provided between each vertically neighboring pair of a respective one of the bonding pads 405 and a contact electrode 351 and 151, as shown in FIG. 46. Alternatively, either the diode-side bonding material portion 407 or the backplane-side bonding material portion 407 may be omitted. In some embodiments, a solder flux (not shown in FIG. 46) may be applied between the backplane 400 and the pixels 25 such that the solder flux laterally surrounds each bonding material portion 365, 407. The solder flux may be any suitable liquid flux which reacts with tin oxide to leave conductive tin bonding material portions 365, 407.

In some embodiments, the assembly of the backplane 400 and the initial growth substrate 101 may be provided within a fixture (not shown) that may hold the assembly in place without lateral slippage. The fixture may include, for example, a clamp assembly that may be configured to apply compressive force against the backside(s) of the initial growth substrate 101 and/or the backplane 400. The clamp assembly may hold the assembly of the backplane 400 and the initial growth substrate 101 in such a manner that optical radiation may be allowed to pass through at least a portion of the clamp assembly and the initial growth substrate 101 during one or more subsequent optical irradiation steps described in further detail below.

Referring again to FIG. 46, a compressive force may be applied to the assembly of the backplane 400, the bonding material portions 365, 407 and the initial growth substrate 101 along a vertical direction, as indicated by the arrows in FIG. 46. In some embodiments, the compressive force may be applied by the above-described clamp assembly. The magnitude of the compressive force may be selected such that the bonding material portions 365, 407 are not deformed in a significant manner, i.e., the bonding material portions 365, 407 may maintain the shapes as provided prior to clamping, and without bonding the respective bonding material portions 365 and 407 to each other.

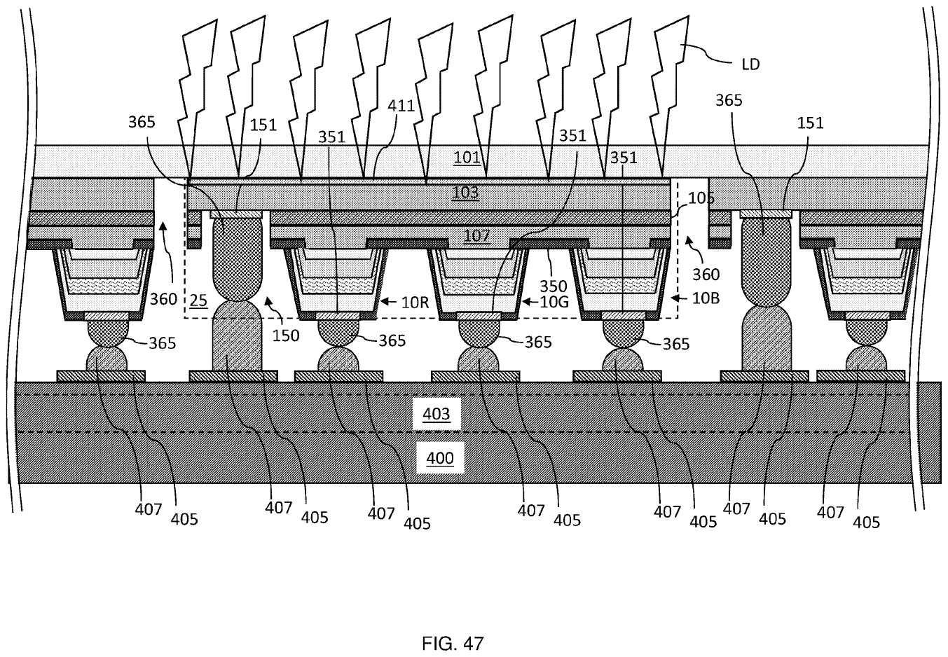

FIG. 47 is a vertical cross-section view illustrating a laser irradiation process using a detachment laser beam LD according to various embodiments of the present disclosure. Referring to FIG. 47, a set of all light emitting device structures that are subsequently transferred from the initial growth substrate 101 to the backplane 400, which may be for example, individual pixels 25 and/or groups of pixels 25 located on the initial growth substrate 101, may be referred to as a first subset of the light emitting device structures. In various embodiment, a detachment laser beam LD may be used to perform a laser liftoff process to lift off the first subset of the light emitting device structures, which may be referred to as a detachment laser irradiation process.

Referring to FIG. 47, a laser irradiation process may be performed to irradiate the first conductivity-type doped semiconductor material layer 103 of each light emitting device structure to be subsequently transferred to the backplane 400 using a detachment laser beam LD. Thus, in the embodiment shown in FIG. 47, the first conductivity-type doped semiconductor material layer 103 within the multicolor pixel 25 may be irradiated with the detachment laser beam LD. In the embodiment shown in FIG. 47, the multicolor pixel 25 includes a common first conductivity-type doped semiconductor material layer 103, and thus the first conductivity-type doped semiconductor material layer 103 may be irradiated over the entire area of the first conductivity-type doped semiconductor material layer 103 within pixel 25 (i.e., the contiguous area of the first conductivity-type doped semiconductor material layer 103 in pixel 25 that is surrounded by an isolation trench 360 may be irradiated). In embodiments in which the lateral dimensions (e.g., diameter) of the detachment laser beam LD is larger than the corresponding lateral dimensions of the multicolor pixel 25, the entire area of the first conductivity-type doped semiconductor material layer 103 within the pixel 25 may be simultaneously irradiated by the detachment laser beam LD. Alternatively, the area of the first conductivity-type doped semiconductor material layer 103 within the pixel 25 may irradiated sequentially, such as by scanning the detachment laser beam LD across different portions of the first conductivity-type doped semiconductor material layer 103 located within the pixel 25.

In some embodiments, the detachment laser beam LD may have an ultraviolet peak wavelength or a peak wavelength in a visible light range, and may have a peak wavelength that is preferentially absorbed by constituent atoms (e.g., gallium and/or nitrogen atoms) of the first conductivity-type doped semiconductor material layer 103. Without wishing to be bound by a particular theory, it is believed that irradiation of the detachment laser beam LD onto the first conductivity-type doped semiconductor material layer 103 may result in the evaporation of nitrogen atoms while producing minimal or no evaporation of gallium atoms. The irradiation thus reduces the atomic percentage of nitrogen in the remaining material.

In one embodiment, and without being bound by a particular theory, it is believed that following irradiation by the detachment laser beam LD, at least a portion of the first conductivity-type doped semiconductor material layer 103 may be converted into gallium-rich drops. The gallium-rich drops may consist of pure liquid gallium-rich drops or may include an alloy of gallium and nitrogen containing gallium at an atomic concentration greater than 55%, such as 60% to 99%. The liquid gallium-rich drops may solidify into solid gallium-rich material portions 411 (e.g., pure gallium or gallium rich alloy particles or regions) after the irradiation if the temperature of the assembly is maintained below the melting temperature of gallium (e.g., 29.76° C.) or its alloy. In one embodiment, within each first conductivity-type doped semiconductor material layer 103 of the first subset of the light emitting device structures that are irradiated by the detachment laser beam LD, a portion of the first conductivity-type doped semiconductor material layer 103 located near the interface between the first conductivity-type doped semiconductor material layer 103 and the initial growth substrate 101 may include gallium-rich material portions 411 (i.e., solid pure gallium or gallium rich alloy particles or regions), as shown in FIG. 47. In some embodiments, the gallium-rich material portions 411 may include gallium atoms at an atomic concentration greater than 55%, such as 60% to 100%. The gallium-rich material portions 411 may have an average thickness in a range from 5 nm to 100 nm, such as from 10 nm to 50 nm, although lesser and greater thicknesses are within the scope of disclosure. Each gallium-rich material portion 411 may include a continuous material layer or may include a cluster of ball-shaped material portions. In various embodiments, first conductivity-type doped semiconductor material layers 103, or portions thereof, that are not located in light emitting device structures to be subsequently transferred to the backplane 400 and are thus not irradiated with the detachment laser beam LD may not include any gallium-rich material portions 411. In some embodiments, the gallium-rich material portions 411 within first conductivity-type doped semiconductor material layers 103 that are irradiated with the detachment laser beam LD may include gallium atoms at an atomic concentration of at least 55% and may have a lower melting point than the first conductivity-type doped semiconductor material layers 103 that are not irradiated with the detachment laser beam LD, and which may include gallium atoms at an atomic concentration of less than 55%, such as at about 50%.

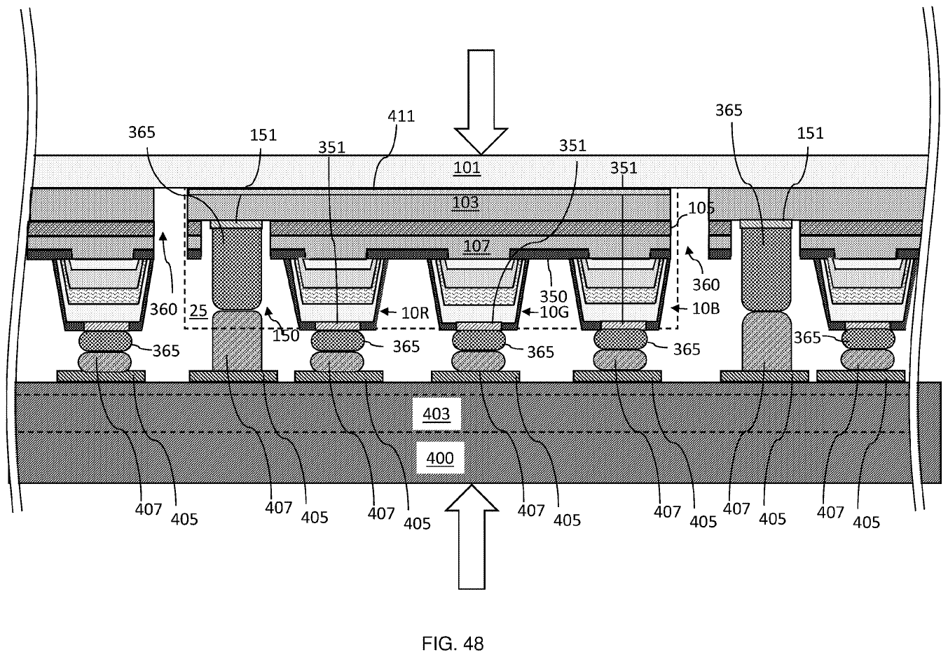

FIG. 48 is a vertical cross-section view illustrating the initial growth substrate 101 and the backplane 400 following the application of a compressive force that induces deformation of the bonding material portions 365 and 407 according to an embodiment of the present disclosure. Referring to FIG. 48, an additional compressive force may be applied to the assembly of the backplane 400, the bonding material portions 365, 407 and the initial growth substrate 101 along a vertical direction, as indicated by the arrows in FIG. 48. In some embodiments, the compressive force may be applied by the above-described clamp assembly. The magnitude of the compressive force may be selected to induce deformation of the bonding material portions 365 and 407 (i.e., to coin the bonding material portions to smooth out any rough bonding surfaces). Thus, each mating pair of a respective diode-side bonding material portion 365 and a respective backplane-side bonding material portion 407 may be pressed against each other at a second pressure that is greater than the first pressure after conversion of the subset of the first conductivity-type doped semiconductor material layers 103 into the gallium-rich material portions 411. The second pressure is sufficient to produce deformation of the diode-side bonding material portions 365 and the backplane-side bonding material portions 407.

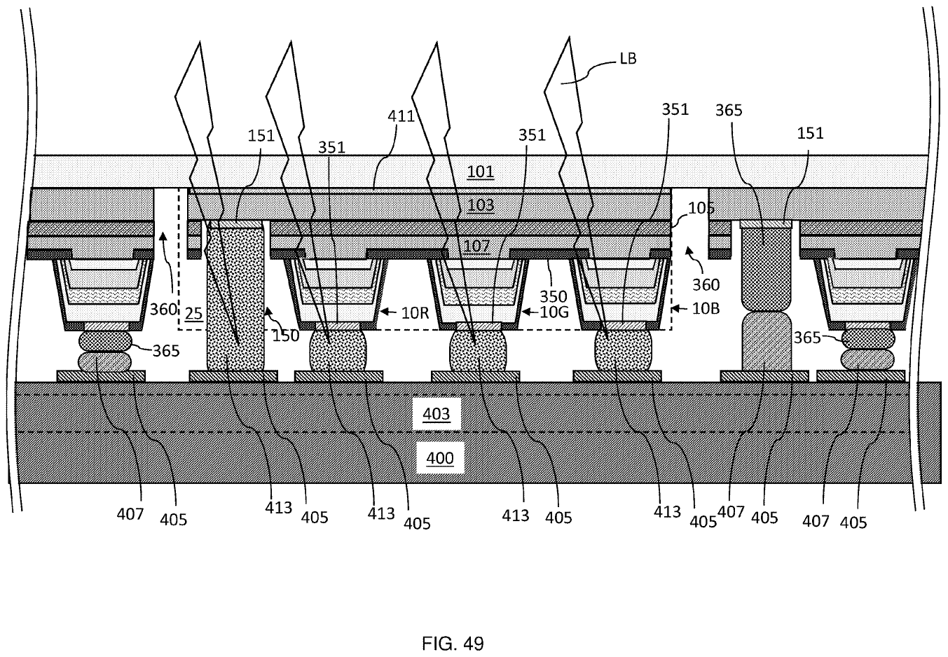

FIG. 49 is a vertical cross-section view illustrating a bonding laser irradiation process that induces reflow and subsequent bonding of mating pairs of diode-side bonding material portions 365 and backplane-side bonding material portions 407 according to an embodiment of the present disclosure. Referring to FIG. 49, the mating pairs of diode-side bonding material portions 365 and backplane-side bonding material portions 407 underlying each light emitting device (e.g., multicolor pixel 25) of the first set of light emitting devices to be transferred to the backplane 400 may be irradiated using a laser beam LB. The laser beam LB may have a photon energy that is less than the band gap of the III-V compound semiconductor materials (e.g., gallium and nitrogen containing materials) in the light emitting devices, and thus may pass through the light emitting devices to the bonding material portions 365, 407. For example, the laser beam LB employed during the bonding laser irradiation process may be an infrared laser beam such as a carbon dioxide laser beam having a peak wavelength of 9.4 microns or 10.6 microns.

Each mating pair of a diode-side bonding material portion 365 and a backplane-side bonding material portion 407 that is irradiated by the laser beam LB may be heated to a reflow temperature at which the bonding materials (which may be solder materials) of the pair of the diode-side bonding material portion 365 and the backplane-side bonding material portion 407 reflow. Upon termination of the irradiation of the laser beam LB, the reflowed material may re-solidify to provide a re-solidified bonding material portion 413. Each re-solidified bonding material portion 413 is bonded to a bonding pad 405 of the backplane 400 and a contact electrode 351 or 151 of a multicolor pixel 25 to be subsequently transferred to the backplane 400.

In one embodiment, the laser beam LB may have a rectangular intensity profile have a uniform intensity as a function of beam width rather than a gaussian intensity profile which has a peak intensity as a function of beam width. In this embodiment, the laser beam LB width may be wider than one pixel 25, and may be as wide as 2 or more pixels 25. In this case, the laser beam LB may simultaneously irradiate plural mating pairs of the diode-side bonding material portion 365 and the backplane-side bonding material portion 407 for plural pixels 25.

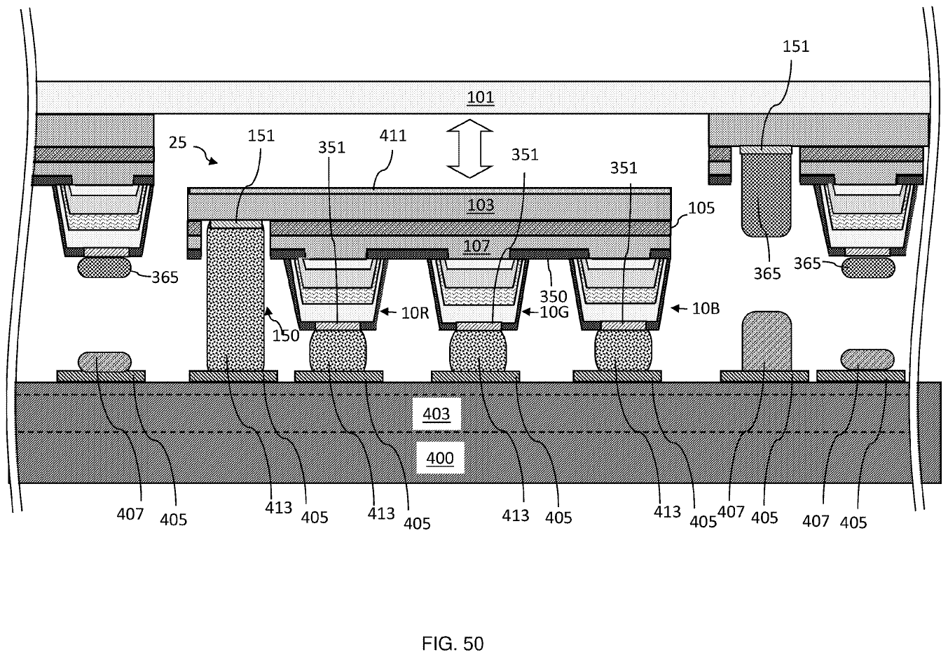

FIG. 50 is a vertical cross-section view illustrating a multicolor light emitting device pixel 25 transferred from the initial growth substrate 101 to the backplane 400 according to an embodiment of the present disclosure. Referring to FIGS. 49 and 50, following the above-described bonding laser irradiation process, the assembly including the initial growth substrate 101, the light emitting devices 25, and the backplane 400 may be heated to a temperature above the melting temperature of the gallium-rich material portions 411 of the first conductivity-type doped semiconductor layers 103 but below the melting temperature of the remaining portions of the first conductivity-type doped semiconductor layers 103 (e.g., below the melting temperature of gallium nitride). For example, if the gallium-rich material portions 411 are composed of pure gallium, then the temperature may be raised to at least 30 degrees Celsius, such as 35 to 50 degrees Celsius to melt the gallium-rich material portions 411 into gallium-rich drops. This may enable each of the light emitting devices (e.g., multicolor pixels 25) underlying a gallium-rich portion 411 to be easily separated from the initial growth substrate 101, as indicated by the arrow in FIG. 50. For example, the initial growth substrate 101, and any light emitting devices remaining attached thereto, may be pulled apart from the backplane 400 and the first set of light emitting devices 25 bonded thereto by the re-solidified bonding material portions 413 with a force less than 100 N.

Although a single multicolor light emitting device pixel 25 is shown bonded to the backplane 400 in FIG. 50, it will be understood a plurality of multicolor light emitting device pixels 25 may be similarly bonded to the backplane 400 to form a direct view multicolor display. In some embodiments, a contiguous region of multicolor light emitting pixels 25, including all the multicolor light emitting pixels 400 that form the display may be transferred to the backplane 400 from a common initial growth substrate 101 in a single transfer process such as described above with reference to FIGS. 49-50. In some embodiments, a center-to-center spacing of neighboring multicolor light emitting device pixels 25 of the display may be the same as the center-to-center spacing of neighboring multicolor light emitting device pixels 25 on the initial growth substrate 101 from which the pixels 25 were transferred. In some embodiments, a density of the pixels 25 on the display may be at least about 1100 PPI. In some embodiments, a space separating adjacent pixels 25 of the display may be less than about 10 μm, such as less than about 5 μm (e.g., ≤2 μm), including less than about 1 μm. In some embodiments, a space separating adjacent subpixels (10B, 10G, 10R) in each pixel 25 of the display may be less than about 10 μm, such as less than about 5 μm (e.g., ≤2 μm), including less than about 1 μm, such as 500 nm to 2 μm for example.

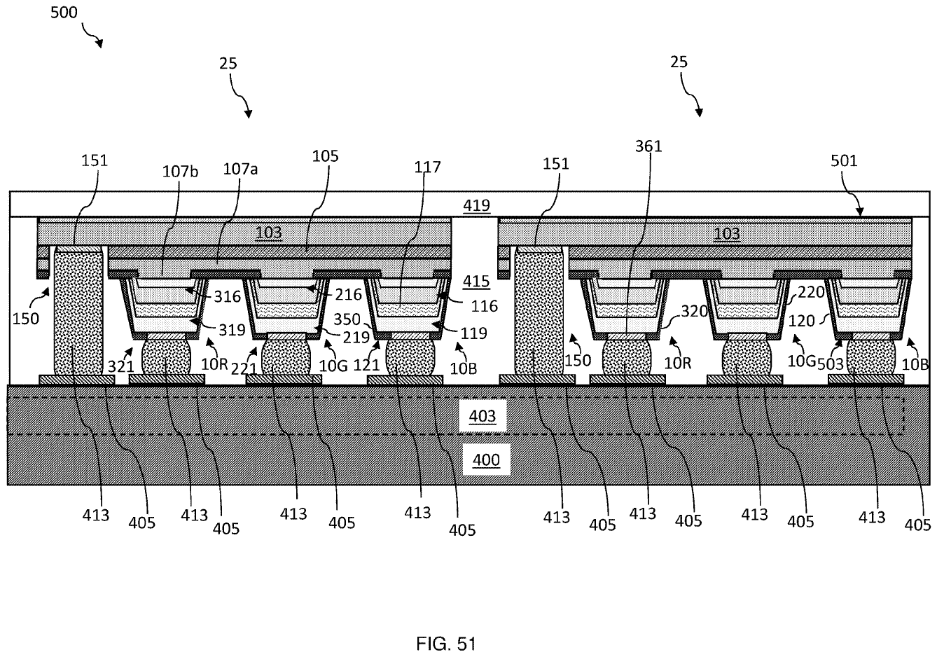

FIG. 51 is a vertical cross-section view of a portion of a display 500 including a plurality of multicolor light emitting device pixels 25 mounted to a backplane 400 according to an embodiment of the present disclosure. Referring to FIG. 51, following the transfer of a plurality of multicolor light emitting device pixels 25 to the backplane, a dielectric matrix 415 may optionally be provided within the spaces between neighboring pixels 25 and in the spaces between light emitting device subpixels 10B, 10G, 10R that are bonded to the backplane 400. The dielectric matrix 415 may include a self-planarizing dielectric material such as spin-on glass (SOG) or polymer, or may be planarized by a recess etch or chemical mechanical planarization. The planar surface of the dielectric matrix 415 as planarized may be within the horizontal plane including the planar upper surfaces of each of the pixels 25 of the display 500, or may be vertically recessed below the horizontal plane including the planar upper surfaces of the pixels 25. An optional transparent passivation dielectric layer 419 may be formed over the front side surfaces 501 of the pixels 25. The transparent passivation dielectric layer 419 may include silicon nitride or silicon oxide. Other suitable dielectric materials are within the contemplated scope of disclosure.

Referring again to FIG. 51, a direct view display device 500 according to one embodiment includes at least one multicolor light emitting device pixel 25 bonded to a backplane 400. Each of the multicolor light emitting device pixels 25 bonded to the backplane may include a plurality of semiconductor material subpixels (10B, 10G, 10R) where each semiconductor material subpixel (10B, 10G, 10R) is configured to emit light having a different peak wavelength. Each of the multicolor light emitting device pixels 25 may be a lateral light emitting device in which both the p-side and n-side contact electrodes 351 and 151 are located on the same side of the pixel 25 and are bonded to the backplane 400 via a bonding material portion 413. In particular, each semiconductor material subpixel (10B, 10G, 10R) may include a contact electrode 351 that is bonded to a corresponding bonding pad 405 of the backplane 400 by a bonding material portion 413. The multicolor light emitting device pixels 25 may further include a contact area 150 including a common contact electrode 151 that is bonded to a corresponding bonding pad 405 of the backplane 400 by a bonding material portion 413. The common contact electrode 151 may electrically contact a first conductivity type doped semiconductor layer 103 that may extend continuously between the semiconductor material subpixels (10B, 10G, 10R) of the multicolor pixel 25. The common contact electrode 151 may also be referred to as a first contact electrode 151 of the multicolor light emitting device pixel 25, and the contact electrodes 351 that contact each of the semiconductor material subpixels (10B, 10G, 10R) of the multicolor light emitting device pixel 25 may each be referred to as second electrodes 351.

In the embodiment shown in FIG. 51, each of the semiconductor material subpixels (10B, 10G, 10R) may include a front side surface 501 configured to emit light therethrough, and a rear side surface 503 facing the backplane 400. Each of the semiconductor material subpixels (10B, 10G, 10R) may include a front side portion (103, 105, 107a) adjacent to the front side surface 501 of the semiconductor material subpixel (10B, 10G, 10R), a rear side portion (121, 221, 321) adjacent to the rear side surface 503 of the semiconductor material subpixel (10B, 10G, 10R) and a semiconductor connecting portion 107b between the front side portion (103, 105, 107a) and the rear side portion (121, 221, 321). The front side portion (103, 105, 107a) of each of the semiconductor material subpixels (10R, 10G, 10R) may include a first conductivity-type doped semiconductor material layer 103, and may optionally also include a superlattice structure 105 and/or a portion of a spacer layer 107a. The rear side portion (121, 221, 321) of each of the semiconductor material subpixels (10B, 10G, 10R) may include an active region (116, 216, 316) and a second conductivity-type doped semiconductor material layer (119, 219, 319), and may optionally further include an electron blocking layer 117. The rear side portion (121, 221, 321) of each of the semiconductor material subpixels (10R, 10G, 10R) may include first and second planar surfaces extending parallel to a major surface of the backplane 400 (i.e., the surface of the backplane 400 to which the respective semiconductor material subpixels (10B, 10G, 10R) are bonded), and a tapered sidewall (120, 220, 320) extending between the first and second planar surfaces. A lateral dimension of the rear side portion (121, 221, 321) of each of the semiconductor material subpixels (10B, 10G, 10R) may decrease between the first and second planar surfaces along a direction extending towards the backplane 400.

A dielectric material layer 350 may extend over the tapered sidewall (120, 220, 320) and at least a portion of the first and second planar surfaces of the rear side portion (121, 221, 321) of each of the semiconductor material subpixels (10B, 10G, 10R), and may laterally surround the semiconductor connecting portion 107b. The dielectric material layer 350 may extend continuously over each of the semiconductor material subpixels (10B, 10G, 10R). The semiconductor connecting portion 107b in each of the semiconductor material sub-pixels (10B, 10G, 10R) may have a lateral dimension along a direction parallel to the major surface of the backplane 400 that is less than the lateral dimensions of the front side portion (103, 105, 107a) and the rear side portion (121, 221, 321) of the respective semiconductor material sub-pixel (10B, 10G, 10R).

In the embodiment FIG. 51, the semiconductor connecting portion 107b between the front side portion (103, 105, 107a) and the rear side portion (121, 221, 321) in each of the semiconductor material subpixels (10B, 10G, 10R) includes a portion of the spacer layer 107b. In other embodiments, the light emitting device pixels 25 may have a structure as shown in FIG. 44. In other words, the front side portion (103a) of each of the semiconductor material subpixels (10B, 10G, 10R) may include a portion 103a of the first conductivity-type doped semiconductor material layer 103 that may extend continuously between the semiconductor material subpixels (10B, 10G, 10R) and may electrically contact the common contact electrode 151 in the contact region 150 of the multicolor pixel 25. Another portion 103b of the first conductivity-type doped semiconductor material layer may form the semiconductor connecting portion 103b in each of the semiconductor material subpixels (10B, 10G, 10R). The rear side portion (121, 221, 321) of each of the semiconductor material subpixels (10B, 10G, 10R) may include a superlattice structure 105, a spacer layer 107, an active region (116, 216, 316) and a second conductivity-type doped semiconductor material layer (119, 219, 319), and may optionally further include an electron blocking layer 117.

In still further embodiments, a reflector layer 353 as shown in FIGS. 32 and 33 may be located over the dielectric material layer 350 and may extend over at least the tapered sidewall (120, 220, 320) and a portion of a planar surface of the rear side portion (121, 221, 321) of each of the semiconductor material subpixels (10B, 10G, 10R).

In still further embodiments, a plurality of multicolor pixels 25 may be continuous with one another as shown in FIGS. 35 and 36, such that the first conductivity-type doped semiconductor layer 103 may extend continuously between multiple pixels 25 of the display device 500. In some embodiments, each of the pixels 25 may have a contact region 150 including a common contact electrode 151 as shown in FIG. 35. In some embodiments, a single contact region 150 including a contact electrode 151 may function as a common contact electrode 151 for multiple pixels 25 as shown in FIG. 36.

Various embodiments of the present disclosure may include direct view display devices and methods of fabricating direct view display devices having relatively low pixel pitch. For example, certain types of direct view displays, such as displays for TV monitors, may have a relatively low pixel density, such as 500 pixels-per-inch (PPI) or less, including 300 PPI or less. In case of a direct transfer method as described above in which multicolor pixels are transferred directly from an initial growth substrate to the backplane of the display device, this may result in poor utilization of the growth substrate (e.g., a semiconductor wafer) since the pitch (i.e., the center-to-center spacing) of the multicolor light emitting device pixels matches the pitch of the multicolor light emitting device pixels of the display device.

Various embodiments include a transfer method in which the pitch of the multicolor light emitting device pixels on the initial growth substrate is not identical to the pitch of the multicolor light emitting device pixels on the backplane of the display device. In particular, the pitch of the multicolor light emitting device pixels on the backplane of the display device may be greater than the pitch of the multicolor light emitting pixels on the initial growth substrate. This may enable more efficient utilization of the initial growth substrate since a greater number of closely-packed pixels may be formed on the initial growth substrate and subsequently transferred to the backplane such that there is a greater inter-pixel spacing between the pixels.

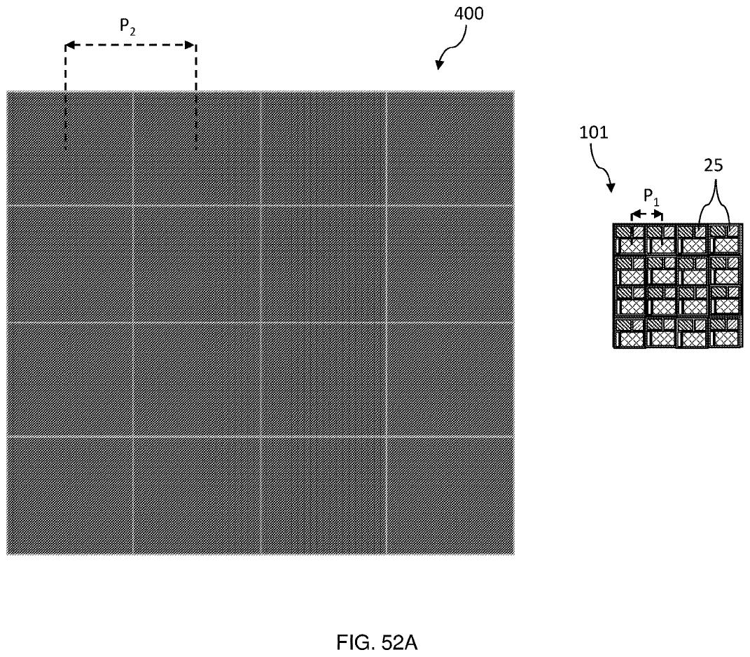

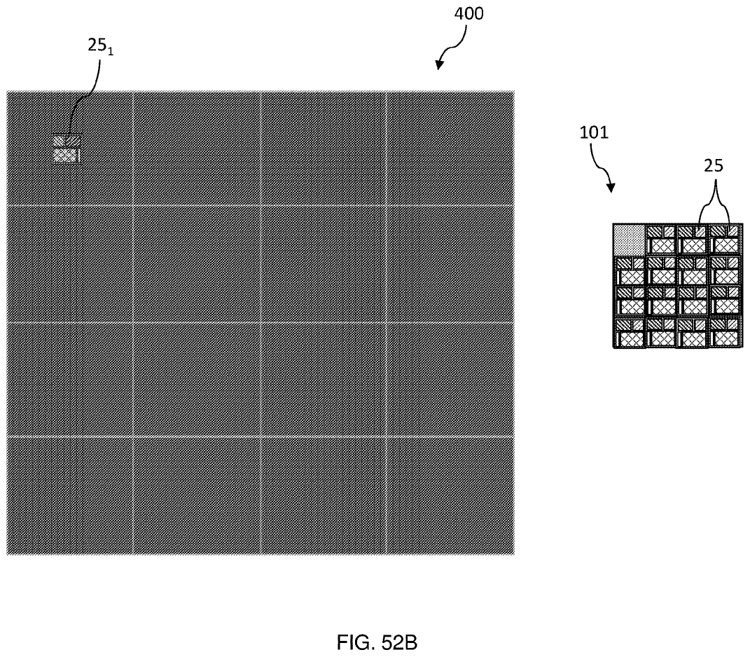

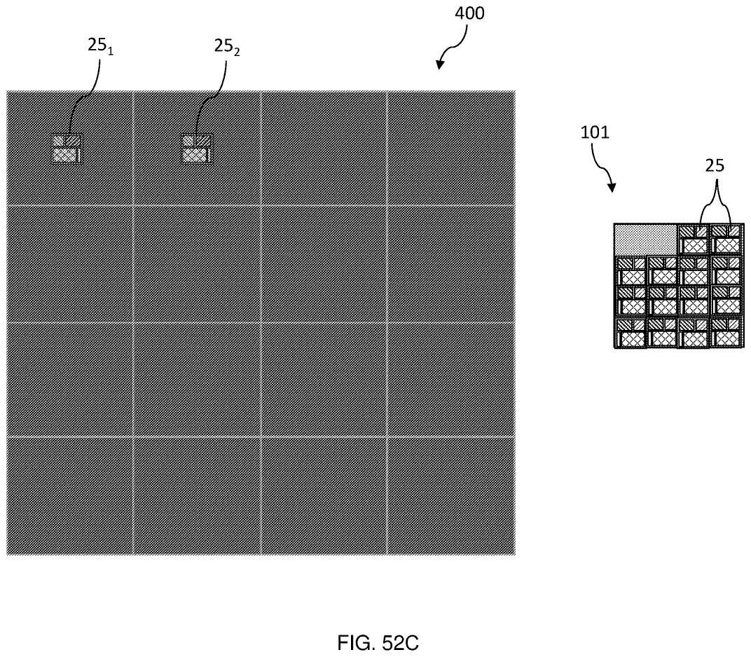

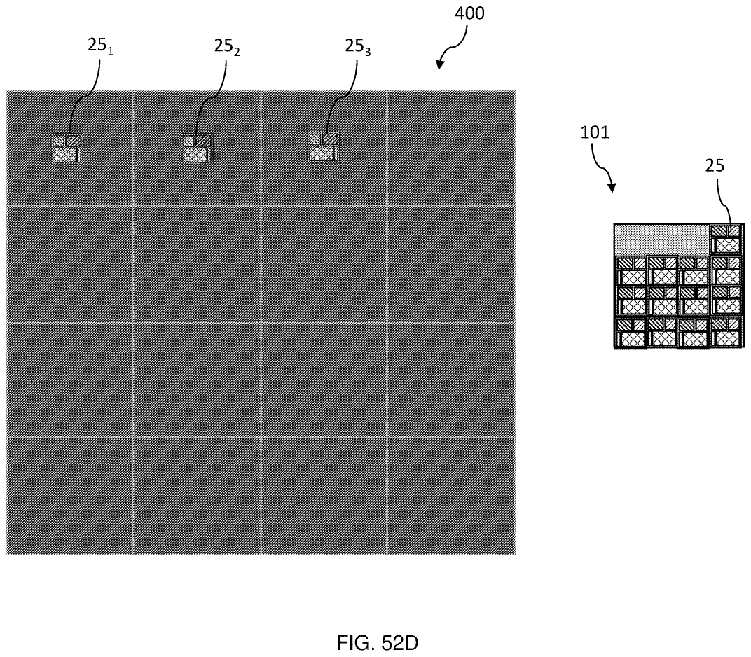

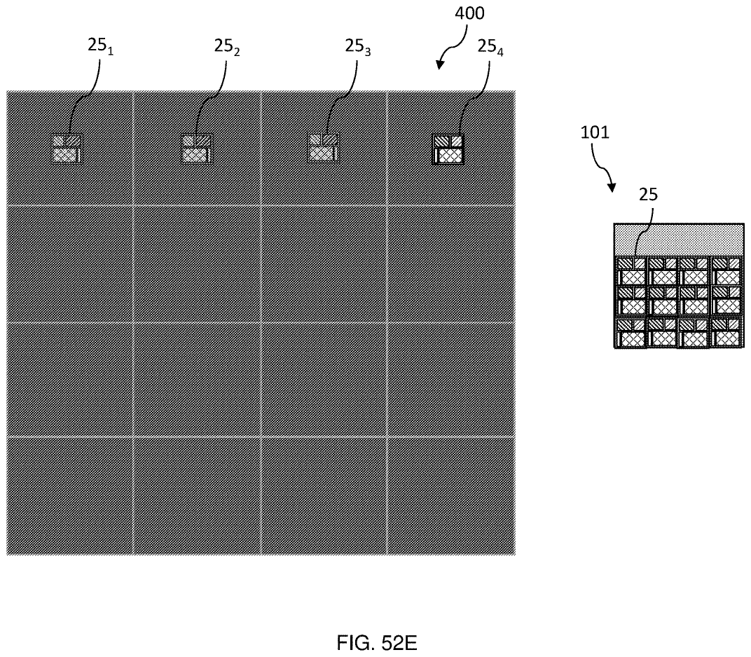

FIGS. 52A-52E schematically illustrate a method of transferring multicolor light emitting device pixels 25 from an initial growth substrate 101 to a target substrate 400 (e.g., a backplane 400 of a direct view display device 500) according to an embodiment of the present disclosure. Referring to FIG. 52A, the plurality of pixels 25 formed on the initial growth substrate 101 may have a densely-packed configuration with a first pitch P₁ between adjacent pixels 25. The pixels 25 may be transferred to a target substrate 400 to provide a display device having a second pitch P₂ between adjacent pixels 25 that is greater than the first pitch P₁. In one non-limiting example, the target substrate 400 may be a backplane 400 for a television monitor display having a pixel pitch P₂ that is greater than 50 μm, such as greater than 100 μm (e.g., between 150 μm and 350 μm). For example, the display device may have a PPI of 130 such that the pixel pitch P₂ may be 196 μm in the X- and Y-directions. By contrast, the pitch P₁ of the pixels 25 on the initial growth substrate 101 may be 50 μm or less, such as 49 μm in the X- and Y-directions. In the illustrated embodiment, sixteen (16) pixels 25 are shown on the initial growth substrate 101. The sixteen (16) pixels 25 may only occupy a 196 μm×196 μm area on the initial growth substrate 101 (i.e., 1/16^{th} of the size of the region of the display onto which the pixels 25 may be transferred). Each multicolor pixel 25 includes a common contact electrode 151 (e.g., a common cathode electrode) in a contact region 150 of the pixel 25, as described above.

FIGS. 52A-52E illustrate a process of sequentially transferring multicolor pixels 25 from the initial growth substrate 101 to the target substrate 400. As shown in FIGS. 52B-52E, individual pixels 25₁ through 25₄ may be transferred from the initial growth substrate 101 to the target substrate 400 to populate each of the pixel regions of the target substrate 400. This process may continue until all pixel locations on the target substrate 400 have been populated. If there are more pixel regions of the display than the total number of pixels 25 on the initial growth substrate 101, additional pixels may be transferred from one or more additional growth substrates 101. In some embodiments, the same initial growth substrate 101 may be used multiple times—i.e., after all pixels 25 have been transferred from the initial growth substrate 101 to a target substrate 400, additional multicolor pixels 25 may be formed on the same substrate 101 and may be subsequently transferred to the same target substrate 400 and/or one or more additional target substrates 400. Moreover, because each of the pixels 25 includes a local common contact electrode 151 (e.g., a common cathode electrode), the display does not require additional backend processing steps to provide both the p-side and n-side connections to the multicolor light emitting device pixels 25.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

1. A display, comprising:
a backplane having a mounting surface; and
a multicolor pixel bonded to the mounting surface of the backplane, the multicolor pixel comprising a plurality of subpixels, where each subpixel is configured to emit light having a different peak wavelength, and wherein:
each subpixel of the multicolor pixel comprises a front side surface configured to emit light there through and a rear side surface facing the backplane, and each subpixel of the multicolor pixel comprises:
a front side portion adjacent to the front side surface of the subpixel and comprising a first conductivity-type semiconductor material layer extending continuously between each subpixel of the multicolor pixel; and
a rear side portion adjacent to the rear side surface of the subpixel and comprising an active region and a second conductivity-type semiconductor material layer;
a first contact electrode electrically contacting the first conductivity-type semiconductor material layer;
second contact electrodes electrically contacting the second conductivity-type semiconductor material layer in each subpixel of the multicolor pixel, and
bonding material portions mechanically and electrically coupling the first contact electrode and the plurality of second contact electrodes to corresponding bonding pads on the mounting surface of the backplane.

2. The display of claim 1, wherein the first contact electrode contacts a rear surface of the first conductivity-type semiconductor material layer that faces the backplane.

3. The display of claim 2, wherein:
the first contact electrode is located in a contact region of the multicolor pixel; and
the multicolor pixel comprises a blue light emitting subpixel, a green light emitting subpixel and a red light emitting subpixel.

4. The display of claim 3, wherein the blue light emitting subpixel and the green light emitting subpixel are located adjacent to one another along a first horizontal direction, the red light emitting subpixel and the contact region are located adjacent to one another along the first horizontal direction, and a horizontal cross-sectional area of the red light emitting subpixel is greater than a horizontal cross-sectional area of the blue light emitting subpixel and a horizontal cross-sectional area of the green light emitting subpixel.

5. The display of claim 1, wherein the display comprises a plurality of multicolor pixels, the first conductivity-type semiconductor material extending continuously between the plurality of multicolor pixels, and the first contact electrode functions as a common contact electrode for the plurality of multicolor pixels.

6. The display of claim 1, wherein:
the rear side portion of each of the subpixels of the multicolor pixel includes first and second planar surfaces extending parallel to the mounting surface of the backplane and a sidewall extending between the first and second planar surfaces;
a semiconductor connecting portion is located between the front side portion and the rear side portion of the subpixel, and
a dielectric material layer extends over the sidewall and at least a portion of the first and second planar surfaces of the rear side portion and laterally surrounds the semiconductor connecting portion of each of the subpixels of the multicolor pixel.

7. The display of claim 6, wherein the first contact electrode contacts the first conductivity-type semiconductor material layer through an opening in the dielectric material layer.

8. The display of claim 7, wherein the multicolor pixel further comprises:
a superlattice structure extending continuously between the subpixels; and
a first portion of a semiconductor spacer layer extending continuously between the subpixels, wherein second portions of the semiconductor spacer layer form the semiconductor connecting portion of each subpixel, and wherein the first contact electrode contacts the first conductivity-type semiconductor material layer through an opening in the dielectric material layer, the first portion of the semiconductor spacer layer, and the superlattice structure.

9. The display of claim 6, wherein:
the sidewall extending between the first and second planar surfaces of the rear side portion of each of the subpixels of the multicolor pixel comprises a tapered sidewall, and a lateral dimension of the rear side portion of each subpixel decreases between the first and second planar surfaces along a direction extending towards the backplane;
the second conductivity-type semiconductor material layer forms the second planar surface, the tapered sidewall, and a portion of the first planar surface of the rear side portion of each subpixel, and the second conductivity-type semiconductor material layer laterally surrounds the active region in each subpixel; and
the rear side portion of each of the subpixels of the multicolor pixel further comprises a semiconductor electron blocking layer located between the active region and the second conductivity-type semiconductor material layer.

10. The display of claim 6, wherein:
the dielectric material layer has a thickness in a range of 10-100 nm; and
the dielectric material layer comprises at least one of aluminum oxide, silicon oxide or silicon nitride; and
the dielectric material layer extends continuously over and between each of the subpixels of the multicolor pixel.

11. The display of claim 6, wherein a lateral dimension of the semiconductor connecting portion is less than a lateral dimension of the first and second planar surfaces of the rear side portion in each of the subpixels.

12. The display of claim 6, wherein the first conductivity-type semiconductor material layer, the second conductivity type semiconductor material layer and the semiconductor connecting portion in each subpixel comprises GaN, and the active region in each subpixel comprises a quantum well structure comprising at least one GaN layer and at least one InGaN layer.

13. The display of claim 6, wherein the front side portion of each of the subpixels of the multicolor pixel comprises a first portion of the first conductivity type semiconductor material layer, and a second portion of the first conductivity type semiconductor material layer forms the semiconductor connecting portion of each of the subpixels.

14. A method of fabricating a display device, comprising:
forming a multicolor light emitting device pixel over an initial growth substrate, the multicolor light emitting device pixel comprising a first conductivity-type semiconductor material layer and a plurality of light emitting device structures over the first conductivity-type semiconductor material layer that are configured to emit light having different peak wavelengths;
forming a contact electrode over the first conductivity-type semiconductor material layer; and
transferring the multicolor light emitting device pixel from the initial growth substrate to a second substrate such that a bonding material portion electrically couples the contact electrode to a bonding pad on the second substrate and the contact electrode provides a common contact electrode for the plurality of light emitting device structures of the multicolor light emitting device pixel.

15. The method of claim 14, wherein:
the first contact electrode contacts a rear surface of the first conductivity-type semiconductor material layer that faces the second substrate; and
the multicolor light emitting device pixel is transferred from the initial growth substrate to the second substrate using laser liftoff and laser bonding.

16. The method of claim 14, wherein each of the light emitting device structures formed over the first conductivity-type semiconductor material layer are formed via a selective growth process.

17. The method of claim 16, wherein the selective growth process comprises:
forming a first dielectric material layer over the first conductivity-type semiconductor material layer;
lithographically patterning the first dielectric material layer to form an opening through the first dielectric material layer;
forming a first semiconductor material pedestal structure within the opening and laterally-surrounded by the first dielectric material layer;
forming a first light emitting device structure comprising a first active region and a second conductivity-type semiconductor material layer over first active region via selective growth from the first semiconductor material pedestal structure, wherein the first active region is configured to emit light having a first peak wavelength;
performing an etching process to remove the first dielectric material layer;
forming a second dielectric material layer over the first conductivity-type semiconductor layer and the first light emitting device structure and laterally surrounding and contacting the first semiconductor material pedestal structure using a conformal deposition process;
lithographically patterning the second dielectric material layer to form an opening through the second dielectric material layer;
forming a second semiconductor material pedestal structure within the opening and laterally-surrounded by the second dielectric material layer;
forming a second light emitting device structure comprising a second active region and a second conductivity-type semiconductor material layer over the second active region via selective growth from the second semiconductor material pedestal structure, wherein the second active region is configured to emit light having a second peak wavelength that is different than the first peak wavelength; and
performing an etching process to remove the second dielectric material layer.

18. The method of claim 17, further comprising:
forming a third dielectric material layer over the first conductivity-type semiconductor layer, the first light emitting device structure, and the second light emitting device structure, and laterally surrounding and contacting each of the first semiconductor material pedestal structure and the second semiconductor material pedestal using a conformal deposition process;
lithographically patterning the third dielectric material layer to form an opening through the third dielectric material layer;
forming a third semiconductor material pedestal structure within the opening and laterally-surrounded by the third dielectric material layer;
forming a third light emitting device structure comprising a third active region and a second conductivity-type semiconductor material layer over the third active region via selective growth from the third semiconductor material pedestal structure, wherein the third active region is configured to emit light having a third peak wavelength that is different than the first peak wavelength and the second peak wavelength; and
performing an etching process to remove the third dielectric material layer.

19. The method of claim 18, further comprising:
forming a fourth dielectric material layer over the first conductivity-type semiconductor layer, the first light emitting device structure, the second light emitting device structure, and the third light emitting device structure and laterally surrounding and contacting each of the first semiconductor material pedestal structure, the second semiconductor material pedestal structure and the third semiconductor material pedestal structure; and
performing an etching process to remove the fourth dielectric material layer from a contact region, wherein the contact electrode is formed in the contact region.

20. The method of claim 14, wherein the method further comprises forming a plurality of multicolor light emitting device pixels over the initial growth substrate, wherein the first conductivity-type semiconductor layer extends continuously between the plurality of multicolor light emitting device pixels.

21. The method of claim 14, further comprising:
performing an etching process to form a trench extending continuously around each multicolor light emitting device pixel, wherein the trench extends through the first conductivity type semiconductor material layer to the initial growth substrate, and a contact electrode electrically contacting the first conductivity-type semiconductor material layer is formed in each multicolor light emitting device pixel.

22. The method of claim 21, wherein multiple multicolor light emitting device pixels are transferred from the initial growth substrate to the second substrate, and a pitch between adjacent multicolor light emitting device pixels on the initial growth substrate is less than a pitch between adjacent multicolor light emitting device pixels on the second substrate.

23. The method of claim 20, wherein multiple multicolor light emitting device pixels are transferred from the initial growth substrate to the second substrate, and the contact electrode provides a common contact electrode for the plurality of light emitting device structures of multiple multicolor light emitting device pixels on the second substrate.
